(19) United States
(12) Patent Application Publication
(10) Pub. No.: US 2026/0327432 A1
(43) Pub. Date: Oct. 22, 2026

(54) POLYMER-BASED PORTION, FOLDABLE APPARATUS CONTAINING THE SAME, AND METHODS OF MAKING

(71) Applicant: CORNING INCORPORATED, CORNING, NY (US)

(72) Inventors: Charles Brandenburg, Wellsboro, PA (US); Cassandra Ann Haynes, Sayre, PA (US); Jenny Kim, Sunnyvale, CA (US); Eric Emil Leonhardt, Philadelphia, PA (US); Jennifer Lynn Lyon, Watkins Glen, NY (US); James Robert Matthews, Painted Post, NY (US); Kevin Robert McCarthy, Horseheads, NY (US); Weijun Niu, Painted Post, NY (US); Manuela Ocampo Davila, Corning, NY (US); Cynthia Jean Wilson, Corning, NY (US); Tingge Xu, San Jose, CA (US)

(21) Appl. No.: 19/130,718

(22) PCT Filed: Nov. 7, 2023
(86) PCT No.: PCT/US2023/036897

§ 371 Date: May 16, 2025

Related U.S. Application Data
(60) Provisional application No. 63/427,174, filed on Nov. 22, 2022.

(51) Int. Cl. C09D 4/00; C03C 17/32; C09D 7/48; C09D 7/61; C09D 7/65; C09D 135/02; H05K 5/03

(52) U.S. Cl. CPC C09D 4/00; C03C 17/32; C09D 7/48; C09D 7/61; C09D 7/65; C09D 135/02; H05K 5/03

(57) ABSTRACT

Polymer-based portions include an elastic modulus from about 500 MegaPascals to about 3 GigaPascals and a difference between an ultimate elongation and a strain at a well-defined yield of about 3% or more. In aspects, polymer-based portions include one or more branching points corresponding to a multi-functional urethane acrylate-oligomer, a multi-functional acrylate, or combinations thereof. In aspects, the polymer-based portion includes an epoxy and an inorganic filler. Foldable apparatus include the polymer-based portion and a substrate. In aspects, methods include curing a precursor solution including from about 30 wt % to about 80 wt % of a multi-functional urethane-acrylate oligomer, a multi-functional acrylate monomer, or combinations thereof. In aspects, methods include curing a precursor solution including from about 25 wt % to about 85 wt % of a difunctional epoxy and from about 15 wt % to about 70 wt % of an inorganic filler.

### CROSS-REFERENCE TO RELATED APPLICATION

This application claims the benefit of priority under 35 U.S.C. § 119 of U.S. Provisional Application Ser. No. 63/427,174 filed on Nov. 22, 2022, the content of which is relied upon and incorporated herein by reference in its entirety.

### FIELD

The present disclosure relates generally to polymer-based portions, foldable apparatus containing polymer-based portions, and methods of making the same and, more particularly, to polymer-based portions comprising one or more branching points, an epoxy with an inorganic filler, and/or an elastic modulus of about 500 MPa or more, foldable apparatus containing the same, and methods of making the same from multi-functional urethane acrylate oligomers, multi-functional acrylate monomers, or an epoxy with an inorganic filler.

### BACKGROUND

Glass-based substrates are commonly used, for example, in display devices, for example, liquid crystal displays (LCDs), electrophoretic displays (EPD), organic light-emitting diode displays (OLEDs), plasma display panels (PDPs), or the like.

There is a desire to develop foldable versions of displays as well as foldable protective covers to mount on foldable displays. Foldable displays and covers should have good impact and puncture resistance. At the same time, foldable displays and covers should have small minimum bend radii (e.g., about 10 millimeters (mm) or less). However, plastic displays and covers with small minimum bend radii tend to have poor impact and/or puncture resistance. Furthermore, conventional wisdom suggests that ultra-thin glass-based sheets (e.g., about 75 micrometers (μm or microns) or less thick) with small minimum bend radii tend to have poor impact and/or puncture resistance. Furthermore, thicker glass-based sheets (e.g., greater than 125 micrometers) with good impact and/or puncture resistance tend to have relatively large minimum bend radii (e.g., about 30 millimeters or more). Consequently, there is a need to develop foldable apparatus and/or polymer-based portions that have low minimum bend radii and good impact and puncture resistance.

### SUMMARY

There are set forth herein polymer-based portions, foldable apparatus comprising the same, and methods of making polymer-based portions and foldable apparatus comprising the same. Polymer-based portions can comprise an epoxy with an organic filler, or an acrylate or urethane-acrylate with one or more branching points. Providing a polymer with one or more branching points can increase a stiffness of the polymer and/or an ability of the polymer to absorb impacts (e.g., impact resistance). The polymer-based portion can comprise a well-defined yield. Providing a polymer-based portion with a well-defined yield can enable the polymer-based portion and/or a foldable apparatus containing the polymer-based portion to withstand impacts without failure and/or puncture, for example, because the polymer-based portion can withstand greater impacts through plastic deformation instead of failing. As demonstrated in the Examples, the pen drop height and/or puncture resistance of portions of foldable apparatus including the polymer-based portion can be greater than the Comparative Examples, meaning that the impact resistance and/or puncture resistance in portions of the foldable apparatus including the polymer-based portion can be closer to the corresponding properties of other portions of the polymer-based portion than was previously attainable. Providing a polymer-based portion with a glass-transition temperature outside of an operating range (e.g., from about 0° C. to about 40° C., from about −10° C. to about 50° C.) can enable consistent properties across the operating range.

Providing a refractive index for the polymer-based portion from about 1.48 to about 1.55 or from 1.49 to 1.52 can reduce an absolute difference of refractive index (e.g., about 0.05 or less, about 0.01 or less) between the polymer-based portion and components (e.g., substrate, adhesive, hard-coating) that can be adjacent to the polymer-based portion in an application, which can reduce optical distortions. Providing a low absolute value of b* (e.g., from −1 to 1) can be substantially free of yellowing and/or other noticeable color. Providing a polymer-based portion with a low yellowing index (e.g., about 2 or less, about 1.4 or less) can be substantially free of yellowing and/or other noticeable color.

Providing an inorganic filler can increase an elastic modulus, impact resistance, and/or puncture resistance of the resulting polymer-based portion. Providing a composition free of functionalized oligomeric silsesquioxanes can decrease a cost to produce the composition and/or resulting polymer-based portion, increase a flexibility of the resulting polymer-based portion, and/or increase an adhesion of the resulting polymer-based portion. Alternatively, in aspects, the composition can comprise functionalized oligomeric silsesquioxanes that can be in combination with silica nanoparticles or not. Providing a composition comprising functionalized oligomeric silsesquioxanes can increase a hardness and/or impact resistance of the resulting polymer-based portion. In aspects, the composition can be substantially free (e.g., 1 wt % or less) and/or free of silica nanoparticles. Without wishing to be bound by theory, silica nanoparticles can aggregate, especially at elevated temperature, impairing mechanical and/or optical properties of the composition or resulting coating and/or coated article. Providing a composition substantially free and/or free of silica nanoparticles can reduce processing issues (e.g., agglomeration, aggregation, phase separation) with the composition, improve optical properties (e.g., maintain low haze and/or high transmittance even after aging at elevated temperature and/or humidity) of the coating and/or the resulting coating and/or coated article, and reduce mechanical properties (e.g., hardness, modulus, strain) of the resulting coating and/or coated article compared to a corresponding composition, coating, and/or coated article comprising a plurality of functionalized oligomeric silsesquioxanes without silica nanoparticles.

Providing a composition that is substantially solvent-free (e.g., entirely solvent-free) can increase the curing rate of the composition, which can decrease processing time. Providing a composition that is substantially solvent-free (e.g., entirely solvent-free) can reduce (e.g., decrease, eliminate) the use of additives, for example, rheology modifiers, and increase composition homogeneity, which can improve the quality of the resulting polymer-based portion (e.g., increased transmittance, decreased haze, increased mechanical properties). Providing a composition that is substantially solvent-free (e.g., entirely solvent-free) can reduce a volume change as a result of curing (e.g., shrinkage). In aspects, the composition and/or the polymer-based portion can be substantially free of fluorine-based compounds and/or free of fluorine-based compounds, which can reduce an environmental impact of the polymer-based portion and/or reduce a cost to produce the polymer-based portion.

The foldable substrate can comprise glass-based and/or ceramic-based portions, which can provide good dimensional stability, reduced incidence of mechanical instabilities, good impact resistance, and/or good puncture resistance. The foldable substrate can comprise glass-based and/or ceramic-based portions comprising one or more compressive stress regions, which can further provide increased impact resistance and/or increased puncture resistance. By providing a foldable substrate comprising a glass-based and/or ceramic-based substrate, the substrate can also provide increased impact resistance and/or puncture resistance while simultaneously facilitating good folding performance. In aspects, the substrate thickness can be sufficiently large (e.g., from about 70 micrometers (microns or μm) to about 2 millimeters) to further enhance impact resistance and puncture resistance. Providing foldable substrates comprising a central portion comprising a central thickness that is less than a substrate thickness (e.g., first thickness of the first portion and/or second thickness of the second portion) (e.g., by about 10 μm or more) can enable a small parallel plate distance (e.g., about 10 millimeters or less) based on the reduced thickness in the central portion, which can enable the foldability and/or rollability of the foldable substrate and/or foldable apparatus.

In aspects, the foldable apparatus and/or foldable substrates can comprise one or more recesses, for example, a first central surface area recessed from a first major surface by a first distance and/or a second central surface area recessed from a second major surface by a second distance. Providing a first recess opposite a second recess can provide the central thickness that is less than a substrate thickness. Further, providing a first recess opposite a second recess can reduce a maximum bend-induced strain of the foldable apparatus, for example, between a central portion and a first portion and/or second portion since the central portion comprising the central thickness can be closer to a neutral axis of the foldable apparatus and/or foldable substrates than if only a single recess was provided. Additionally, providing the first distance substantially equal to the second distance can reduce the incidence of mechanical instabilities in the central portion, for example, because the foldable substrate is symmetric about a plane comprising a midpoint in the substrate thickness and the central thickness. Moreover, providing a first recess opposite a second recess can reduce a bend-induced strain of a material positioned in the first recess and/or second recess compared to a single recess with a surface recessed by the sum of the first distance and the second distance. Providing a reduced bend-induced strain of a material positioned in the first recess and/or the second recess can enable the use of a wider range of materials because of the reduced strain requirements for the material. For example, stiffer and/or more rigid materials can be positioned in the first recess, which can improve impact resistance, puncture resistance, abrasion resistance, and/or scratch resistance of the foldable apparatus. Additionally, controlling properties of a first material positioned in a first recess and a second material positioned in a second recess can control the position of a neutral axis of the foldable apparatus and/or foldable substrates, which can reduce (e.g., mitigate, eliminate) the incidence of mechanical instabilities, apparatus fatigue, and/or apparatus failure.

In aspects, the foldable apparatus and/or foldable substrates can comprise a first transition region attaching the central portion to the first portion and/or a second transition region attaching the central portion to the second portion. Providing transition regions with smoothly and/or monotonically decreasing (e.g., continuously decreasing) thicknesses can reduce stress concentration in the transition regions and/or avoid optical distortions. Providing a sufficient length of the transition region(s) (e.g., about 0.15 mm or more or about 0.3 mm or more) can avoid optical distortions that may otherwise exist from a sharp change in thickness of the foldable substrate. Providing an average transition angle of a first transition surface area of the first transition region relative to the first central surface area that is sufficiently large (e.g., about 167° or more or about 170° or more) can avoid optical distortions and/or reduce visibility of the transition region. Providing a sufficiently small average transition angle (e.g., about 179° or less or about 176° or less) can reduce the amount of the foldable apparatus and/or the foldable substrates having an intermediate thickness that may have reduced impact resistance and/or reduced puncture resistance.

Some example aspects of the disclosure are described below with the understanding that any of the features of the various aspects may be used alone or in combination with one another.

Aspect 1. A polymer-based portion comprising:
an elastic modulus from about 500 MegaPascals to about 3 GigaPascals;
an ultimate elongation of about 12% or more;
a glass-transition temperature from about 45° C. to about 150° C.; and
a refractive index from about 1.48 to about 1.55,
wherein the polymer-based portion exhibits a well-defined yield, and a difference between the ultimate elongation and a strain at the well-defined yield is about 3% or more.

Aspect 2. The polymer-based portion of aspect 1, wherein the polymer-based portion comprises urethane-acrylate branching points or acrylate branching points.

Aspect 3. The polymer-based portion of aspect 1, wherein the polymer-based portion is an epoxy with from about 5 weight % to about 20 weight % of an inorganic filler.

Aspect 4. The polymer-based portion of any one of aspects 1-3, wherein a stress at the well-defined yield ranges from about 30 MegaPascals to about 90 MegaPascals.

Aspect 5. The polymer-based portion of any one of aspects 1-4, wherein the ultimate elongation ranges from about 25% to about 100%.

Aspect 6. The polymer-based portion of any one of aspects 1-5, wherein the difference between the ultimate elongation and the strain at the well-defined yield is from about 5% to about 75%.

Aspect 7. A polymer-based portion comprising:
from about 30 wt % to about 80 wt % of a multi-functional urethane-acrylate oligomer, a multi-functional acrylate, or combinations thereof, and at least one of the multi-functional urethane-acrylate oligomer or the multi-functional acrylate has 3 or more functionalities; and
from 0 wt % to about 70 wt % of an inorganic filler,
wherein the polymer-based portion comprises:
   one or more branching points at the multi-functional urethane-acrylate oligomer or the multi-functional acrylate;
   a refractive index from about 1.48 to about 1.55;
   an elastic modulus from about 500 MegaPascals to about 3 GigaPascals;
   an ultimate elongation of about 12% or more; and
   a glass-transition temperature from about 45° C. to about 150° C.

Aspect 8. The polymer-based portion of aspect 7, wherein the inorganic filler comprises from about 20 wt % to about 60 wt % of an acrylate-functionalized polyhedral oligomeric silsesquioxane.

Aspect 9. The polymer-based portion of aspect 7, wherein the inorganic filler comprises from about 10 wt % to about 30 wt % of silica nanoparticles dispersed throughout the polymer-based portion.

Aspect 10. The polymer-based portion of any one of aspects 7-9, wherein the polymer-based portion comprises from about 30 wt % to about 80 wt % of the multi-functional urethane-acrylate oligomer.

Aspect 11. The polymer-based portion of any one of aspects 7-9, wherein the polymer-based portion comprises from about 30 wt % to about 50 wt % of the multi-functional acrylate.

Aspect 12. A polymer-based portion comprising:
from about 30 wt % to about 85 wt % of an epoxy; and
from about 15 wt % to about 70 wt % of an inorganic filler,
wherein the polymer-based portion comprises:
   a refractive index from about 1.48 to about 1.55;
   an elastic modulus from about 500 MegaPascals to about 3 GigaPascals;
   an ultimate elongation of about 25% or more; and
   a glass-transition temperature from about 45° C. to about 150° C.

Aspect 13. The polymer-based portion of aspect 12, wherein the polymer-based portion comprises from about 15 wt % to about 70 wt % of an epoxy-functionalized polyhedral oligomeric silsesquioxane, a glycidyl-functionalized polyhedral oligomeric silsesquioxane, or combinations thereof.

Aspect 14. The polymer-based portion of aspect 12, wherein the polymer-based portion comprises from about 15 wt % to about 30 wt % of silica nanoparticles dispersed throughout the polymer-based portion.

Aspect 15. The polymer-based portion of any one of aspects 7-12, wherein the polymer-based portion exhibits a well-defined yield, and a difference between the ultimate elongation and a strain at the well-defined yield is about 3% or more.

Aspect 16. The polymer-based portion of aspect 15, wherein the difference between the ultimate elongation and the strain at the well-defined yield is from about 5% to about 75%.

Aspect 17. The polymer-based portion of any one of aspects 7-16, wherein the ultimate elongation ranges from about 25% to about 100%.

Aspect 18. The polymer-based portion of aspect 17, wherein a stress at the well-defined yield ranges from about 30 MegaPascals to about 90 MegaPascals.

Aspect 19. The polymer-based portion of any one of aspects 1-18, wherein the polymer-based portion comprises from about 0.5 parts-per-hundred to about 3 parts-per-hundred of a photoinitiator.

Aspect 20. The polymer-based portion of any one of aspects 1-19, wherein the polymer-based portion comprises from about 0.1 parts-per-hundred to about 10 parts-per-hundred of an acrylate silane.

Aspect 21. The polymer-based portion of any one of aspects 1-20, wherein the polymer-based portion comprises from about 0.1 parts-per-hundred to about 1 parts-per-hundred of an antioxidant.

Aspect 22. The polymer-based portion of any one of aspects 1-21, wherein a minimum transmittance of the polymer-based portion for optical wavelengths from 400 nanometers to 750 nanometers is 89% or more.

Aspect 23. The polymer-based portion of any one of aspects 1-22, wherein a haze of the polymer-based portion is about 1% or less.

Aspect 24. The polymer-based portion of aspect 23, wherein the haze is about 0.1% or less.

Aspect 25. The polymer-based portion of any one of aspects 1-24, wherein the polymer-based portion has a CIE b* value from about −1 to about 1.

Aspect 26. The polymer-based portion of any one of aspects 1-25, wherein the polymer-based portion has a yellowing index of about 2 or less.

Aspect 27. The polymer-based portion of aspect 26, wherein the yellowing index is about 1.4 or less.

Aspect 28. The polymer-based portion of any one of aspects 1-27, wherein the polymer-based portion can withstand 200,000 cycles of bending to a parallel plate distance of 3 millimeters at 25° C. and 40% relative humidity.

Aspect 29. The polymer-based portion of any one of aspects 1-28, wherein a tensile stress of the polymer-based portion is from about 40 MegaPascals to about 100 MegaPascals.

Aspect 30. The polymer-based portion of any one of aspects 1-29, wherein the elastic modulus is from about 1 GigaPascal to about 2.5 GigaPascals.

Aspect 31. The polymer-based portion of any one of aspects 1-30, wherein the glass-transition temperature is from about 50° C. to about 100° C.

Aspect 32. The polymer-based portion of any one of aspects 1-31, wherein the polymer-based portion is fluorine-free.

Aspect 33. The polymer-based portion of any one of aspects 1-32, wherein the polymer-based portion can withstand a pen drop height of 10 centimeters or more when a pen is incident on a 50 micrometer thick sheet of poly(ethylene terephthalate) that is disposed on a 25 micrometer thick adhesive having an elastic modulus of 10 MegaPascals that is in turn disposed on the polymer-based portion that is in turn disposed on a glass-based substrate comprising a thickness of 30 micrometers.

Aspect 34. The polymer-based portion of any one of aspects 1-33, wherein the polymer-based portion can withstand a load of 1 kgf from a 0.25 millimeter diameter tungsten carbide ball incident on a 50 micrometer thick sheet of poly(ethylene terephthalate) that is disposed on a 25 micrometer thick adhesive having an elastic modulus of 10 MegaPascals that is in turn disposed on the polymer-based portion that is in turn disposed on a glass-based substrate comprising a thickness of 30 micrometers without puncturing the 50 micrometer thick sheet of poly(ethylene terephthalate).

Aspect 35. The polymer-based portion of any one of aspects 1-33, wherein the polymer-based portion can withstand a load of 2 kgf from a 0.5 millimeter diameter tungsten carbide ball incident on a 50 micrometer thick sheet of poly(ethylene terephthalate) that is disposed on a 25 micrometer thick adhesive having an elastic modulus of 10 MegaPascals that is in turn disposed on the polymer-based portion that is in turn disposed on a glass-based substrate comprising a thickness of 30 micrometers without puncturing the 50 micrometer thick sheet of poly(ethylene terephthalate).

Aspect 36. A foldable apparatus comprising:
a substrate comprising:
   a substrate thickness defined between a first major surface and a second major surface opposite the first major surface;
   a first portion comprising the substrate thickness, a first compressive stress region extending to a first depth of compression from the first major surface, a second compressive stress region extending to a second depth of compression from the second major surface;
   a second portion comprising the substrate thickness, a third compressive stress region extending to a third depth of compression from the first major surface, a fourth compressive stress region extending to a fourth depth of compression from the second major surface; and
   a central portion positioned between the first portion and the second portion, the central portion comprising a central thickness defined between a first central surface area and a second central surface area opposite the first central surface area, a first central compressive stress region extending to a first central depth of compression from the first central surface area, a second central compressive stress region extending to a second central depth of compression from the second central surface area, and the central thickness is less than the substrate thickness; and
the polymer-based portion of any one of aspects 1-32, the polymer-based portion positioned in a recess defined between the first central surface area and a first plane that the first major surface extends along.

Aspect 37. The foldable apparatus of aspect 36, wherein an absolute value of a difference between a substrate refractive index of the substrate and the refractive index of the polymer-based portion is about 0.05 or less.

Aspect 38. The foldable apparatus of aspect 36, wherein an absolute value of a difference between a substrate refractive index of the substrate and the refractive index of the polymer-based portion is about 0.01 or less.

Aspect 39. The foldable apparatus of any one of aspects 36-38, wherein the polymer-based portion further extends over the first major surface, a minimum thickness of the polymer-based portion over the first major surface is about 5 micrometers or more.

Aspect 40. The foldable apparatus of any one of aspects 36-39, wherein the substrate comprises a first compressive stress region extending to a first depth of compression from the first major surface, the first compressive stress region comprising a maximum compressive stress from about 300 MegaPascals to about 1,500 MegaPascals.

Aspect 41. The foldable apparatus of any one of aspects 36-40, wherein the foldable apparatus can withstand a pen drop height of 10 centimeters or more when a pen is incident on a 50 micrometer thick sheet of poly(ethylene terephthalate) that is disposed on a 25 micrometer thick adhesive having an elastic modulus of 10 MegaPascals that is in turn disposed on the polymer-based portion of the foldable apparatus.

Aspect 42. The foldable apparatus of any one of aspects 36-41, wherein the foldable apparatus can withstand a load of 1 kgf from a 0.25 millimeter diameter tungsten carbide ball incident on a 50 micrometer thick sheet of poly(ethylene terephthalate) that is disposed on a 25 micrometer thick adhesive having an elastic modulus of 10 MegaPascals that is in turn disposed on the polymer-based portion of the foldable apparatus without puncturing the 50 micrometer thick sheet of poly(ethylene terephthalate).

Aspect 43. The foldable apparatus of any one of aspects 36-41, wherein the foldable apparatus can withstand a load of 2 kgf from a 0.5 millimeter diameter tungsten carbide ball incident on a 50 micrometer thick sheet of poly(ethylene terephthalate) that is disposed on a 25 micrometer thick adhesive having an elastic modulus of 10 MegaPascals that is in turn disposed on the polymer-based portion of the foldable apparatus without puncturing the 50 micrometer thick sheet of poly(ethylene terephthalate).

Aspect 44. A consumer electronic product, comprising:
a housing comprising a front surface, a back surface, and side surfaces;
electrical components at least partially within the housing, the electrical components comprising a controller, a memory, and a display, the display at or adjacent the front surface of the housing; and
a cover substrate disposed over the display,
wherein at least one of a portion of the housing or the cover substrate comprises the polymer-based portion of any one of aspects 1-35.

Aspect 45. A method of making a polymer-based portion comprising:
curing a precursor solution to form the polymer-based portion, the precursor solution comprising:
from about 30 wt % to about 80 wt % of a multi-functional urethane-acrylate oligomer, a multi-functional acrylate monomer, or combinations thereof, and at least one of the multi-functional urethane-acrylate oligomer or the multi-functional acrylate monomer has a functionality of 3 or more;
from 0 wt % to about 60 wt % of a reactive diluent;
from 0 wt % to about 40 wt % of a difunctional acrylate monomer;
from 0 wt % to about 40 wt % of a difunctional urethane-acrylate oligomer; and
from 0 wt % to about 70 wt % of an inorganic filler,
wherein the polymer-based portion comprises:
   one or more branching points at the multi-functional urethane-acrylate oligomer or multi-functional acrylate monomer;
   a refractive index from about 1.48 to about 1.55;
   an elastic modulus from about 500 MegaPascals to about 3 GigaPascals; and
   a glass-transition temperature from about 45° C. to about 150° C.

Aspect 46. The method of aspect 45, wherein the inorganic filler comprises from about 20 wt % to about 60 wt % of an acrylate-functionalized polyhedral oligomeric silsesquioxane.

Aspect 47. The method of aspect 46, wherein the inorganic filler comprises from about 10 wt % to about 30 wt % of silica nanoparticles dispersed in at least a portion of the reactive diluent, the difunctional acrylate monomer, or combinations thereof.

Aspect 48. The method of any one of aspects 45-47, wherein the precursor solution comprises from about 30 wt % to about 80 wt % of multi-functional urethane-acrylate oligomer, and the functionality of the multi-functional urethane-acrylate oligomer is 3 or more.

Aspect 49. The method of any one of aspects 45-47, wherein the precursor solution comprises from about 30 wt % to about 50 wt % of the multi-functional acrylate monomer, and the functionality of the multi-functional acrylate monomer is 3 or more.

Aspect 50. The method of any one of aspects 45-49, the precursor solution comprises from about 20 wt % to about 40 wt % of the reactive diluent.

Aspect 51. The method of any one of aspects 45-50, wherein the reactive diluent comprises is a mono-functional acrylate.

Aspect 52. The method of any one of aspects 45-51, the precursor solution comprises from about 20 wt % to about 40 wt % of the difunctional acrylate monomer.

Aspect 53. A method of making a polymer-based portion comprising:
curing a precursor solution to form the polymer-based portion, the precursor solution comprising:
from about 25 wt % to about 85 wt % of a difunctional epoxy;
from 0 wt % to about 45 wt % of a reactive diluent;
from about 15 wt % to about 70 wt % of an inorganic filler,
wherein the polymer-based portion comprises:
   a refractive index from about 1.48 to about 1.55;
   an elastic modulus from about 500 MegaPascals to about 3 GigaPascals; and
   a glass-transition temperature from about 45° C. to about 150° C.

Aspect 54. The method of aspect 53, wherein the precursor solution comprises from about 15 wt % to about 70 wt % of an epoxy-functionalized polyhedral oligomeric silsesquioxane, a glycidyl-functionalized oligomeric silsesquioxane, or combinations thereof.

Aspect 55. The method of aspect 53, wherein the precursor solution comprises from about 15 wt % to about 30 wt % of silica nanoparticles dispersed in at least a portion of the reactive diluent, the difunctional epoxy, or combinations thereof.

Aspect 56. The method of any one of aspects 53-55, wherein the precursor solution comprises from about 20 wt % to about 40 wt % of the reactive diluent.

Aspect 57. The method of any one of aspects 53-56, wherein the reactive diluent comprises a monofunctional epoxy.

Aspect 58. The method of any one of aspects 45-57, wherein the precursor solution comprises from about 0.5 parts-per-hundred to about 3 parts-per-hundred of a photoinitiator by superaddition.

Aspect 59. The method aspect 58, wherein the curing comprises irradiating the precursor solution with one or more wavelengths that the photoinitiator is sensitive to with a predetermined fluence.

Aspect 60. The method of aspect 59, wherein the predetermined fluence is from about 1 milliJoule per centimeter squared to about 4 millJoules per centimeter squared.

Aspect 61. The method of any one of aspects 45-60, wherein the precursor solution is solvent-free.

Aspect 62. The method of any one of aspects 45-61, wherein the precursor solution is fluorine-free.

Aspect 63. The method of any one of aspects 45-62, wherein the precursor solution comprises from about 0.1 parts-per-hundred to about 10 parts-per-hundred of an acrylate silane by superaddition.

Aspect 64. The method of any one of aspects 45-63, wherein the precursor solution comprises from about 0.1 parts-per-hundred to about 1 parts-per-hundred of an antioxidant by superaddition.

Aspect 65. The method of any one of aspects 45-64, wherein the polymer-based portion comprises an ultimate elongation of about 12% or more.

Aspect 66. The method of aspect 65, wherein the ultimate elongation ranges from about 25% to about 100%.

Aspect 67. The method of any one of aspects 45-66, wherein the polymer-based portion exhibits a well-defined yield, and a difference between an ultimate elongation and a strain at the well-defined yield is about 3% or more.

Aspect 68. The method of aspect 67, wherein a stress at the well-defined yield ranges from about 30 MegaPascals to about 90 MegaPascals.

Aspect 69. The method of any one of aspects 45-68, wherein a minimum transmittance of the polymer-based portion for optical wavelengths from 400 nanometers to 750 nanometers is 89% or more.

Aspect 70. The method of any one of aspects 45-69, wherein a haze of the polymer-based portion is about 1% or less.

Aspect 71. The method of aspect 70, wherein the haze is about 0.1% or less.

Aspect 72. The method of any one of aspects 45-71, wherein the polymer-based portion has a CIE b* value from about −1 to about 1.

Aspect 73. The method of any one of aspects 45-72, wherein the polymer-based portion has a yellowing index of about 2 or less.

Aspect 74. The method of aspect 73, wherein the yellowing index is about 1.4 or less.

Aspect 75. The method of any one of aspects 45-74, wherein the polymer-based portion can withstand 200,000 cycles of bending to a parallel plate distance of 3 millimeters at 25° C. and 40% relative humidity.

Aspect 76. The method of any one of aspects 45-75, wherein a tensile stress of the polymer-based portion is from about 40 MegaPascals to about 100 MegaPascals.

Aspect 77. The method of any one of aspects 45-76, wherein the elastic modulus is from about 1 GigaPascal to about 2.5 GigaPascals.

Aspect 78. The method of any one of aspects 45-77, wherein the glass-transition temperature is from about 50° C. to about 100° C.

Aspect 79. The method of any one of aspects 45-78, wherein the difference between the ultimate elongation and the strain at the well-defined yield is from about 5% to about 75%.

Aspect 80. The method of any one of aspects 45-79, wherein the polymer-based portion is fluorine-free.

Aspect 81. The method of any one of aspects 45-80, wherein the polymer-based portion can withstand a pen drop height of 10 centimeters or more when a pen is incident on a 50 micrometer thick sheet of poly(ethylene terephthalate) that is disposed on a 25 micrometer thick adhesive having an elastic modulus of 10 MegaPascals that is in turn disposed on the polymer-based portion that is in turn disposed on a glass-based substrate comprising a thickness of 30 micrometers.

Aspect 82. The method of any one of aspects 45-81, wherein the polymer-based portion can withstand a load of 1 kgf from a 0.25 millimeter diameter tungsten carbide ball incident on a 50 micrometer thick sheet of poly(ethylene terephthalate) that is disposed on a 25 micrometer thick adhesive having an elastic modulus of 10 MegaPascals that is in turn disposed on the polymer-based portion that is in turn disposed on a glass-based substrate comprising a thickness of 30 micrometers without puncturing the 50 micrometer thick sheet of poly(ethylene terephthalate).

Aspect 83. The method of any one of aspects 45-81, wherein the polymer-based portion can withstand a load of 2 kgf from a 0.5 millimeter diameter tungsten carbide ball incident on a 50 micrometer thick sheet of poly(ethylene terephthalate) that is disposed on a 25 micrometer thick adhesive having an elastic modulus of 10 MegaPascals that is in turn disposed on the polymer-based portion that is in turn disposed on a glass-based substrate comprising a thickness of 30 micrometers without puncturing the 50 micrometer thick sheet of poly(ethylene terephthalate).

Aspect 84. The method of any one of aspects 45-79, wherein the precursor solution is disposed in a recess of a substrate prior to the curing, the substrate comprising:
a substrate thickness defined between a first major surface and a second major surface opposite the first major surface;
a first portion comprising the substrate thickness, a first compressive stress region extending to a first depth of compression from the first major surface, a second compressive stress region extending to a second depth of compression from the second major surface;
a second portion comprising the substrate thickness, a third compressive stress region extending to a third depth of compression from the first major surface, a fourth compressive stress region extending to a fourth depth of compression from the second major surface; and
a central portion positioned between the first portion and the second portion, the central portion comprising a central thickness defined between a first central surface area and a second central surface area opposite the first central surface area, a first central compressive stress region extending to a first central depth of compression from the first central surface area, a second central compressive stress region extending to a second central depth of compression from the second central surface area, and the central thickness is less than the substrate thickness,
wherein the recess is defined between the first central surface area and a first plane that the first major surface extends along.

Aspect 85. The method of any one of aspects 45-79, wherein the polymer-based portion is disposed on a first central surface area of a substrate, the substrate comprising:
a substrate thickness defined between a first major surface and a second major surface opposite the first major surface;
a first portion comprising the substrate thickness, a first compressive stress region extending to a first depth of compression from the first major surface, a second compressive stress region extending to a second depth of compression from the second major surface;
a second portion comprising the substrate thickness, a third compressive stress region extending to a third depth of compression from the first major surface, a fourth compressive stress region extending to a fourth depth of compression from the second major surface; and
a central portion positioned between the first portion and the second portion, the central portion comprising a central thickness defined between the first central surface area and a second central surface area opposite the first central surface area, a first central compressive stress region extending to a first central depth of compression from the first central surface area, a second central compressive stress region extending to a second central depth of compression from the second central surface area, and the central thickness is less than the substrate thickness,
wherein a recess is defined between the first central surface area and a first plane that the first major surface extends along.

Aspect 86. The method of any one of aspects 84-85, wherein an absolute value of a difference between a substrate refractive index of the substrate and the refractive index of the polymer-based portion is about 0.05 or less.

Aspect 87. The method of aspect 86, wherein an absolute value of a difference between a substrate refractive index of the substrate and the refractive index of the polymer-based portion is about 0.01 or less.

Aspect 88. The method of any one of aspects 84-87, wherein the polymer-based portion extends over the first major surface, a minimum thickness of the polymer-based portion over the first major surface is about 5 micrometers or more.

Aspect 89. The method of any one of aspects 84-88, wherein the substrate comprises a first compressive stress region extending to a first depth of compression from the first major surface, the first compressive stress region comprising a maximum compressive stress from about 300 MegaPascals to about 1,500 MegaPascals.

Aspect 90. A consumer electronic product, comprising:
a housing comprising a front surface, a back surface, and side surfaces;
electrical components at least partially within the housing, the electrical components comprising a controller, a memory, and a display, the display at or adjacent the front surface of the housing; and
a cover substrate disposed over the display,
wherein at least one of a portion of the housing or the cover substrate comprises the polymer-based portion of any one of aspects 45-83.

### BRIEF DESCRIPTION OF THE DRAWINGS

The above and other features and advantages of aspects of the present disclosure are better understood when the following detailed description is read with reference to the accompanying drawings, in which:

FIG. 1 is a schematic view of an example foldable apparatus in a flat configuration according to aspects, wherein a schematic view of the folded configuration may appear as shown in FIG. 5;

FIGS. 2-4 are cross-sectional views of the foldable apparatus along line 2-2 of FIG. 1 including a foldable substrate according to aspects;

FIG. 5 is a schematic view of example foldable apparatus of aspects of the disclosure in a folded configuration wherein a schematic view of the flat configuration may appear as shown in FIG. 1;

FIG. 6 is a cross-sectional view of a testing apparatus to determine the minimum parallel plate distance of an example foldable substrate along line 7-7 of FIG. 5;

FIG. 7 is a cross-sectional views of another testing apparatus to determine the minimum parallel plate distance of an example modified foldable apparatus along line 7-7 of FIG. 5;

FIG. 8 is a cross-sectional view of a testing apparatus to determine the minimum parallel plate distance of an example foldable substrate along line 7-7 of FIG. 5;

FIG. 9 is a cross-sectional views of another testing apparatus to determine the minimum parallel plate distance of an example modified foldable apparatus along line 7-7 of FIG. 5;

FIG. 10 is a schematic plan view of an example consumer electronic device according to aspects;

FIG. 11 is a schematic perspective view of the example consumer electronic device of FIG. 10;

FIG. 12 is a flow chart illustrating example methods making foldable apparatus in accordance with aspects of the disclosure; and

FIGS. 13-18 schematically illustrate steps in methods of making a foldable apparatus.

Throughout the disclosure, the drawings are used to emphasize certain aspects. As such, it should not be assumed that the relative size of different regions, portions, and substrates shown in the drawings are proportional to its actual relative size, unless explicitly indicated otherwise.

### DETAILED DESCRIPTION

Aspects will now be described more fully hereinafter with reference to the accompanying drawings in which example aspects are shown. Whenever possible, the same reference numerals are used throughout the drawings to refer to the same or like parts.

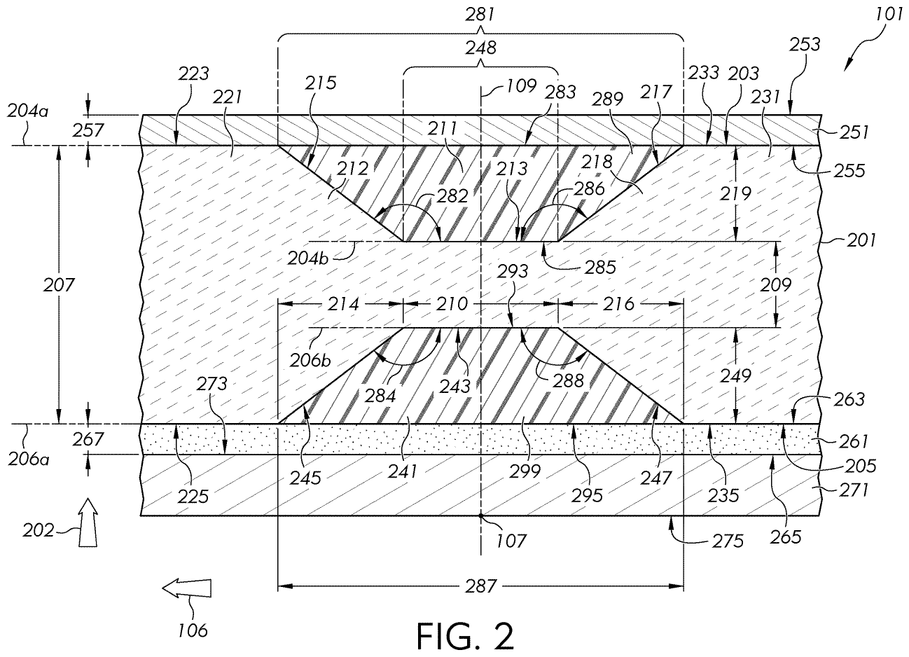

The polymer-based portions of aspects of the disclosure can be used, for example, in a foldable apparatus 101, 301, 401, 701, and 901 illustrated in FIGS. 2-4, 7, and 9. However, it is to be understood that the polymer-based portions are not limited to such applications and can be used in other applications. Unless otherwise noted, a discussion of features of aspects of one polymer-based portion and/or foldable apparatus can apply equally to corresponding features of any aspect of the disclosure. For example, identical part numbers throughout the disclosure can indicate that, in some aspects, the identified features are identical to one another and that the discussion of the identified feature of one aspect, unless otherwise noted, can apply equally to the identified feature of any other aspect of the disclosure.

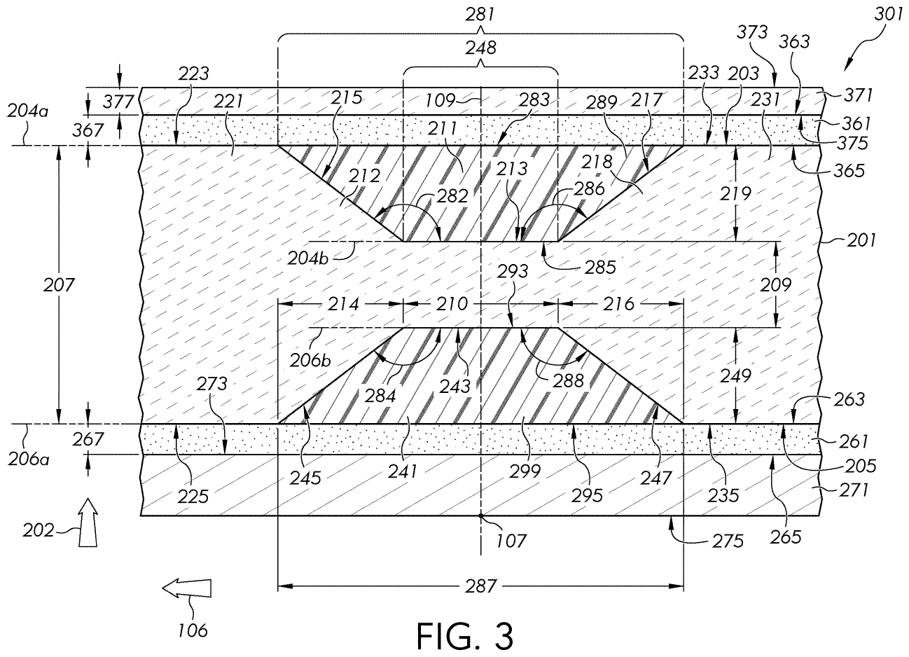

Aspects of the disclosure can comprise a polymer-based portion (e.g., first polymer-based portion 289 and/or second polymer-based portion 299). As shown in FIGS. 2-3, a first polymer-based portion 289 can comprise a first contact surface 283 and a second contact surface 285 opposite the first contact surface 283. In aspects, as shown, the first contact surface 283 can comprise a planar surface. As shown in FIGS. 2-4, a second polymer-based portion 299 can comprise a third contact surface 293 and a fourth contact surface 295 opposite the third contact surface 293. In aspects, as shown, the fourth contact surface 295 can comprise a planar surface.

As used herein, refractive index is measured in accordance with ASTM E1967-19 at a wavelength of 589 nanometers (nm). In aspects, the polymer-based portion 289 and/or 299 can be optically clear and/or comprise a first refractive index. In aspects, refractive index of the polymer-based portion 289 and/or 299 may be about 1.48 or more, about 1.49 or more, about 1.495 or more, about 1.50 or more, about 1.55 or less, about 1.54 or less, about 1.53 or less, about 1.52 or less, about 1.51 or less, or about 1.505 or less. In aspects, the refractive index of the polymer-based portion 289 and/or 299 can be in a range from about 1.48 to about 1.55, from about 1.48 to about 1.54, from about 1.49 to about 1.53, from about 1.49 to about 1.52, from about 1.49 to about 1.51, from about 1.495 to about 1.505, from about 1.50 to about 1.505, or any range or subrange therebetween. Providing a refractive index for the polymer-based portion within one or more of the above-mentioned ranges can reduce an absolute difference of refractive index between the polymer-based portion and components (e.g., substrate, adhesive, hard-coating) that can be adjacent to the polymer-based portion in an application, which can reduce optical distortions.

As used herein, “optically transparent” or “optically clear” means an average transmittance of 70% or more in the wavelength range of 400 nm to 700 nm through a 1.0 mm thick piece of material, wherein the thickness is measured along the path length of light travelling through the piece of material. As used herein, an average transmittance of a material is measured by averaging over optical wavelengths in a range from 400 nm to 700 nm through a 1.0 mm thick piece of the material, which comprises measuring the transmittance of whole number wavelengths from about 400 nm to about 700 nm and averaging the measurements. Unless specified otherwise, “transmittance” of a material refers to the average transmittance of the material. In aspects, an “optically transparent material” or an “optically clear material” may have an average transmittance of 75% or more, 80% or more, 85% or more, 89% or more, or 90% or more, 92% or more, 94% or more, 96% or more in the wavelength range of 400 nm to 700 nm through a 1.0 mm thick piece of the material. In aspects, the polymer-based portion 289 and/or 299 can be optically transparent. In further aspects, the polymer-based portion 289 and/or 299 can comprise an average transmittance measured over optical wavelengths in a range from 400 nm to 700 nm of about 89% or more, about 90% or more, about 91% or more, about 92% or more, about 93% or more, 100% or less, about 96% or less, about 95% or less, or about 94% or less. In further aspects, the polymer-based portion can comprise an average transmittance measured over optical wavelengths in a range from 400 nm to 700 nm in a range from about 89% to 100%, from about 90% to about 96%, from about 91% to about 96%, from about 91% to about 95%, from about 92% to about 95%, from about 92% to about 94%, from about 93% to about 94%, or any range or subrange therebetween. As used herein, “minimum transmittance” refers to the lowest transmittance value for any optical wavelength within a specified range of optical wavelengths. In aspects, the polymer-based portion 289 and/or 299 can comprise a minimum transmittance for optical wavelengths from 400 nm to 750 nm can be about 85% or more, about 87% or more, about 88% or more, about 89% or more, about 90% or more, about 91% or more, or about 92% or more.

The polymer-based portion 289 and/or 299 can comprise a haze as a function of an angle of illumination relative to a direction normal to a surface of the polymer-based portion. As used herein, haze refers to transmission haze that is measured in accordance with ASTM E430. Haze can be measured using a haze meter supplied by BYK Gardner under the trademark HAZE-GUARD PLUS, using an aperture over the source port. The aperture has a diameter of 8 mm. A CIE D65 illuminant is used as the light source for illuminating the foldable apparatus. Unless indicated otherwise, haze is measured at about 10° relative to an angle of incidence normal to a surface of the polymer-based portion. In aspects, the haze at about 0° and/or 10° relative to an angle of incidence normal to the surface of the polymer-based portion measured through a 1.0 millimeter (mm) thick piece of the polymer-based portion can be about 1% or less, about 0.5% or less, about 0.2% or less, about 0.15% or less, about 0.1% or less, or about 0.01% or more, about 0.02% or more, about 0.05% or more, or about 0.08% or more. In aspects, the haze at about 0° and/or 10° relative to an angle of incidence normal to the surface of the polymer-based portion measured through a 1.0 mm thick piece of the polymer-based portion can be in a range from 0% to about 1%, from 0% to 0.5%, from about 0.01% to about 0.2%, from about 0.02% to about 0.15%, from about 0.05% to about 0.1%, or any range or subrange therebetween. In aspects, the haze at about 20° relative to an angle of incidence normal to the surface of the polymer-based portion can be within one or more of the ranges specified above for 0° and/or 10°. Providing a polymer-based portion comprising low haze can enable good visibility through the polymer-based portion.

The polymer-based portion 289 and/or 299 can comprise a glass-transition (Tg) temperature. As used herein, the glass-transition temperature, a storage modulus at a range of temperatures, a storage modulus (e.g., at a glassy plateau), and a loss modulus (e.g., at a glass plateau) are measured using Dynamic Mechanical Analysis (DMA) with an instrument, for example, the DMA 850 from TA Instruments. The samples for the DMA analysis comprise a film secured by a tension clamp. As used herein, the storage modulus refers to the in-phase component of a response of the polymer-based material to the dynamic testing. Throughout the disclosure, the modulus of elasticity of a polymer-based material refers to the storage modulus of the polymer-based material because, without wishing to be bound by theory, the in-phase component of the response is attributed to the elastic portion of a viscoelastic material. As used herein, the loss modulus refers to the out-of-phase component of a response to the polymer-based material during the dynamic testing. Without wishing to be bound by theory, the loss modulus can correspond to the viscous component of a viscoelastic material. As used herein, the glass-transition temperature corresponds to a maximum value of a tan delta, which is a ratio of the loss modulus to the storage modulus.

In aspects, the glass-transition temperature (Tg) of the polymer-based portion can be about 45° C. or more, about 47° C. or more, about 50° C. or more, or about 52° C. or more, about 55° C. or more, about 150° C. or less, about 130° C. or less, about 100° C. or less, bout 85° C. or less, about 75° C. or less, about 70° C. or less, or about 65° C. or less. In aspects, the glass-transition temperature (Tg) of the polymer-based portion can be in a range from about 45° C. to about 150° C., from about 47° C. to about 130° C., from about 50° C. to about 100° C., from about 52° C. to about 85° C., from about 55° C. to about 75° C., from about 55° C. to about 65° C., or any range or subrange therebetween. Providing a polymer-based portion with a glass-transition temperature outside of an operating range (e.g., from about 0° C. to about 40° C., from about −10° C. to about 50° C.) can enable consistent properties across the operating range.

Throughout the disclosure, an elastic modulus of the polymer-based portion 289 and/or 299 is measured using ISO 527-1:2019. In aspects, an elastic modulus of the polymer-based portion can be about 500 MPa or more, about 800 MPa or more, about 1 GigaPascal (GPa) or more, about 1.2 GPa or more, about 1.4 GPa or more, about 3 GPa or less, about 2.7 GPa or less, about 2.5 GPa or less, about 2.2 GPa or less, about 2 GPa or less, or about 1.8 GPa or less. In aspects, an elastic modulus of the polymer-based portion 289 and/or 299 can be in a range from about 500 MPa to about 3 GPa, from about 800 MPa to about 2.7 GPa, from about 1 GPa to about 2.5 GPa, from about 1.2 GPa to about 2.2 GPa, from about 1.4 GPa to about 2 GPa, from about 1.4 GPa to about 1.8 GPa, or any range or subrange therebetween.

Throughout the disclosure, tension set of a sample is measured using ASTM D-412 as the strain at zero stress after the sample is stretched to a specified strain. In aspects, the polymer-based portion 289 and/or 299 can comprise a tension set after being extended to a strain of 10% at a strain rate of 10% strain per minute at 23° C. In further aspects, the tension set can be about 2% or less, about 1% or less, about 0.5% or less, or 0% or more. In further aspects, the tension set can be in a range from 0% to about 2%, from 0% to about 1%, from 0% to about 0.5%, or any range or subrange therebetween. In further aspects, the polymer-based portion can fully recover after being extended to a strain of 10% at a strain rate of 10% strain per minute at 23° C. In aspects, the polymer-based portion can fully recover after being extended to a strain of 10% at a strain rate of 10% strain per minute at 0° C. In aspects, the polymer-based portion can comprise a tension set after 200 cycles extending the polymer-based portion to a strain of 10% at a strain rate of 10% strain per minute at 23° C. In further aspects, the tension set can be about 2% or less, about 1% or less, about 0.5% or less, or 0% or more. In further aspects, the tension set can be in a range from 0% to about 2%, from 0% to about 1%, from 0% to about 0.5%, or any range or subrange therebetween.

Throughout the disclosure, a tensile strength (e.g., stress at failure), ultimate elongation (e.g., strain at failure), and yield point (e.g., strain at yield, stress at yield) of the polymer-based portion 289 and/or 299 is determined using ASTM D412A from the average of five samples using a tensile testing machine, for example, an Instron 3400 or Instron 6800, at 23° C. with rod of the polymer-based portion having a diameter of 0.6 mm attached to the tensile testing machine using rubber-faced clamps with testing performed at a strain rate of 25.4 mm/minute with an initial spacing between the clamps (i.e., gauge length) of 51 millimeters. The sample rod was formed by injecting a precursor composition of the polymer-based portion into a poly(tetrafluoroethylene) (PTFE) tube with an inner diameter of about 0.635 mm, cured using a radiation dose of 2.4 joules per centimeter squared (J/cm²) from a D-type ultraviolent lamp (available from Fusion) after which the PTFE tube was removed and the samples were equilibrated in a 23° C., 50% relative humidity environment for 24 hours before testing. The actual diameter of the sample rod was measured for each sample. In aspects, a tensile strength of the polymer-based portion 289 and/or 299 can be about 5 MPa or more, 20 MPa or more, about 40 MPa, about 45 MPa or more, about 50 MPa or more, about 55 MPa or more, about 250 MPa or less, about 150 MPa or less, about 100 MPa or less, about 90 MPa or less, about 85 MPa or less, or about 80 MPa or less. In aspects, a tensile strength of the polymer-based portion can be in a range from about 5 MPa to about 250 MPa, from about 20 MPa to about 150 MPa, from about 40 MPa to about 100 MPa, from about 45 MPa to about 90 MPa, from about 50 MPa to about 85 MPa, from about 55 MPa to about 80 MPa, or any range or subrange therebetween.

In aspects, an ultimate elongation of the polymer-based portion 289 and/or 299 can be about 12% or more, about 15% or more, about 20% or more, 25% or more, about 30% or more, about 35% or more, about 40% or more, about 45% or more, about 500% or less, about 100% or less, about 90% or less, about 85% or less, about 80% or less, or about 75% or less. In aspects, an ultimate elongation of the polymer-based portion 289 and/or 299 can be in a range from about 12% to about 500%, from about 15% to about 100%, from about 20% to about 90%, from about 25% to about 85%, from about 35% to about 80%, from about 45% to about 75%, or any range or subrange therebetween.

The yield point can be determined from a stress-strain curve measured in accordance with ASTM D412A, as described above. A yield point in a stress-strain curve corresponds to the stress value (and associated strain value) beyond which plastic deformation predominantly occurs. While minor plastic deformation may occur at stresses lower than the yield stress (e.g., tension set), the predominant plastic deformation can be immediately visible upon inspection with the naked eye. Without wishing to be bound by theory, brittle materials may not comprise a yield point (distinct from the ultimate failure of the sample), and ductile materials may undergo significant plastic deformation at relatively low strains (e.g., less than 1%) without a discernable transition between predominantly elastic (e.g., recoverable) deformation before a yield point and predominantly plastic (e.g., non-recoverable) deformation beyond the yield point. As used herein, a material exhibits a “well-defined yield” if a stress-strain curve for the material exhibits a yield point with a slope of 0 corresponding to a local maximum. In aspects, a stress at the well-defined yield (i.e., yield stress) can be about 10 MPa or more, about 20 MPa or more, about 30 MPa or more, about 40 MPa or more, about 45 MPa or more, about 100 MPa or less, about 90 MPa or less, about 80 MPa or less, about 75 MPa or less, or about 70 MPa or less. In aspects, a stress at the well-defined yield (i.e., yield stress) can range from about 10 MPa to about 100 MPa, from about 20 MPa to about 90 MPa, from about 30 MPa to about 80 MPa, from about 40 MPa to about 75 MPa, from about 45 MPa to about 70 MPa, or any range or subrange therebetween.

The polymer-based portion 289 and/or 299 can exhibit a well-defined yield. In aspects, a difference between the ultimate elongation and the strain at the well-defined yield of the polymer-based portion 289 and/or 299 can be about 3% or more, about 4% or more, about 5% or more, about 6% or more, about 7% or more, about 25% or less, about 100% or less, about 75% or less, about 60% or less, about 50% or less, about 40% or less, about 30% or less, about 20% or less, about 15% or less, about 10% or less, or about 8% or less. In aspects, a difference between the ultimate elongation and the strain at the well-defined yield of the polymer-based portion 289 and/or 299 can range from about 3% to about 100%, from about 3% to about 75%, from about 3% to about 60%, from about 4% to about 50%, from about 4% to about 40%, from about 5% to about 30%, from about 5% to about 20%, from about 6% to about 15%, from about 6% to about 12%, from about 7% to about 10%, or any range or subrange therebetween. Providing a polymer-based portion with a well-defined yield can enable the polymer-based portion and/or a foldable apparatus containing the polymer-based portion can withstand impacts without failure and/or puncture, for example, because the polymer-based portion can withstand greater impacts through plastic deformation instead of failing.

As used herein, “foldable” includes complete folding, partial folding, bending, flexing, or multiple capabilities. As used herein, the terms “fail,” “failure” and the like refer to breakage, destruction, delamination, or crack propagation. Likewise, a foldable apparatus achieves a parallel plate distance of “X,” or has a parallel plate distance of “X,” or comprises a parallel plate distance of “X” if it resists failure when the foldable apparatus is held at a parallel plate distance of “X” for 24 hours at about 85° C. and about 85% relative humidity.

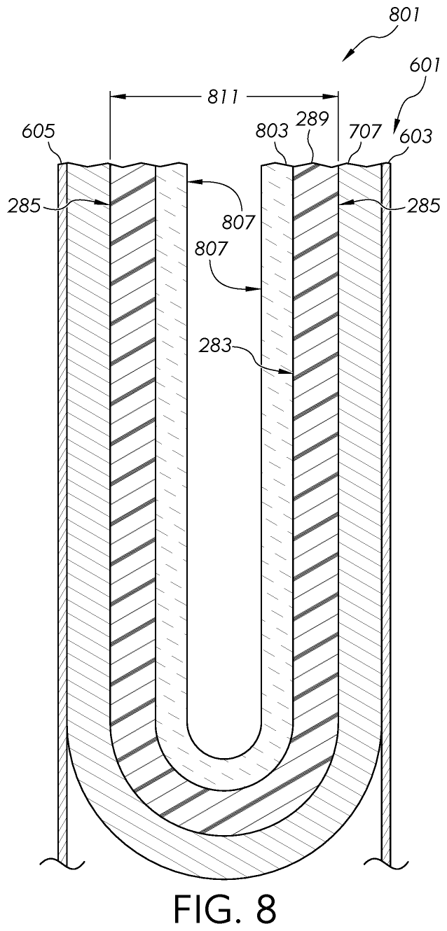

For determining the parallel plate distance or the minimum parallel plate distance of the polymer-based portion, with reference to FIG. 8, a first contact surface 283 of the polymer-based portion 289 is attached to a glass-based substrate 803 with a thickness of 30 μm and a second contact surface 283 of the polymer-based portion 289 is attached to a 50 μm thick sheet of poly(ethylene terephthalate) (PET) 707 that is formed into a foldable apparatus by hot pressing at 180° C. for 1 hour. For determining a parallel plate distance for a polymer-based portion, the 30 μm thick glass-based material comprising Composition 1, nominally, in mol % of: 69.1 SiO₂; 10.2 Al₂O₃; 15.1 Na₂O; 0.01 K₂O; 5.5 MgO; 0.09 SnO₂. As shown in FIG. 8, The test foldable apparatus 801 formed from the polymer-based portion 289 is configured with the 50 μm thick sheet 707 of PET contacting the pair of parallel rigid stainless-steel plates 603 and 605 of a parallel plate apparatus 601 such that an outer surface 807 of the glass-based substrate 803 faces itself. The distance 811 between the parallel plates is reduced at a rate of 50 μm/second until the parallel plate distance is equal to the “parallel plate distance” to be tested. Then, the parallel plates are held at the parallel plate distance to be tested for 24 hours at about 60° C. and about 90% relative humidity. As used herein, the “minimum parallel plate distance” is the smallest parallel plate distance that the foldable apparatus can withstand without failure under the conditions and configuration described above.

In aspects, the polymer-based portion can achieve a parallel plate distance of about 10 millimeters (mm), or 7 mm, or 5 mm, 4 mm, 3 mm, 2 mm, or of 1 mm. In aspects, the polymer-based portion can comprise a minimum parallel plate distance in a range from about 0.5 mm to about 10 mm, from about 1 mm to about 5 mm, from about 2 mm to about 3 mm, or any range or subrange therebetween. In aspects, the polymer-based portion can withstand 200,000 cycles of bending to a parallel plate distance of 3 mm at 25° C. and 40% relative humidity.

The polymer-based portion 289 and/or 299 may have an impact resistance defined by the capability of a test apparatus including the polymer-based portion to avoid failure at a pen drop height (e.g., 5 centimeters (cm) or more, 8 cm or more, 10 centimeters or more, 12 cm or more, 15 cm or more), when measured according to the “Pen Drop Test for Polymer.” For the polymer-based portion, the test apparatus for the Pen Drop Test for Polymer is formed by (1) hot pressing the polymer-based portion to a 30 μm thick glass-based substrate (comprising Composition 1) at 180° C. for 1 hour. Then, the polymer-based portion and glass-based substrate is attached to a 50 μm thick sheet of PET using a 25 μm thick adhesive having an elastic modulus of 10 MPa contacting the polymer-based portion and the 50 μm sheet of PET. As such, the test apparatus has the 50 μm thick sheet of PET disposed on the 25 μm thick adhesive that is in turn disposed on the polymer-based portion that is in turn disposed on the 30 μm thick glass-based substrate. As used herein, the “Pen Drop Test for Polymer” is conducted such that the test apparatus is tested with the load (i.e., from a pen dropped from a certain height) imparted to an outer surface of the PET sheet. During testing, the foldable apparatus bonded to the PET sheet is placed on an aluminum plate (6063 aluminum alloy, as polished to a surface roughness with 400 grit paper) with the glass-based substrate in contact with the aluminum plate. No tape is used on the side of the sample resting on the aluminum plate. A tube is used for the Pen Drop Test for Polymer to guide a pen to the outer surface of the PET sheet of the test apparatus so that the longitudinal axis of the tube is substantially perpendicular to the outer major surface with the longitudinal axis of the tube extending in the direction of gravity. The tube has an outside diameter of 1 inch (2.54 cm), an inside diameter of nine-sixteenths of an inch (1.4 cm), and a length of 90 cm. An acrylonitrile butadiene (ABS) shim is employed to hold the pen at a predetermined height for each test. After each drop, the tube is relocated relative to the test apparatus to guide the pen to a different impact location on the test apparatus. The pen employed in Pen Drop Test is a BIC Easy Glide Pen, Fine, having a tungsten carbide ballpoint tip of 0.7 mm (0.68 mm) diameter, and a weight of 5.73 grams (g) including the cap. The pen is dropped with the cap attached to the top end (i.e., the end opposite the tip) so that the ballpoint can interact with the test apparatus. In a drop sequence according to the Pen Drop Test for Polymer, one pen drop is conducted at an initial height of 1 cm, followed by successive drops in 0.5 cm increments up to 20 cm, and then after 20 cm, 2 cm increments until failure of the test apparatus. After each drop is conducted, the presence of any observable fracture, failure, or other evidence of damage to the test apparatus is recorded along with the particular pen drop height. Using the Pen Drop Test, multiple test apparatus can be tested according to the same drop sequence to generate a population with improved statistical accuracy. For the Pen Drop Test, the pen is to be changed to a new pen after every 5 drops, and for each new test apparatus tested. In addition, all pen drops are conducted at random locations on the test apparatus at or near the center of the test apparatus, with no pen drops near or on the edge of the test apparatus. For purposes of the Pen Drop Test for Polymer, “failure” means the formation of a visible mechanical defect in a laminate. The mechanical defect may be a crack or plastic deformation (e.g., surface indentation). The crack may be a surface crack or a through crack. The crack may be formed on an interior or exterior surface of a laminate. The crack may extend through all or a portion of the glass-based substrate or the test apparatus. A visible mechanical defect has a minimum dimension of 0.2 mm or more.

In aspects, the polymer-based portion 289 and/or 299 can resist failure for a pen drop in the Pen Drop Test for Polymer at a pen drop height of 5 cm or more, 8 cm or more, 9 cm or more, 10 cm or more, 11 cm or more, 12 cm or more, 13 cm or more, 14 cm or more, 15 cm or more, or 20 cm. In aspects, a maximum pen drop height that the polymer-based portion 289 and/or 299 withstand without failure in the Pen Drop Test for Polymer may be about 10 cm or more, about 11 cm or more, about 12 cm or more, about 13 cm or more, about 14 cm or more, about 15 cm or more, or about 20 cm or more.

The polymer-based portion can exhibit a puncture resistance as measured in a Quasi-Static Puncture Test for Polymer. For the “Quasi-Static Puncture Test for Polymer”, a test apparatus identical to the test apparatus discussed above for the Pen Drop Test for Polymer is used. As such, the test apparatus has the 50 μm thick sheet of PET disposed on the 25 μm thick adhesive that is in turn disposed on the polymer-based portion that is in turn disposed on the 30 μm thick glass-based substrate. In the Quasi-Static Puncture Test for Polymer, a tungsten carbide ball with a predetermined diameter is placed on the outer surface of the PET sheet and a load is applied to the tungsten carbide ball at a rate of 0.1 kilogram-force (kgf) per minute until failure. In aspects, the polymer-based portion can withstand a load of about 0.5 kgf or more, about 0.8 kgf or more, about 0.9 kgf or more, about 1 kgf or more, about 1.1 kgf or more, about 1.2 kgf or more applied through a 0.25 millimeter diameter tungsten carbide ball in the Quasi-Static Puncture Test for Polymer. In aspects, the polymer-based portion can withstand a load of about 0.5 kgf or more, about 1 kgf or more, about 1.5 kgf or more, about 1.8 kgf or more, about 1.9 kgf or more, about 2 kgf or more, about 2.1 kgf or more, about 2.2 kgf or more, about 2.5 kgf or more applied through a 0.5 millimeter diameter tungsten carbide ball in the Quasi-Static Puncture Test for Polymer.

As used herein, color coordinates for a polymer-based portion is measured using the same configurations as for haze (i.e., using a D65 illuminant with an observer angle of) 10°, where the results can be quantified using the L*, a*, and b* values of the CIELAB 1976 color space. In aspects, the polymer-based portion 289 and/or 299 can comprise a b* value of about −1 or more, about −0.8 or more, about −0.5 or more, about −0.2 or more, about 0 or more, about 1 or less, about 0.8 or less, about 0.5 or less, about 0.2 or less, or about 0 or less. In aspects, the polymer-based portion 289 and/or 299 can comprise a b* value ranging from about −1 to 1, from about −0.8 to about 0.8, from about −0.5 to about 0.5, from about −0.2 to about 0.2, about 0, or any range or subrange therebetween. Providing a low absolute value of b* (e.g., from −1 to 1) can be substantially free of yellowing and/or other noticeable color.

The polymer-based portion 289 and/or 299 can comprise a color shift, for example, as measured by a yellowing index. As used herein, the yellowing index is measured in accordance with ASTM D1925 using a D65 illuminant with an observer angle of 10°. In aspects, the yellowing index of the polymer-based portion 289 and/or 299 can be about 2 or less, about 1.8 or less, about 1.5 or less, about 1.4 or less, about 1.2 or less, about 1.1 or less, about 1 or less, about 0.9 or less, about 0.8 or less, about 0.7 or less, about 0.6 or less, about 0.2 or more, about 0.3 or more, about 0.4 or more, or about 0.5 or more. In aspects, the yellowing index of the polymer-based portion 289 and/or 299 can be in a range from about 0.2 to about 2, from about 0.2 to about 1.8, from about 0.2 to about 1.5, from about 0.3 to about 1.4, from about 0.3 to about 1.3, from about 0.3 to about 1.2, from about 0.3 to about 1.1, from about 0.3 to about 1.0, from about 0.4 to about 0.9, from about 0.4 to about 0.8, from about 0.5 to about 0.7, or any range or subrange therebetween. In further aspects, the polymer-based portion 289 and/or 299 can comprise a yellowing index within one or more of the ranges for the yellowing index after being held for 10 days in a 50% relative humidity at 25° C. environment. In further aspects, the polymer-based portion 289 and/or 299 can comprise a yellowing index within one or more of the ranges for the yellowing index after being held for 10 days in a 95% relative humidity at 25° C. environment. In further aspects, the polymer-based portion 289 and/or 299 can comprise a yellowing index within one or more of the ranges for the yellowing index after being held for 10 days in a 95% relative humidity at 65° C. environment. Providing a polymer-based portion with a low yellowing index (e.g., about 2 or less, about 1.4 or less) can be substantially free of yellowing and/or other noticeable color.

In aspects, the polymer-based portion 289 and/or 299 can optionally include one or more adhesion promoter (e.g., acrylate functionalized silane coupling agent, epoxy functionalized silane coupling agent), photoinitiator, and/or antioxidant. An amount of the one or more adhesion promoter, photoinitiator, and/or antioxidant can be within one or more of the corresponding ranges discussed below. For example, the polymer-based portion can comprise a photo-initiator from about 0.5 parts-per-hundred (pph) to about 3 pph, the polymer-based portion can comprise an adhesion promoters (e.g., acrylate functionalized silane coupling agent, epoxy functionalized silane coupling agent) from about 0.5 parts-per-million (ppm) to about 50 ppm or from about 0.1 pph to about 10 pph (e.g., from about 0.5 pph to about 5 pph), and/or the polymer-based portion can comprise the antioxidant from about 0.1 pph to about 1 pph. In aspects, the polymer-based portion 289 and/or 299 can be substantially free of fluorine-based compounds. As used herein, the composition can be substantially free of fluorine-based compounds while containing a trace amount of fluorine in a minor component (e.g., about 5 wt % or less of a photoinitiator) of the composition corresponding to an overall wt % of fluorine of about 0.25 wt % or less (resulting 0.0125 wt % fluorine). In further aspects, the composition can be free of fluorine-based compounds.

Throughout the disclosure, contents of the polymer-based portion can be determined through differential scanning calorimetry (DSC), infrared (IR) spectroscopy, X-ray photoelectron spectroscopy (XPS), electron paramagnetic resonance (EPR), and/or nuclear magnetic resonance (NMR). For example, a fraction of organic material (e.g., epoxy, acrylate, urethane-acrylate oligomer) as opposed to inorganic material (e.g., silsesquioxanes, inorganic nanoparticles) can be determined using DSC since mass associated with organic material is typically lost by 300° C. while organic material is usually not. For example, IR spectroscopy can be used determine the presence and/or amount of certain functional groups (e.g., epoxy, ether, acrylate, urethane) based on the existence and/or an intensity of absorbances at characteristic wavenumbers. The fine-structure detected by XPS can indicate a bonding structure of material.

In one set of embodiments, the polymer-based portion 289 and/or 299 described above can comprise one or more urethane-acrylate branching points or acrylate branching points. As used herein, a “branching point” is a location where two or more polymeric chains intersect (e.g., main chain and at least one chain branch). A polymeric chain is a series of covalently bonded repeat units (e.g., acrylate monomers, oligomers) with at least 5 covalently bonded repeat units. As used herein, the “main chain” of a polymer is the longest chain of atoms in the polymer that linearly (i.e., continuously and sequentially) extends from one end of the polymer to another end of the polymer. Providing a polymer with one or more branching points can increase a stiffness of the polymer and/or an ability of the polymer to absorb impacts (e.g., impact resistance). In aspects, the polymer-based portion 289 and/or 299 can comprise a multi-functional urethane-acrylate oligomer, a multi-functional acrylate, or combinations thereof, where at least one of the multi-functional urethane-acrylate oligomer or the multi-functional acrylate has 3 or more functionalities. As used herein, “functionalities” refers to a physically distinct (i.e., non-adjacent) functional groups (e.g., epoxy, acrylate, amine) that can react (or have reacted) with another repeat unit to form the polymer (or grow the polymer). For example, the multi-functional urethane-acrylate oligomer or the multi-functional acrylate can comprise (1) a multi-functional urethane-acrylate oligomer with 3 or more functionalities (e.g., trifunctional urethane-acrylate oligomer) and a multi-functional acrylate that does not have 3 or more functionalities (e.g., difunctional acrylate), (2) a multi-functional acrylate with 3 or more functionalities (e.g., trifunctional acrylate) and a multi-functional urethane-acrylate oligomer that does not have 3 or more functionalities (e.g., difunctional urethane-acrylate oligomer), (3) a multi-functional urethane-acrylate oligomer with 3 or more functionalities (e.g., trifunctional urethane-acrylate oligomer) and a multi-functional acrylate with 3 or more functionalities (e.g., trifunctional acrylate), or combinations thereof (e.g., including both difunctional urethane-acrylate oligomers and higher-functionality urethane-acrylate oligomers). In aspects, the multi-functional urethane-acrylate oligomer, the multi-functional acrylate, or combinations thereof, as a wt % of the polymer-based portion 289 and/or 299, can be about 30 wt % or more, about 35 wt % or more, about 40 wt % or more, about 45 wt % or more, about 50 wt % or more, about 80 wt % or less, about 75 wt % or less, about 70 wt % or less, about 65 wt % or less, or about 60 wt % or less, about 50 wt % or less, about 40 wt % or less, about 30 wt % or less, about 20 wt % or less, or about 10 wt % or less. It is to be understood that the above-mentioned ranges can apply to the content of multi-functional urethane-acrylate oligomers and/or multi-functional acrylate with 3 or more functionalities, and the polymer-based portion can comprise of difunctional urethane-acrylate oligomers and/or difunctional acrylates independent from the above-mentioned ranges. In aspects, the multi-functional urethane-acrylate oligomer, the multi-functional acrylate, or combinations thereof, as a wt % of the polymer-based portion 289 and/or 299, can range from about 30 wt % to about 80 wt %, from about 35 wt % to about 75 wt %, from about 40 wt % to about 70 wt %, from about 45 wt % to about 65 wt %, from about 50 wt % to about 60 wt %, or any range or subrange therebetween. In aspects, the polymer-based portion 289 and/or 299 can comprise an inorganic filler, as a wt % of the polymer-based portion, of 0 wt % or more, about 5 wt % or more, about 10 wt % or more, about 15 wt % or more, about 15 wt % or more, about 20 wt % or more, about 25 wt % or more, about 30 wt % or more, about 60 wt % or less, about 55 wt % or less, about 50 wt % or less, about 45 wt % or less, about 40 wt % or less, about 30 wt % or less, about 25 wt % or less, or about 20 wt % or less. In aspects, the polymer-based portion 289 and/or 299 can comprise an inorganic filler, as a wt % of the polymer-based portion, in a range from 0 wt % to about 70 wt %, from about 5 wt % to about 65 wt %, from about 10 wt % to about 60 wt %, from about 15 wt % to about 50 wt %, from about 20 wt % to about 45 wt %, from about 25 wt % to about 30 wt %, or any range or subrange therebetween. In further aspects, the inorganic filler can comprise an acrylate-functionalized polyhedral oligomeric silsesquioxane (POSS) (discussed below) in an amount, as a wt % of the polymer-based portion 289 and/or 299, of about 20 wt % or more, about 25 wt % or more, about 30 wt % or more, about 35 wt % or more, about 40 wt % or more, about 60 wt % or less, about 58 wt % or less, about 55 wt % or less, about 52 wt % or less, about 50 wt % or less, or about 40 wt % or less, for example, in a range from about 20 wt % to about 60 wt %, from about 25 wt % to about 58 wt %, from about 30 wt % to about 55 wt %, from about 35 wt % to about 52 wt %, from about 40 wt % to about 50 wt %, or any range or subrange therebetween. In further aspects, the inorganic filler can comprise silica nanoparticles in an amount, as a wt % of the polymer-based portion 289 and/or 299, of about 10 wt % or more, about 15 wt % or more, about 18 wt % or more, about 20 wt % or more, about 30 wt % or less, about 26 wt % or less, about 24 wt % or less, or about 22 wt % or less, for example, from about 10 wt % to about 30 wt %, from about 15 wt % to about 26 wt %, from about 18 wt % to about 24 wt %, or any range or subrange therebetween.

In another set of embodiments, the polymer-based portion 289 and/or 299 described above can comprise an epoxy (e.g., cured epoxy) with an inorganic filler. In aspects, the inorganic filler, as a wt % of the polymer-based portion 289 and/or 299, can be about 5 wt % or more, about 7 wt % or more, about 9 wt % or more, about 11 wt % or more, about 20 wt % or less, about 17 wt % or less, about 15 wt % or less, about 13 wt % or less, or about 10 wt % or less. In aspects, the inorganic filler, as a wt % of the polymer-based portion 289 and/or 299, can range from about 5 wt % to about 20 wt %, from about 7 wt % to about 17 wt %, from about 9 wt % to about 15 wt %, from about 11 wt % to about 13 wt %, or any range or subrange therebetween. In further aspects, the inorganic filler can comprise an epoxy-functionalized polyhedral oligomeric silsesquioxane (POSS) (discussed below) in an amount, as a wt % of the polymer-based portion 289 and/or 299, of about 15 wt % or more, about 20 wt % or more, about 30 wt % or more, about 35 wt % or more, about 40 wt % or more, about 50 wt % or more, about 70 wt % or less, about 68 wt % or less, about 65 wt % or less, about 62 wt % or less, about 60 wt % or less, about 55 wt % or less, or about 40 wt % or less, for example, in a range from about 15 wt % to about 70 wt %, from about 20 wt % to about 68 wt %, from about 30 wt % to about 65 wt %, from about 35 wt % to about 62 wt %, from about 40 wt % to about 60 wt %, or any range or subrange therebetween. In further aspects, the inorganic filler can comprise silica nanoparticles dispersed in the epoxy polymer. In even further aspects, the silica nanoparticles can be present in an amount, as a wt % of the polymer-based portion 289 and/or 299, of about 15 wt % or more, about 18 wt % or more, about 20 wt % or more, about 22 wt % or more, about 30 wt % or less, about 26 wt % or less, about 24 wt % or less, or about 22 wt % or less, for example, from about 15 wt % to about 30 wt %, from about 18 wt % to about 26 wt %, from about 20 wt % to about 24 wt %, or any range or subrange therebetween.

The polymer-based portion described above can be formed as the product of curing a composition. Methods of forming the polymer-based portion described above will now be described.

Methods of forming the polymer-based portion including an acrylate and/or a urethane-acrylate oligomer can comprise creating a composition. The composition comprises a multi-functional urethane-acrylate oligomer, a multi-functional acrylate, or combinations thereof, where at least one of the multi-functional urethane-acrylate oligomer or the multi-functional acrylate has 3 or more functionalities. As used herein, “acrylate” includes methacrylates and other functional groups containing acrylate functionality, unless otherwise indicated. In aspects, the multi-functional acrylate and/or the multi-functional urethane-acrylate oligomer can exclude methacrylates. In aspects, an amount of the multi-functional urethane-acrylate oligomer, the multi-functional acrylate, or combinations thereof, as a wt % of the composition, can be within one or more of the corresponding ranges discussed above for the amount of the multi-functional urethane-acrylate oligomer, the multi-functional acrylate, or combinations thereof, as a wt % of polymer-based portion.

For example, the composition can comprise a trifunctional urethane-acrylate oligomer as a multi-functional urethane-acrylate oligomer. Exemplary aspects of trifunctional urethane-acrylate oligomers include Photomer 6019 (IGM Resins), CR90991 (Haohui Polymers), SU7206 (Soltech Ltd.), SU564 (Soltech Ltd.), one of the following products in the Bomar product line available from Dymax: BR-144B, BR930D, and/or BR-990; one of the following products in the Photomer product line available from IGM Resins: 6010, 6019, 6184, 6639, 6642, and/or 6892; and/or one of the following products in the Miramer product line available from Miwon: PU320, PU330, PU340, PU3000, PU3200, PU3210, PU3410, PU3420, PU3450, and/or PU370. In aspects, an amount of the multi-functional urethane-acrylate oligomer (e.g., trifunctional urethane-acrylate oligomer), as a wt % of the composition, can be about 30 wt % or more, about 40 wt % more, about 50 wt % or more, about 55 wt % or more, about 60 wt % or more, about 80 wt % or less, about 75 wt % or less, about 70 wt % or less, or about 65 wt % or less. In aspects, an amount of the multi-functional urethane-acrylate oligomer (e.g., trifunctional urethane-acrylate oligomer), as a wt % of the composition, can range from about 30 wt % to about 80 wt %, from about 40 wt % to about 80 wt %, from about 50 wt % to about 75 wt %, from about 55 wt % to about 70 wt %, from about 60 wt % to about 65 wt %, or any range or subrange therebetween. As discussed above, the multi-functional urethane-acrylate can have 3 or more functionalities (e.g., acrylate functionalities). For example, the multi-functional urethane-acrylate have 4 functionalities (e.g., Miramer PU460 available from Miwon), or 6 functionalities (e.g., the following products in the Miramer product line available from Miwon: PU5000, PU610, PU6140, PU620, PU664, PU6510, or PU640). In aspects, the multi-functional urethane-acrylate oligomer can comprise a glass-transition temperature within one or more of the ranges discussed above for the polymer-based portion. In aspects, the multi-functional urethane-acrylate oligomer can comprise a glass-transition temperature less than the glass-transition temperature of the resulting polymer-based portion. In aspects, the multi-functional urethane-acrylate oligomer can comprise Photomer 6019 (IGM Resins).

For example, the composition can comprise a trifunctional acrylate (e.g., trifunctional acrylate monomer) as the multi-functional acrylate. Exemplary aspects of trifunctional acrylates include OTA480 (Allnex) and one of the following products in the Miramer product line available from Miwon: M300, M320, M340, M360, M370, M3130, M3150, M3160, M3190, and/or M3730. In aspects, an amount of the multi-functional acrylate (e.g., trifunctional acrylate monomer), as a wt % of the composition, can be 0 wt % or more, about 30 wt % or more, about 35 wt % or more, about 38 wt % or more, about 50 wt % or less, about 45 wt % or less, or about 42 wt % or less. In aspects, an amount of the multi-functional acrylate (e.g., trifunctional acrylate monomer), as a wt % of the composition, can range from about 30 wt % to about 50 wt %, from about 35 wt % to about 45 wt %, from about 38 wt % to about 42 wt %, or any range or subrange therebetween. As discussed above, the multi-functional acrylate can have 3 or more functionalities (e.g., acrylate functionalities). An exemplary aspect of a trifunctional methacrylate is Miramer M301 (available from Miwon). For example, the multi-functional acrylate can have 4 acrylate functionalities (e.g., Miramer M4004, Miramer M410, or Miramer M420 available from Miwon; Photomer 6646 or Photomer 6578 available from IGM), 5 acrylate functionalities (e.g., Miramer M500 available from Miwon), or 6 acrylate functionalities (e.g., Miramer M600 available from Miwon; Photomer 6621, Photomer 6628, Photomer 6631, Photomer 6690, Photomer 6692, or Photomer 6720 available from IGM). In aspects, the multi-functional acrylate can comprise M320, M340, M360, M3130, and/or M3190 from the Miramer product line available from Miwon.

In aspects, the composition can comprise a difunctional urethane-acrylate oligomer. In aspects, the difunctional urethane-acrylate oligomer can comprise one or more of the following products in the Miramer product line available from Miwon: PU210, PU256, PU2050, PU2100, PU2300C, PU2560, SC2404, and/or SC2565. In aspects, the difunctional urethane-acrylate oligomer can comprise one or more of the following products in the Photomer product line available from IGM Resins: 6009, 6063, 6210, 6215, 6230, 6620, 6630, 6638, 6643, 6644, 6645, 6891, 6579, 6581, 6582, and/or 6581. In aspects, the difunctional urethane-acrylate oligomer can comprise the following products available from Arkema (Sartomer): PRO13944, PRO14213, CN8881, CN90004, CN9009, CN9030, CN9031, CN964, CN966J75, CN981, CN991, and/or CN 962. In aspects, the difunctional urethane-acrylate oligomer can comprise the following products from Dymax (Bomar): BR-344, BR-345, BR-374, BR-3042, BR-3747AE, BR-541S, BR-543, BR-543TF, BR-571, BR-641E, BR-744BT, BR-744SD, and/or BR-771F. In aspects, the difunctional urethane-acrylate oligomer can comprise a polyether urethane acrylate. In aspects, the difunctional urethane-acrylate oligomer can comprise difunctional aliphatic urethane acrylate. An exemplary aspect of a difunctional urethane-acrylate oligomer is Bomar BR-543 (Dymax). In aspects, an amount of the difunctional urethane-acrylate oligomer, as a wt % of the composition, can be 0 wt % or more, 10 wt % or more, about 15% or more, about 20 wt % or more, about 40 wt % or less, about 30 wt % or less, or about 25 wt % or less. In aspects, an amount of the difunctional urethane-acrylate oligomer, as a wt % of the composition, can range from 0 wt % to about 40 wt %, from about 10 wt % to about 40 wt %, from about 15 wt % to about 30 wt %, from about 20 wt % to about 25 wt %, or any range or subrange therebetween.

In aspects, a total amount of urethane-acrylate oligomers in the composition, can be about 40 wt % or more, about 50 wt % or more, about 60 wt % or more, about 70 wt % or more, about 99 wt % or less, about 90 wt % or less, about 80 wt % or less, or about 70 wt % or less, for example, in a range from about 40 wt % to about 99 wt %, from about 50 wt % to about 90 wt %, from about 60 wt % to about 80 wt %, from about 60 wt % to about 70 wt %, or any range or subrange therebetween.

In some embodiments, the composition can comprise a difunctional acrylate. For example, the difunctional acrylate can comprise a difunctional methacrylate monomer (e.g., propylene-glycol dimethacrylate (SR-644 available from Sartomer) or a difunctional acrylate monomer. Exemplary embodiments of difunctional acrylate monomers include dipropylene-glycol diacrylate (DPGDA) (e.g., SR-508 (Sartomer), Photomer 4226 (IGM Resins)), 1,6-hexanediol diacrylate (e.g., Miramer M200 (Miwon)), hydroxyl pivalic acid neopentyl glycol diacrylate (e.g., Miramer M210 (Miwon)), bisphenol-A [4 EO] diacrylate (e.g., Photomer 4028 (IGM Resins)), tripropylene-glycol diacrylate (TPGDA) (e.g., Photomer 4061 (IGM Resins)), 3-methyl-1,5,-pentanediol diacrylate (MPDDA) (e.g., Photomer 4071 (IGM Resins)), neopentyl-glycol diacrylate (e.g., Photomer 4127 (IGM Resins)), Miramer HR 3700 (Miwon), 1,6-hexanediol ethoxylate diacrylate (e.g., Photomer 4369 (IGM Resins)), an ethoxylated bisphenol A diacrylate (e.g., Miramer M240 (IGM Resins)), and/or dipropylene-glycol diacrylate. In aspects, the difunctional acrylate can comprise 1,6-hexanediol diacrylate (e.g., Miramer M200 (Miwon)), and/or an ethoxylated bisphenol A diacrylate (e.g., Miramer M240 (IGM Resins)). In some embodiments, an amount of a difunctional acrylate, as a weight % (wt %) of the composition, can be 0 wt % or more, about 5 wt % or more, about 10 wt % or more, about 15 wt % or more, about 40 wt % or less, about 35 wt % or less, or about 30 wt % or less. In some embodiments, an amount of a difunctional cross-linking agent, as a weight % (wt %) of the composition, can range from 0 wt % to about 40 wt %, from about 5 wt % to about 35 wt %, from about 10 wt % to about 30 wt %, from about 15 wt % to about 30 wt %, or any range or subrange therebetween.

In aspects, the composition can comprise a reactive diluent. As used herein, a reactive diluent is a monofunctional compound that can decrease the viscosity of the composition and decrease a cross-linking density of the polymer-based portion. Without wishing to be bound by theory, decreasing the cross-linking density of the polymer-based portion can decrease the glass-transition temperature of the polymer-based portion. In aspects, the reactive diluent can comprise a monofunctional acrylate. In further aspects, the reactive diluent comprising a monofunctional acrylate can include isobornyl acrylate (e.g., Miramer 1140 (Miwon), Photomer 4012 (IGM Resins)), biphenyl-methyl acrylate (e.g., Miramer 1192 (Miwon)), 2-propyl-heptyl acrylate, butyl acrylate, ethoxylated nonyl phenol acrylates (e.g., Miramer 164 (Miwon), Miramer 166 (Miwon)), ethoxy ethoxy ethyl acrylate (e.g., Miramer 170 (Miwon)), isooctyl acrylate (e.g., Miramer 1084 (Miwon)), 2-[(butylamino)carbonyl-oxy-ethyl] acrylate (e.g., Photomer 4184 (IGM Resins)), an aromatic acrylate (e.g., Miramer M140 (Miwon)), tetrahydrofurfuryl acrylate (e.g., Miramer M150 (Miwon)), benzyl acrylate (e.g., Miramer M1182 (Miwon), 2-ethylhexyl acrylate, and/or a phenol ether acrylate (e.g., Miramer 144 (Miwon)). In further aspects, the reactive diluent can comprise a monofunctional acrylate (e.g., mono-acrylate monomer). In further aspects, the reactive diluent can comprise a vinyl-terminated mono-acrylate monomer. Exemplary aspects of the reactive diluent include biphenylmethyl acrylate, ethoxylated nonyl phenol acrylate, 2-[(butylamino)carbonyl-oxy-ethyl] acrylate, 2-hydroxy-3-phenoxypropyl acrylate, and/or isooctyl acrylate. In aspects, the reactive diluent can comprise 2 or more, 3 or more, or 4 or more different compounds (e.g., a phenol ether acrylate, isooctyl acrylate, biphenylmethyl acrylate, and/or an ethoxylated nonyl phenyl ether acrylate) that are each reactive diluents. In aspects, the reactive diluent can comprise a polyether acrylate, tetrahydrofurfuryl acrylate, an ethoxylated nonyl phenol acrylate, benzyl acrylate, biphenyl-methyl acrylate, isobornyl acrylate, 2-[(butylamino)carbonyl-oxy-ethyl] acrylate, and/or 2-ethylhexyl acrylate. In aspects, an amount of a reactive diluent, as a wt % of the composition, can be 0 wt % or more, about 10 wt % or more, about 15 wt % or more, about 20 wt % or more, about 25 wt % or more, about 30 wt % or more, about 60 wt % or less, about 55 wt % or less, about 50 wt % or less, or about 45 wt % or less, or about 40 wt % or less. In aspects, an amount of a reactive diluent, as a wt % of the composition, from 0 wt % to about 60 wt %, from about 10 wt % to about 55 wt %, from about 15 wt % to about 50 wt %, from about 20 wt % to about 45 wt %, or any range or subrange therebetween.

The composition can comprise an inorganic filler. In aspects, the inorganic filler can comprise nanoparticles (e.g., silica nanoparticles), a functionalized oligomeric silsesquioxane (e.g., functionalized polyhedral oligomeric silsesquioxane (POSS)), or combinations thereof. In aspects, the composition can be substantially free and/or free of functionalized oligomeric silsesquioxanes while containing nanoparticles. Providing a composition free of functionalized oligomeric silsesquioxanes can decrease a cost to produce the composition and/or resulting polymer-based portion, increase a flexibility of the resulting polymer-based portion, and/or increase an adhesion of the resulting polymer-based portion. Alternatively, in aspects, the composition can comprise functionalized oligomeric silsesquioxanes that can be in combination with silica nanoparticles or not. Providing a composition comprising functionalized oligomeric silsesquioxanes can increase a hardness and/or impact resistance of the resulting polymer-based portion. In aspects, the composition can be substantially free (e.g., 1 wt % or less) and/or free of silica nanoparticles. Without wishing to be bound by theory, silica nanoparticles can aggregate, especially at elevated temperature, impairing mechanical and/or optical properties of the composition or resulting coating and/or coated article. Providing a composition substantially free and/or free of silica nanoparticles can reduce processing issues (e.g., agglomeration, aggregation, phase separation) with the composition, improve optical properties (e.g., maintain low haze and/or high transmittance even after aging at elevated temperature and/or humidity) of the coating and/or the resulting coating and/or coated article, and reduce mechanical properties (e.g., hardness, modulus, strain) of the resulting coating and/or coated article compared to a corresponding composition, coating, and/or coated article comprising a plurality of functionalized oligomeric silsesquioxanes without silica nanoparticles. In aspects, an amount of the inorganic filler, as a wt % of the composition, can be 0 wt % or more, about 10 wt % or more, about 15 wt % or more, about 20 wt % or more, about 50 wt % or more, about 70 wt % or less, about 60 wt % or less, about 50 wt % or less, about 40 wt % or less, or about 30 wt % or less. In aspects, an amount of the inorganic filler, as a wt % of the composition, can range from 0 wt % to about 70 wt %, from about 10 wt % to about 60 wt %, from about 15 wt % to about 50 wt %, from about 20 wt % to about 40 wt %, or any range or subrange therebetween. Providing an inorganic filler can increase an elastic modulus, impact resistance, and/or puncture resistance of the resulting polymer-based portion.

As used herein a functionalized oligomeric silsesquioxane means an organosilicon compound comprises at least two monomers represented as RSiO_{1.5}, where there are three oxygen atoms with each oxygen atom shared with another monomer bonded thereto and R is a functional group that “functionalizes” an oligomeric silsesquioxane to form the functionalized oligomeric silsesquioxane, although the R of one monomer need not be the same as the R of another monomer. In aspects, a number of the RSiO_{1.5} monomers in the functionalized oligomeric silsesquioxane can be a whole number of 4 or more, 6 or more, 8 or more, 50 or less, 30 or less, 20 or less, 16 or less, about 12 or less, or 10 or less. In aspects, a number of the RSiO_{1.5} monomers in the functionalized oligomeric silsesquioxane can be a whole number in a range from 4 to 50, 4 to 30, 4 to 20, 6 to 20, 6 to 16, 6 to 12, 8 to 12, 8 to 10, or any range or subrange therebetween.

In aspects, the functionalized oligomeric silsesquioxane can further comprise any number of RSiO₂ monomers in addition to the RSiO_{1.5} monomeric units discussed above, where again the R can vary between monomers of either or both the RSiO₂ monomers and RSiO_{1.5} monomers. In further aspects, a RSiO₂ monomer can be a terminal monomer, meaning that it is connected to only one other monomer. For simplicity, these “terminal monomers” will be referred to as RSiO₂ with the understanding that terminal RSiO₂ monomers can refer to either RSiO_{3.5}, RSiO_{2.5}, R₂SiO_{3.5}, R₂SiO_{2.5}, R₂SiO_{1.5}, R₃SiO_{3.5}, R₃SiO_{2.5}, R₃SiO_{1.5}, or R₃SiO_{0.5}, where a first R of a single terminal monomer can be the same or different another (e.g., one, all) R of the same single terminal monomer. In further aspects, a RSiO₂ monomer can be bonded to two other monomers. For example, a RSiO₂ monomer can be bonded to another RSiO₂ and a RSiO_{1.5} monomer or two RSiO_{1.5} monomers. For simplicity, “non-terminal RSiO₂ monomers” can refer to either RSiO₃, RSiO₂, R₂SiO₃, or R₂SiO₂, where a first R of a single “non-terminal RSiO₂” monomer can be the same or different another (e.g., one, all) R of the same single “non-terminal RSiO₂ monomer.” In further aspects, the number of RSiO₂ monomers can be less than or equal to the number of RSiO_{1.5} monomers. For example, when the number of RSiO₂ monomers is 4 and the number of the RSiO_{1.5} monomers is 4 or more, a ladder-type functionalized oligomeric silsesquioxane can be formed, where each of the RSiO_{1.5} monomers is connected to two other RSiO_{1.5} monomers and either a RSiO_{1.5} monomer or a RSiO₂ monomer. In even further aspects, a reactant can comprise a ladder-type functionalized oligomeric silsesquioxanes.

In further aspects, the functionalized oligomeric silsesquioxane can comprise from 1 to 3 of RSiO₂ monomers (e.g., 1, 2, 3). In even further aspects, an adjacent pair of RSiO_{1.5} monomers can be connected to each other by two or more non-overlapping paths, where each path comprises at least one monomer other than the adjacent pair of RSiO_{1.5} monomers and the first path is connected to the second path without passing through the adjacent pair of monomers. For example, an open-cage functionalized oligomer silsesquioxane can comprise the adjacent pair of RSiO_{1.5} monomers connected to each other by two or more non-overlapping paths and the first path is connected to the second path without passing through the adjacent pair of monomers while also comprising from 1 to 3 of RSiO₂ monomers. In even further aspects, a reactant can comprise an open-cage functionalized oligomer silsesquioxane. In aspects, the functionalized oligomeric silsesquioxane can consist of RSiO_{1.5} monomers. As used herein, a polyhedral oligomeric silsesquioxane (POSS) refers to a functionalized oligomer silsesquioxane consisting of RSiO_{1.5} monomers. Exemplary aspects of functionalized POSS can comprise 6, 8, 10, or 12 RSiO_{1.5} monomers, although other aspects are possible. For example, functionalized oligomeric silsesquioxane consisting of 8 RSiO_{1.5} monomers is an octahedral functionalized POSS (e.g., polyoctahedral silsesquioxane). In aspects, functionalized oligomeric silsesquioxanes can be formed from condensation reactions of silane. As used herein a condensation reaction produces an R₂O byproduct, where R can include any of the R units discussed below and can further comprise hydrogen (e.g., with a hydroxyl or water byproduct). For example, silanes (e.g., R₃OSi) can be reacted to form terminal RSiO₂ monomers. For example, a terminal RSiO₂ monomer can react with another RSiO₂ monomer (e.g., terminal, non-terminal) to form an RSiO_{1.5} monomer as an oxygen atom of one monomer forms a bond with a silicon atom of another monomer, producing the condensation byproduct. It is to be understood that the RSiO_{1.5} silsesquioxane monomers are different from siloxane monomers, which can include M-type siloxane monomers (e.g., R₃SiO_{0.5}), D-type siloxane monomers (e.g., R₂SiO₂), and/or silica-type siloxane monomers (SiO₂).

Functionalized oligomeric silsesquioxanes can be functionalized by one or more functional groups. As used herein, a functional group functionalizing the functionalized oligomeric silsesquioxane can exclude hydrogen, bisphenols, and/or fluorine-containing functional groups. In aspects, the functional group functionalizing the functionalized oligomeric silsesquioxane can exclude isocyanates, alkenes, and/or alkynes. In aspects, a functional group for the functionalized oligomeric silsesquioxane can comprise epoxies, glycidyls, acrylates, and methacrylates. In further aspects, the functional group for the functionalized oligomeric silsesquioxane can be a glycidyl functional group, an epoxy functional group (e.g., epoxycyclohexyl), an acrylate (e.g., methacrylate) functional group. In even further aspects, the functional group for the functionalized oligomeric silsesquioxane can be an acrylate (e.g., methacrylate). Exemplary aspects of glycidyl functional groups include amine glycidyls, alkyl glycidyls (e.g., glycidylpropyl), ether glycidyls (e.g., glycidyloxy), siloxane glycidyls (e.g., glycidyldimethyoxy), and combinations thereof (e.g., glycidyloxypropyl, glycidyloxypropyldimethylsiloxy). Exemplary aspects of epoxy functional groups include epoxy, alkyl epoxy (e.g., epoxyethyl, epoxypropyl), and cycloalkyl epoxy (e.g., epoxycyclohexyl). A commercially available example of epoxy functionalized POSS includes (3,4, epoxycyclohexyl)ethyl functionalized POSS (e.g., 560316 (Sigma Aldrich)). Example aspects of acrylates include acrylate, alkyl acrylates (e.g., acrylopropyl, acryloisobutyl), and cycloalkyl acrylates (acrylocyclohexyl). Commercially available examples of acylate functionalized POSS include acrylopropyl functionalized POSS (e.g., MA0736 (Hybrid Polymers) and acryloisobutyl functionalized POSS (e.g., MA0701 (Hybrid Polymers)). Example aspects of methacrylates include methacrylate, alkyl methacrylates (e.g., methacrylomethyl, methacrylopropyl), cycloalkyl methacrylates (e.g., methacrylocyclopentyl), and combinations thereof (e.g., (propylmethacryl)cyclopentyl). Commercially available examples of methacrylate functionalized POSS include methylmethacrylate functionalized POSS (e.g., MA0706 (Hybrid Polymers), MA0716 (Hybrid Polymers), MA0718 (Hybrid Polymers)), methacrylopropyl functionalized POSS (e.g., 534633 (Sigma Aldrich), MA0702 (Hybrid Polymers), MA0735 (Hybrid Polymers), MA0719 (Hybrid Polymers)), and (propylmethacryl)cyclopentyl functionalized POSS (e.g., 560340 (Sigma Aldrich). In aspects, a functionalized POSS can be cross-linked with a difunctional polymer before being added to the composition, for example, a poly(propylene oxide) or poly(dimethyl siloxane) polymer cross-linking the functionalized POSS.

In aspects, the composition can comprise the functionalized oligomeric silsesquioxanes (e.g., functionalized POSS) in an amount of about 20 wt % or more, about 30 wt % or more, about 40 wt % or more, about 45 wt % or more, about 50 wt % or more, about 60 wt % or less, about 55 wt % or less, or about 50 wt % or less. In aspects, the composition can comprise the functionalized oligomeric silsesquioxanes in a range from about 20 wt % to about 60 wt %, from about 30 wt % to about 50 wt %, from about 40 wt % to about 55 wt %, from about 30 wt % to about 45 wt %, from about 35 wt % to about 45 wt %, from about 40 wt % to about 45 wt %, or any range or subrange therebetween.

As used herein, nanoparticles refer to particles comprising an effective diameter of at least 20 nm. Exemplary aspects of nanoparticles can comprise solid silica particles or mesoporous silica particles. Silica nanoparticles can be larger (e.g., comprise a larger effective diameter) than a functionalized oligomeric silsesquioxane of the plurality of functionalized oligomeric silsesquioxanes. Silica nanoparticles can be formed from colloidal silica and/or via a sol-gel method. In aspects, the nanoparticles (e.g., silica nanoparticles) can be dispersed in one of the other components of the compositions (e.g., reactive diluent, difunctional acrylate, multifunctional acrylate, difunctional urethane-acrylate oligomer, etc.). As used herein, the wt % of nanoparticles refers the content of nanoparticles excluding any material that the nanoparticles are dispersed in. For example, a composition with 40 wt % of a silica nanoparticle dispersion in a reactive diluent with 60 wt % silica nanoparticles in the dispersion would correspond to a net amount of silica nanoparticle of 24 wt % (40 wt %*60 wt %).

In aspects, an amount of the silica nanoparticles, as a wt % of the composition, can be about 10% or more, about 15% or more, about 20% or more, about 22 wt % or more, about 30% or less, about 28% or less, about 26% or less, or about 25% or less. In aspects, an amount of the silica nanoparticles, as a wt % of the composition, can be in a range from about 10% to about 30%, from about 15% to about 28%, from about 20% to about 26%, from about 22% to about 24%, or any range or subrange therebetween. In aspects, a mean effective diameter of the silica nanoparticles can be about 20 nm or more, about 30 nm or more, about 100 nm or less, or about 50 nm or less. In aspects, a mean effective diameter in a range from about 20 nm to about 100 nm, from about 20 nm to about 50 nm, from about 30 nm to about 50 nm, or any range or subrange therebetween. In aspects, the silica nanoparticles may not be functionalized or bonded to a functionalized oligomeric silsesquioxane in the composition. Providing nanoparticles can increase a hardness and/or an impact resistance of the coated article.

In aspects, the composition can comprise a photo-initiator. As used herein a photo-initiator is a compound sensitive to one or more wavelengths that upon absorbing light comprising the one or more wavelengths undergoes a reaction to produce one or more radicals or ionic species that can initiate a polymerization reaction. In further aspects, the photo-initiator may be sensitive to one or more wavelengths of ultraviolet (UV) light. Example aspects of photoinitiators sensitive to UV light include without limitation benzoin ethers, benzil ketals, dialkoxyacetophenones, hydroxyalkylphenones, aminoalkylphenones, acylphosphine oxides, thioxanthones, hydroxyalkylketones, and thoxanthanamines. In further aspects, the photoinitiator may be sensitive to one or more wavelengths of visible light. Example aspects of photoinitiators sensitive to visible light include without limitation 5,7-diiodo-3-butoxy-6-fluorone, bis(4-methoxybenzoyl) diethylgermanium, bis(2,4,6-trimethylbenzoyl)-phenylphosphineoxide, 3-methyl-4-aza-6-helicene, and thiocyanide borates. In further aspects, the photoinitiator may be sensitive to a wavelength that other components of the polymer-based portion and/or composition are substantially transparent at. As used herein, a compound (e.g., component of the composition) is substantially transparent at a predetermined wavelength if it comprises an average transmittance of 75% or more (e.g., 80% or more, 85% or more, or 90% or more, 92% or more, 94% or more, 96% or more) through a 1.0 mm thick piece of the compound at the predetermined wavelength. Providing a photo-initiator can enable controlled activation of curing of the composition. Providing a photo-initiator can enable uniform curing of the composition.

In further aspects, the photo-initiator may produce one or more ions. Example aspects of photoinitiators producing one or more ions include without limitation triarylsulfonium hexfluoroantimonate, triphenylsulfonium hexafluoroantimonate, and bis(4-tert-butylphenyl) iodonium perfluoro-1-butanesulfonate. Commercially available photoinitiators include without limitation the Irgacure product line from BASF. Exemplary aspects of photoinitiators include acetophenone-based compounds, for example, dimethoxyphenyl acetophenone. In further aspects, the photo-initiator may produce one or more radicals (e.g., free radicals). Example aspects of photo-initiators producing one or more radicals include acetophenone, anisoin, anthraquinone, benzene, benzil, benzoin, benzoin ethyl ether, benzoin isobutyl ether, benzoin methyl ether, benzophenone, hydroxycyclohexyl phenyl ketone, 4-benzoylbiphernyl, camphorquinone, 2-chlorothioxanthen-9-one, bibezosuberenone, 2-,2-diethyoxyacetophenone, dimethylbenzil, ferrocene, ethylanthraquinone, hydroxyacetophenone, hydroxybenzophenone, thioxanthene-9-one, diphenyl(2,4,6-trimethylbenzoyl)phosphine oxide, and phophineoxide. In even further aspects, the photo-initiator can comprise ethyl (2,4,6-trimethylbenzoyl)phenylphosphinate. As used herein, “superaddition” refers to an additional material added to a composition with the reference 100 wt % of the composition excluding the material added by superaddition. Throughout the disclosure, one “part-per-hundred” (pph) and 10,000 “parts-per-million” (ppm) refers to an amount equal to 1 wt % of the composition excluding materials added by superaddition. It is to be understood that compositions stated in terms of components added by superaddition can be converted to compositions without one or more of the components stated as superaddition by renormalizing the wt % of the composition to include the one or more components. In aspects, the composition can comprise an amount of the photoinitiator added by superaddition of about 0.1 pph or more, about 0.5 pph or more, about 1 pph or more, about 1.5 pph or more, about 5 pph or less, about 3 pph or less, about 2 pph or less, or about 1.5 pph or less, for example, from about 0.1 pph to about 5 pph, from about 0.5 pph to about 3, from about 1 to about 2, or any range or subrange therebetween.

In aspects, the polymer-based portion and/or composition can comprise a catalyst. Without wishing to be bound by theory, a catalyst can increase a rate of the curing (e.g., polymerization, reaction), and the catalyst may avoid permanent chemical change as a result of the curing. In aspects, the catalyst can comprise one or more platinum group metals, for example, ruthenium, rhodium, palladium, osmium, iridium, and/or platinum. In aspects, the catalyst can comprise a platinum-based Karstedt's catalyst solution. Exemplary aspects of platinum-based catalysts include chloroplatinic acid, platinum-fumarate, colloidal platinum, metallic platinum, and/or platinum-nickel nanoparticles.

In aspects, the composition can comprise a silane coupling agent. In further aspects, the silane coupling agent can comprise a mercapto silane, an acrylate silane, and/or an epoxy silane. In even further aspects, the silane coupling agent can comprise an acrylate silane. Exemplar aspects of mercapto silanes include 3-mercaptopropylmethyldimethoxysilane (e.g., SIM6474.0 (Gelest), 3-mercaptopropyltrimethoxysilane (e.g., SIM6476.0 (Gelest)), 3-mercaptopropylmethyldiethoxysilane, 3-mercaptopropyltriethoxysilane (e.g., SIM6475.0 (Gelest)), 11-mercaptoundecyltrimethoxysilane (e.g., SIM6480.0 (Gelest)), (mercaptomethyl)methyldiethoxysilane (e.g., SIM6473.0 (Gelest)), and/or 3-mercaptopropylmethyldimethoxysilane (e.g., SIM6474.0 (Gelest)). Exemplary aspects of acrylate silanes include 3-acryloxypropyltrimethoxysilane (e.g., SIA0200.0 (Gelest)), 3-acryloxypropyltriethoxysilane, 3-arcyloxypropyldimethylmethoxysilane (e.g., SIA0190.0 (Gelest)), 3-acryloxyproplydimethylethoxysilane, 3-acryloxypropylmethyldiethoxysilane (e.g., SIA0197.0 (Gelest)), 3-acryloxypropylmethyldimethoxysilane (e.g., SIA0198.0 (Gelest)), N-(3-acryloxy-2-hydroxypropyl)-3-aminopropyltrimethoxysilane, N-(3-acryloxy-2-hydroxypropyl)-3-aminopropyltriethoxysilane (e.g., SIA0180.0 (Gelest)), acryloxymethyltrimethoxysilane (e.g., SIA0182.0 (Gelest)), acryloxymethyltriethoxysilane, acryloxymethylphenethyltrimethoxysilane (e.g., SIA0184.0 (Gelest), and acryloxymethylphenethyltriethoxysilane. In aspects, the composition can comprise an amount of the silane coupling agent added by superaddition of about 0.5 ppm or more, about 5 ppm or more about 20 ppm or more, about 0.1 pph or more, about 0.5 pph or more, about 1 pph or more, about 2 pph or more, about 5 pph or more, about 10 pph or less, about 5 pph or less, about 3 pph or less, about 1 pph or less, about 0.1 pph or less, about 1,000 ppm or less, or about 50 ppm or less. In aspects, the composition can comprise an amount of the silane coupling agent added by superaddition from about 0.5 ppm to about 10 pph, from about 0.1 pph to about 10 pph, from about 0.5 pph to about 5 pph, from about 1 pph to about 3 pph, from about 2 pph to about 3 pph, or any range or subrange therebetween. Alternatively, aspects, the composition can comprise less than 1 pph of the silane coupling agent added by superaddition, for example, in a range from 0.5 ppm to about 0.1 pph, from about 5 ppm to about 1,000 ppm or less, from about 20 ppm to about 50 ppm, or any range or subrange therebetween.

In aspects, the polymer-based portion and/or composition can comprise an antioxidant. In further aspects, the antioxidant can comprise a phenolic-based compound or a phosphite-based compound. Exemplary aspects of antioxidants comprising phenolic-based compounds available include pentaerythritol tetrakis(3-(3,5-di-tert-butyl-4-hydroxyphenyl)propionate (e.g., Irganox 1010 (BASF)), thiodiethylene bis[3-(3,5-di-ter-butyl-4-hydroxy-phenyl)]propionate (e.g., Irganox 1035 (BASF)), octadecyl-3-(3,5-di-tert-butyl-4-hydroxyphenyl)propionate (e.g., Irganox 1076 (BASF)), benzenepropanoic acid (e.g., Irganox 1135 (BASF)), 3,3′,3′,5,5′,5′-hexa-tert-butyl-a,a′,a′-(mesitylene-2,4,6-triyl)tri-p-cresol (e.g., Irganox 1330 (BASF)), (1,1-di-tert-butyl)-4-hydroxyphenyl)methyl)ethylphosphonate (e.g., Irganox 1425 (BASF)), 4,6-bis[octylthiomethyl]-o-crsol (e.g., Irganox 1520 (BASF)), 1,3,5-tris[3,5-di-tert-butyl-4-hydroxybenzyl)-1,3,5-triazine-2,4,5 (1H,3H,5H)-trione (e.g., Irganox 3114 (BASF)), 2,6-di-tert-butyl-4-(4,6-bis(octothiol)-1,3,5-triazin-2-ylamino) phenol (e.g., Irganox 565 (BASF)), and 2′,3-bis[3-(3,5-di-tert-butyl-4-hydroxyphenyl) propionyl]propionohydrazine (e.g., Irganox MD-1024 (BASF)). Exemplary aspects of antioxidants comprising phosphite-based compounds include 2,2′,2″-nitrolo(triethyl-tris[3,3′,5,5′-terta-tert-butyl-1,1′-biphenyl-2,2′-diyl])phosphile (e.g., Irgafos 12 BASF), bis[2,4,-di-tert-butylphenol]pentaerythritol diphosphate (e.g., Irgafos 126 (BASF), tris[2,4-ditert-butylphenyl]phosphite (e.g., Irgafos 168 (BASF)), bis[2,4-di-tert-butyl-6-methylphenyl]-ethyl-phosphite (e.g., Irgafos 38 (BASF)), trisnonylphenyl phosphite (e.g., Weston 399 (Addivant)), 3,9-bis(octadecyloxy)-2,4,8,10-tetraoxa-3,9-diphosphaspiroundecane (e.g., Weston 618 (Addivant)) [1,3,2-dioxaphosphorinane, 5-butyl-5-ethyle-2-(2,4,6-tris[1,1-dimethylethyl]phenoxy)-1,3,2-dioxaphosphinane] (e.g., Ultranox 641 (SI Group)), 2,2′-ethyidene-bis[4,6,-di-tert-butylphenyl]fluorophosphate (e.g., Ethenox 398 (SI Group)), and 2,2′-Methylene-bis[4,6-di-tert-butylphenyl]-2-ethylhexyl phosphite (e.g., ADK STAB HP-10 (Adeka)). In aspects, the composition can comprise an amount of the antioxidant added by superaddition of about 0.01 pph or more, about 0.1 pph or more, about 0.2 pph or more, about 0.4 pph or more, about 5 pph or less, about 1 pph or less, about 0.8 pph or less, or about 0.6 pph or less, for example, in a range from about 0.01 pph to about 5 pph, from about 0.1 pph to about 1 pph, from about 0.2 pph to about 0.8 pph, from about 0.4 pph to about 0.6 pph, or any range or subrange therebetween. Providing an antioxidant can improve a color of the polymer-based portion and/or foldable apparatus, for example by decreasing yellowing as the polymer-based portion and/or foldable apparatus.

In aspects, the composition can be substantially solvent-free, solvent-free, and/or entirely solvent-free. As used herein, a composition is entirely solvent-free if it only contains components that participate in the curing reaction and/or are considered an inorganic filler, a photo-initiator, a catalyst, a silane coupling agent, or an antioxidant based on the above discussion. As used herein, a composition is solvent-free if it contains 99.5 wt % or more components that participate in the curing reaction and/or are considered a photo-initiator, a catalyst, or an antioxidant based on the above discussion. As used herein a composition is substantially solvent-free if it contains 98 wt % or more components that participate in the curing reaction and/or are considered a photo-initiator, a catalyst, or an antioxidant based on the above discussion. For example, water and octanol are considered solvents. Solvents can comprise one or more of a polar solvent (e.g., water, an alcohol, an acetate, acetone, formic acid, dimethylformamide, acetonitrile, dimethyl sulfoxone, nitromethane, propylene carbonate, poly(ether ether ketone)) or a non-polar solvent (e.g., pentane, 1,4-dioxane, chloroform, dichloromethane, diethyl ether, hexane, heptane, benzene, toluene, xylene). For example, a composition comprising up to 0.5 wt % solvent is considered to be both substantially solvent-free and solvent-free. Likewise, a composition containing no solvent is considered to be substantially solvent-free, solvent-free, and entirely solvent-free. Providing a composition that is substantially solvent-free (e.g., entirely solvent-free) can increase the curing rate of the composition, which can decrease processing time. Providing a composition that is substantially solvent-free (e.g., entirely solvent-free) can reduce (e.g., decrease, eliminate) the use of additives, for example, rheology modifiers, and increase composition homogeneity, which can improve the quality of the resulting polymer-based portion (e.g., increased transmittance, decreased haze, increased mechanical properties). Providing a composition that is substantially solvent-free (e.g., entirely solvent-free) can reduce a volume change as a result of curing (e.g., shrinkage). In aspects, the composition and/or the polymer-based portion can be substantially free of fluorine-based compounds and/or free of fluorine-based compounds, which can reduce an environmental impact of the polymer-based portion and/or reduce a cost to produce the polymer-based portion.

Example composition ranges of polymer-based portions and/or compositions including an acrylate and/or a urethane-acrylate oligomer in accordance aspects of the disclosure are presented in Table 1. R1 is the broadest of the ranges in Table 1. Ranges R1-R8 can comprise the multi-functional urethane-acrylate oligomer while Ranges R1 and R5-R8 can be free of the multi-functional urethane-acrylate oligomer. Ranges R1-R8 can comprise the multi-functional acrylate while Ranges R1-R4 can be free of the multi-functional acrylate. Ranges R3-R4 and R7-R8 are free of functionalized POSS. Ranges R2 and R5-R6 are free of silica nanoparticles. Again, it is to be understood that other ranges or subranges discussed above for these components can be used in combination with any of the ranges presented in Table 1.

TABLE 1
Composition ranges (wt %) of aspects of polymer-based portions

| Range | R1 | R2 | R3 | R4 | R5 | R6 | R7 | R8 |
|---|---|---|---|---|---|---|---|---|
| Multi-functional | 0-80 | 30-80 | 30-80 | 30-60 | 0-50 | 0-30 | 0-60 | 0-40 |
| (>=3) Urethane- | | | | | | | | |
| Acrylate Oligomer | | | | | | | | |
| Difunctional | 0-40 | 0-40 | 0-40 | 0-40 | 0-40 | 0-40 | 0-40 | 0-40 |
| Urethane-Acrylate | | | | | | | | |
| Oligomer | | | | | | | | |
| Multi-functional | 0-50 | 0-50 | 0-50 | 0-50 | 30-50 | 30-50 | 30-50 | 30-50 |
| (>=3) Acrylate | | | | | | | | |
| Difunctional | 0-40 | 0-40 | 0-40 | 20-40 | 0-40 | 20-40 | 0-40 | 20-40 |
| Acrylate | | | | | | | | |
| Reactive Diluent | 0-60 | 20-40 | 20-40 | 0-60 | 0-60 | 0-60 | 0-60 | 0-60 |
| Functionalized | 0-60 | 20-60 | 0 | 0 | 20-60 | 20-60 | 0 | 0 |
| POSS | | | | | | | | |
| Silica | 0-30 | 0 | 10-30 | 10-30 | 0 | 0 | 10-30 | 10-30 |
| Nanoparticles | | | | | | | | |
| Photo-initiator | 0-3 | 0.5-3 | 0.5-3 | 0-3 | 0.5-3 | 0.5-3 | 0-3 | 0.5-3 |
| | pph | pph | pph | pph | pph | pph | pph | pph |
| Silane Coupling | 0-10 | 0.5-5 | 1-5 | 0-10 | 0.5-5 | 0.1-5 | 0.5-5 | 0.5-5 |
| Agent | pph | pph | pph | pph | pph | pph | pph | pph |
| Antioxidant | 0-1 | 0.1-1 | 0.1-1 | 0-1 | 0.1-1 | 0.1-1 | 0-1 | 0.1-1 |
| | pph | pph | pph | pph | pph | pph | pph | pph |

Methods of forming the polymer-based portion including an epoxy and an inorganic filler. In aspects, the epoxy can be a multi-functional epoxy monomer (e.g., difunctional epoxy monomer). An exemplary aspect of a difunctional epoxy monomer is 3,4-epoxycyclohexylmethyl 3,4-epoxycyclohexanecarboxylate (e.g., S06E available from Synasia). In aspects, an amount of the multi-functional epoxy monomer (e.g., difunctional epoxy monomer), as a wt % of the composition, can be about 25 wt % or more, about 30 wt % or more, about 35 wt % or more, about 40 wt % or more, about 85 wt % or less, about 80 wt % or less, about 75 wt % or less, about 70 wt % or less, about 65 wt % or less, or about 60 wt % or less. In aspects, an amount of the multi-functional epoxy monomer (e.g., difunctional epoxy monomer), as a wt % of the composition, can range from about 25 wt % to about 85 wt %, from about 30 wt % to about 80 wt %, from about 35 wt % to about 75 wt %, from about 40 wt % to about 65 wt %, from about 40 wt % to about 60 wt %, or any range or subrange therebetween.

In aspects, the composition can comprise a reactive diluent. In further aspects, the reactive diluent can comprise a monofunctional epoxy. In further aspects, the reactive diluent can include CuraliteOx (available from Perstorp). In aspects, the reactive diluent can comprise 2 or more, 3 or more, or 4 or more different compounds that are each reactive diluents. In aspects, an amount of a reactive diluent, as a wt % of the composition, can be 0 wt % or more, about 10 wt % or more, about 15 wt % or more, about 20 wt % or more, about 25 wt % or more, about 30 wt % or more, about 45 wt % or less, about 40 wt % or less, about 35 wt % or less, or about 30 wt % or less, or about 25 wt % or less. In aspects, an amount of a reactive diluent, as a wt % of the composition, from 0 wt % to about 45 wt %, from about 10 wt % to about 40 wt %, from about 15 wt % to about 40 wt %, from about 20 wt % to about 40 wt %, from about 25 wt % to about 35 wt %, or any range or subrange therebetween.

The composition can comprise an inorganic filler. In aspects, the inorganic filler can comprise nanoparticles (e.g., silica nanoparticles), a functionalized oligomeric silsesquioxane (e.g., functionalized polyhedral oligomeric silsesquioxane (POSS)), or combinations thereof. In aspects, the composition can be substantially free and/or free of functionalized oligomeric silsesquioxanes while containing nanoparticles. Alternatively, in aspects, the composition can comprise functionalized oligomeric silsesquioxanes that can be in combination with silica nanoparticles or not. In aspects, an amount of the inorganic filler, as a wt % of the composition, can be 0 wt % or more, about 10 wt % or more, about 15 wt % or more, about 20 wt % or more, about 50 wt % or more, about 70 wt % or less, about 60 wt % or less, about 50 wt % or less, about 40 wt % or less, or about 30 wt % or less. In aspects, an amount of the inorganic filler, as a wt % of the composition, can range from 0 wt % to about 70 wt %, from about 10 wt % to about 60 wt %, from about 15 wt % to about 50 wt %, from about 20 wt % to about 40 wt %, or any range or subrange therebetween.

In aspects, the functionalized oligomeric silsesquioxane (e.g., functionalized POSS) can be functionalized by an epoxy functional group or a glycidyl functional group. In aspects, the composition can comprise the functionalized oligomeric silsesquioxanes (e.g., functionalized POSS) in an amount of about 15 wt % or more, about 30 wt % or more, about 40 wt % or more, about 45 wt % or more, about 50 wt % or more, about 70 wt % or less, about 60 wt % or less, about 55 wt % or less, about 50 wt % or less, or about 45 wt % or less. In aspects, the composition can comprise the functionalized oligomeric silsesquioxanes in a range from about 15 wt % to about 70 wt %, from about 30 wt % to about 60 wt %, from about 40 wt % to about 55 wt %, from about 30 wt % to about 50 wt %, from about 35 wt % to about 45 wt %, or any range or subrange therebetween.

In aspects, the nanoparticles (e.g., silica nanoparticles) can be dispersed in one of the other components of the compositions (e.g., epoxy, reactive diluent, etc.). As discussed above, the wt % of nanoparticles refers the content of nanoparticles excluding any material that the nanoparticles are dispersed in. In aspects, an amount of the silica nanoparticles, as a wt % of the composition, can be about 10% or more, about 15% or more, about 20% or more, about 22 wt % or more, about 30% or less, about 28% or less, about 26% or less, or about 25% or less. In aspects, an amount of the silica nanoparticles, as a wt % of the composition, can be in a range from about 10% to about 30%, from about 15% to about 28%, from about 20% to about 26%, from about 22% to about 24%, or any range or subrange therebetween. In aspects, a mean effective diameter of the silica nanoparticles can be about 20 nm or more, about 30 nm or more, about 100 nm or less, or about 50 nm or less. In aspects, a mean effective diameter in a range from about 20 nm to about 100 nm, from about 20 nm to about 50 nm, from about 30 nm to about 50 nm, or any range or subrange therebetween. In aspects, the silica nanoparticles may not be functionalized or bonded to a functionalized oligomeric silsesquioxane in the composition.

In aspects, the composition can comprise a photoinitiator, a silane coupling agent, and/or an antioxidant. In further aspects, an amount of the photoinitiator added by superaddition can be within one or more of the ranges discussed above for the amount of the photoinitiator. In further aspects, the silane coupling agent can be an acrylate silane and/or an epoxy silane. In further aspects, an amount of the silane coupling agent added by superaddition can be within one or more of the ranges discussed above for the amount of the silane coupling agent. In further aspects, an amount of the antioxidant added by superaddition can be within one or more of the ranges discussed above for the amount of the antioxidant. In aspects, the composition can be substantially solvent-free, solvent-free, and/or entirely solvent-free. In aspects, the composition and/or the polymer-based portion can be substantially free of fluorine-based compounds and/or free of fluorine-based compounds.

Example composition ranges of polymer-based portions and/or compositions including an epoxy and an inorganic filler in accordance aspects of the disclosure are presented in Table 2. R9 is the broadest of the ranges in Table 2. Ranges R9-R13 can the difunctional epoxy. Ranges R9-R13 can comprise a reactive diluent while ranges R9-R10 can be free of reactive diluents. Ranges R9-R11 include a functionalized POSS while Ranges R12-R13 are free of functionalized POSS. Ranges R9 and R12-R13 can include silica nanoparticles while Ranges R9-R11 can be free of silica nanoparticles. Again, it is to be understood that other ranges or subranges discussed above for these components can be used in combination with any of the ranges presented in Table 2.

TABLE 2
Composition ranges (wt %) of aspects of polymer-based portions

| Range | R9 | R10 | R11 | R12 | R13 |
|---|---|---|---|---|---|
| Difunctional | 30-85 | 30-85 | 30-65 | 30-85 | 30-65 |
| Epoxy | | | | | |
| Reactive | 0-45 | 0-45 | 20-40 | 0-45 | 20-40 |
| Diluent | | | | | |
| Functionalized | 15-70 | 15-70 | 15-70 | 0 | 0 |
| POSS | | | | | |
| Silica | 0-30 | 0 | 0 | 15-30 | 15-30 |
| Nanoparticles | | | | | |
| Photo-initiator | 0-3 | 0.5-3 | 0.5-3 | 0.5-3 | 0-3 |
| | pph | pph | pph | pph | pph |
| Silane | 0-10 | 0.5-5 | 0-10 | 0.5-5 | 0-10 |
| Coupling | pph | pph | pph | pph | pph |
| Agent | | | | | |
| Antioxidant | 0-1 | 0.1-1 | 0-1 | 0.1-1 | 0-1 |
| | pph | pph | pph | pph | pph |

Methods of forming the polymer-based portion can comprise curing the composition to form the polymer-based portion. In aspects, curing the composition to form the polymer-based portion can comprise heating, ultraviolet (UV) irradiation, and/or waiting for a predetermined period of time. In aspects where the composition comprises a photo-initiator, curing can comprise irradiating the composition with at least one wavelength of light that the photo-initiator is sensitive to. In aspects, the irradiating can comprise impinging the composition with a light beam emitted from a light source with a predetermined fluence. In further aspects, the light source can be configured to emit a light beam comprising an ultra-violet (UV) wavelength or a visible wavelength. In even further aspects, the wavelength of the light beam can be in a range from about 10 nm to about 400 nm, from about 100 nm to about 400 nm, from about 200 nm to about 400 nm, from about 10 nm to about 300 nm, from about 100 nm to about 300 nm, from about 200 nm to about 300 nm, from about 10 nm to about 200 nm, from about 100 nm to about 200 nm, or any range or subrange therebetween. In even further aspects, an operating wavelength range of the light source may be over a range of optical wavelengths from about 315 nm to about 400 nm, from about 280 nm to about 315 nm, from about 100 nm to about 280 nm, or from 122 nm to about 200 nm. In even further aspects, the wavelength of the light beam can be in a range from about 300 nm to about 1,000 nm, from about 350 nm to about 900 nm, from about 400 to about 800 nm, from about 500 nm to about 700 nm, or any range or subrange therebetween. In still further aspects, the wavelength of the light beam can be about 365 nm, about 415 nm, or about 590 nm. In further aspects, the predetermined fluence can be about 1 milliJoule per centimeter squared (mJ/cm²) or more, about 1.5 mJ/cm² or more, about 2 mJ/cm² or more, about 4 mJ/cm² or less, about 3 mJ/cm² or less, or about 2.5 mJ/cm² or less. In further aspects, the predetermined fluence can range from about 1 mJ/cm² to about 4 mJ/cm², from about 1.5 mJ/cm² to about 3 mJ/cm², from about 2 mJ/cm² to about 2.5 mJ/cm², or any range or subrange therebetween.

In aspects, curing can comprise heating the composition at a temperature for a time. As used herein, heating a composition “at a temperature” means that the composition is exposed to the temperature, for example, by being placed in an oven. In further aspects, the temperature can be about 80° C. or more, about 100° C. or more, about 120° C. or more, about 140° C. or more, about 250° C. or less, about 200° C. or less, about 180° C. or less, or about 160° C. or less. In further aspects, the temperature can be in a range from about 80° C. to about 250° C., from about 80° C. to about 200° C., from about 100° C. to about 200° C., from about 100° C. to about 180° C., from about 120° C. to about 180° C., from about 120° C. to about 160° C., from about 140° C. to about 160° C., or any range or subrange therebetween. In further aspects, the time can be about 15 minutes or more, about 30 minutes or more, 1 hour or more about 12 hours or less, about 6 hours or less, about 3 hours or less, or about 2 hours or less. In further aspects, the time can be in a range from about 15 minutes to about 12 hours, from about 15 minutes to about 6 hours, from about 15 minutes to about 3 hours, from about 30 minutes to about 3 hours, from about 1 hour to about 3 hours, from about 1 hour to about 2 hours, or any range or subrange therebetween.

In aspects, curing the composition to form the polymer-based material can result in a volume change of the polymer-based portion relative to a volume of the composition. In further aspects, a magnitude of a difference of the volume of the polymer-based portion relative to the volume of the composition as a percentage of the volume of the composition can be about 5% or less, about 2% or less, about 1% or less, about 0.5% or less, about 0.1% or less, about 0.01% or more, about 0.1% or more, about 0.5% or more, about 1% or more. In further aspects, a magnitude of a difference of the volume of the polymer-based portion relative to the volume of the composition as a percentage of the volume of the composition can be in a range from 0% to about 5%, from 0% to about 2%, from 0% to about 1%, from 0.01% to about 1%, from about 0.1% to about 1%, from about 0.5% to about 1%, from about 0.01% to about 5%, from about 0.01% to about 2%, from about 0.1% to about 2%, from about 0.5% to about 2%, or any range or subrange therebetween.

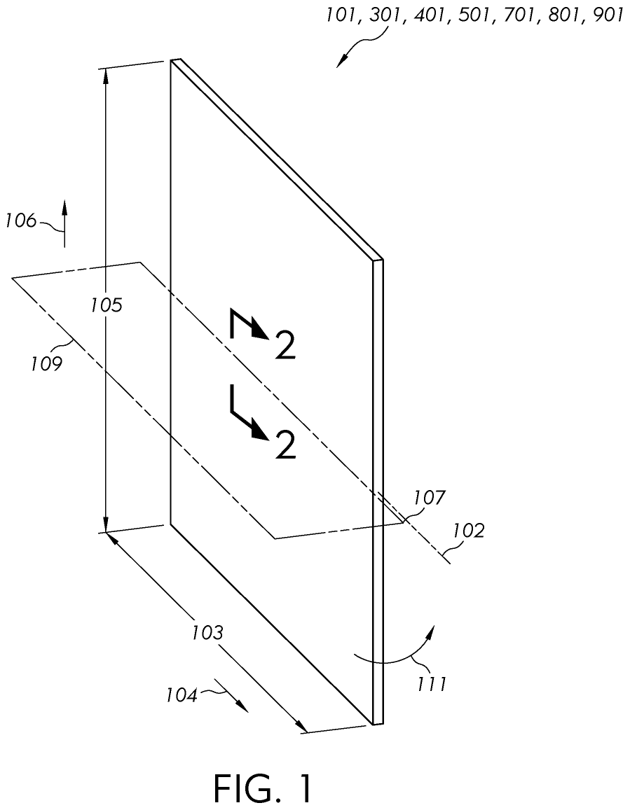

Aspects will now be described more fully hereinafter with reference to the accompanying drawings in which example aspects are shown. Whenever possible, the same reference numerals are used throughout the drawings to refer to the same or like parts. FIGS. 1-4, 6-7, and 9 illustrate views of foldable apparatus 101, 301, 401, 501, 701, and 901 comprising a foldable substrate 201 in accordance with aspects of the disclosure. Unless otherwise noted, a discussion of features of aspects of one foldable apparatus can apply equally to corresponding features of any aspects of the disclosure. For example, identical part numbers throughout the disclosure can indicate that, in some aspects, the identified features are identical to one another and that the discussion of the identified feature of one aspect, unless otherwise noted, can apply equally to the identified feature of any of the other aspects of the disclosure.

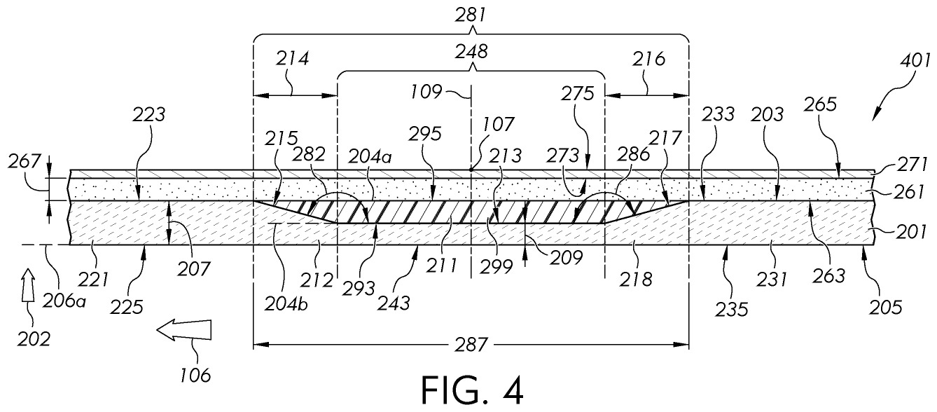

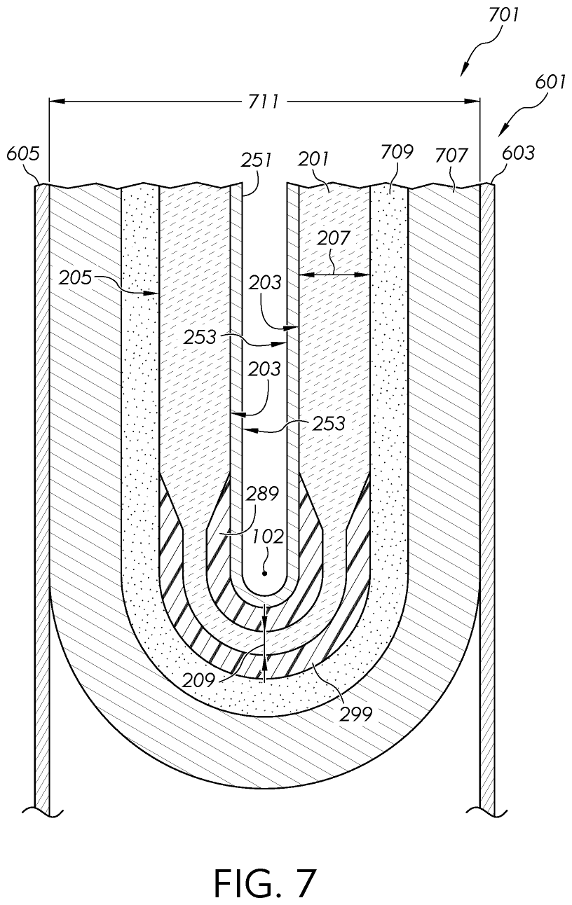

FIGS. 2-4 schematically illustrate example aspects of foldable apparatus 101, 301, and 401 comprising the foldable substrate 201 in accordance with aspects of the disclosure in an unfolded (e.g., flat) configuration while FIGS. 6-7 and 9 illustrates an example aspect of a foldable apparatus 501, 701, and 901 comprising the foldable substrate 201 in accordance with aspects of the disclosure in a folded configuration. FIG. 3 schematically illustrate example aspects of foldable apparatus 301 consisting of the foldable substrate 201 in accordance with aspects of the disclosure in an unfolded (e.g., flat) configuration. The foldable apparatus 101, 301, and 401 and the foldable substrate 201 comprise a first portion 221, a second portion 231, and a central portion 281 positioned between the first portion 221 and the second portion 231. In aspects, as shown in FIGS. 2 and 4, the foldable apparatus 101 and 401 can comprise a release liner 271 although other substrates (e.g., a glass-based substrate and/or a ceramic-based substrate discussed throughout the application) may be used in further aspects rather than with the illustrated release liner 271. In aspects, as shown in FIGS. 2 and 7, the foldable apparatus 101 and 701 can comprise a coating 251. In aspects, as shown in FIGS. 2 and 4, the foldable apparatus 101 can comprise an adhesive layer 261. In aspects, as shown in FIGS. 2 and 7, foldable apparatus 101 and 701 can comprise a polymer-based portion 289 and/or 299. As shown in FIGS. 2-4, the foldable substrate 201 can comprise a first recess 211. In aspects, as shown in FIGS. 2-3, the foldable substrate 201 can further comprise a second recess 241. It is to be understood that any of the foldable apparatus of the disclosure can comprise a second substrate (e.g., a glass-based substrate and/or a ceramic-based substrate), a release liner 271, a display device, a coating 251, an adhesive layer 261, and/or a polymer-based portion 289 and/or 299.

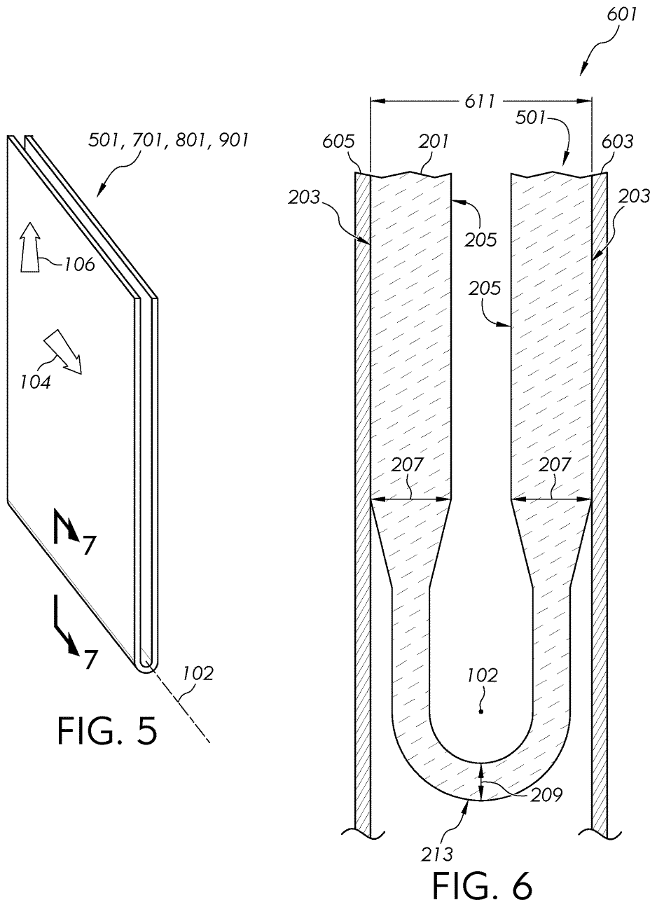

Throughout the disclosure, with reference to FIG. 1, the width 103 of the foldable apparatus 101, 301, 401, 501, 701, and/or 901 is considered the dimension of the foldable apparatus taken between opposed edges of the foldable apparatus in a direction 104 of a fold axis 102 of the foldable apparatus, wherein the direction 104 also comprises the direction of the width 103. Furthermore, throughout the disclosure, the length 105 of the foldable apparatus is considered the dimension of the foldable apparatus taken between opposed edges of the foldable apparatus in a direction 106 perpendicular to the fold axis 102 of the foldable apparatus. It is to be understood that the direction 104 of the width 103 and/or the direction 106 of the length 105 can correspond to corresponding directions in the foldable substrate 201. In aspects, as shown in FIGS. 1-2, the foldable apparatus of any aspects of the disclosure can comprise a fold plane 109 that includes the fold axis 102 when the foldable apparatus is in the flat configuration (see FIG. 2). In further aspects, as shown in FIG. 2, the fold plane 109 can extend along the fold axis 102 and in a direction of the substrate thickness 207 when the foldable apparatus is in the flat configuration (see FIG. 2). The fold plane 109 may comprise a central axis 107 of the foldable apparatus. In aspects, the foldable apparatus can be folded in a direction 111 (see FIG. 1) about the fold axis 102 extending in the direction 104 of the width 103 to form a folded configuration (see FIGS. 5, 7, and 9). As shown, the foldable apparatus and/or the foldable substrate may include a single fold axis to allow the foldable apparatus and/or the foldable substrate to comprise a bifold wherein, for example, the foldable apparatus and/or the foldable substrate may be folded in half. In further aspects, the foldable apparatus and/or the foldable substrate may include two or more fold axes with each fold axis including a corresponding central portion similar or identical to the central portion 281 discussed herein. For example, providing two fold axes can allow the foldable apparatus and/or the foldable substrate to comprise a trifold wherein, for example, the foldable apparatus and/or the foldable substrate may be folded with the first portion 221, the second portion 231, and a third portion similar or identical to the first portion or second portion with the central portion 281 and another central portion similar to or identical to the central portion positioned between the first portion and the second portion and between the second portion and the third portion, respectively.

The foldable substrate 201 can comprise a glass-based substrate and/or a ceramic-based substrate having a pencil hardness of 8H or more, for example, 9H or more. As used herein, pencil hardness is measured using ASTM D3363-20 with standard lead graded pencils. Providing a glass-based foldable substrate and/or a ceramic-based foldable substrate can enhance puncture resistance and/or impact resistance. Throughout the disclosure, an elastic modulus (e.g., Young's modulus) is measured using ISO 527-1:2019. In aspects, the foldable substrate 201 can comprise an elastic modulus in a range from about 10 GPa to about 150 GPa, from about 40 GPa to about 100 GPa, from about 60 GPa to about 80 GPa, or any range or subrange therebetween.

In aspects, the foldable substrate 201 can comprise a glass-based substrate. As used herein, “glass-based” includes both glasses and glass-ceramics, wherein glass-ceramics have one or more crystalline phases and an amorphous, residual glass phase. A glass-based material (e.g., glass-based substrate) may comprise an amorphous material (e.g., glass) and optionally one or more crystalline materials (e.g., ceramic). Amorphous materials and glass-based materials may be strengthened. As used herein, the term “strengthened” may refer to a material that has been chemically strengthened, for example, through ion exchange of larger ions for smaller ions in the surface of the substrate, as discussed below. However, other strengthening methods, for example, thermal tempering, or utilizing a mismatch of the coefficient of thermal expansion between portions of the substrate to create compressive stress and central tension regions, may be utilized to form strengthened substrates. Exemplary glass-based materials, which may be free of lithia or not, comprise soda lime glass, alkali aluminosilicate glass, alkali-containing borosilicate glass, alkali-containing aluminoborosilicate glass, alkali-containing phosphosilicate glass, and alkali-containing aluminophosphosilicate glass. In aspects, glass-based material can comprise an alkali-containing glass or an alkali-free glass, either of which may be free of lithia or not. In aspects, the glass material can be alkali-free and/or comprise a low content of alkali metals (e.g., R₂O of about 10 mol % or less, wherein R₂O comprises Li₂O Na₂O, K₂O, or the more expansive list provided below). In one or more aspects, a glass-based material may comprise, in mole percent (mol %):SiO₂ in a range from about 40 mol % to about 80%, Al₂O₃ in a range from about 5 mol % to about 30 mol %, B₂O₃ in a range from 0 mol % to about 10 mol %, ZrO₂ in a range from 0 mol % to about 5 mol %, P₂O₅ in a range from 0 mol % to about 15 mol %, TiO₂ in a range from 0 mol % to about 2 mol %, R2O in a range from 0 mol % to about 20 mol %, and RO in a range from 0 mol % to about 15 mol %. As used herein, R2O can refer to an alkali-metal oxide, for example, Li₂O, Na₂O, K₂O, Rb₂O, and Cs₂O. As used herein, RO can refer to MgO, CaO, SrO, BaO, and ZnO. “Glass-ceramics” include materials produced through controlled crystallization of glass. In aspects, glass-ceramics have about 1% to about 99% crystallinity. Examples of suitable glass-ceramics may include Li₂O—Al₂O₃—SiO₂ system (i.e., LAS-System) glass-ceramics, MgO—Al₂O₃—SiO₂ system (i.e., MAS-System) glass-ceramics, ZnO×Al₂O₃×nSiO₂ (i.e., ZAS system), and/or glass-ceramics that include a predominant crystal phase including β-quartz solid solution, β-spodumene, cordierite, petalite, and/or lithium disilicate. The glass-ceramic substrates may be strengthened using the chemical strengthening processes. In one or more aspects, MAS-System glass-ceramic substrates may be strengthened in Li₂SO₄ molten salt, whereby an exchange of 2Li⁺ for Mg²⁺ can occur.

In aspects, the foldable substrate 201 can comprise a ceramic-based substrate. As used herein, “ceramic-based” includes both ceramics and glass-ceramics, wherein glass-ceramics have one or more crystalline phases and an amorphous, residual glass phase. Ceramic-based materials may be strengthened (e.g., chemically strengthened). In aspects, a ceramic-based material can be formed by heating a glass-based material to form ceramic (e.g., crystalline) portions. In further aspects, ceramic-based materials may comprise one or more nucleating agents that can facilitate the formation of crystalline phase(s). In aspects, ceramic-based materials can comprise one or more oxides, nitrides, oxynitrides, carbides, borides, and/or silicides. Example aspects of ceramic oxides include zirconia (ZrO₂), zircon (ZrSiO₄), titania (TiO₂), hafnium oxide (Hf₂O), yttrium oxide (Y₂O₃), iron oxides, beryllium oxides, vanadium oxide (VO₂), fused quartz, cristobalite, mullite (a mineral comprising a combination of aluminum oxide and silicon dioxide), and spinel (MgAl₂O₄). Example aspects of ceramic nitrides include silicon nitride (Si₃N₄), aluminum nitride (AlN), gallium nitride (GaN), beryllium nitride (Be₃N₂), boron nitride (BN), tungsten nitride (WN), vanadium nitride, alkali earth metal nitrides (e.g., magnesium nitride (Mg₃N₂)), nickel nitride, and tantalum nitride. Example aspects of oxynitride ceramics include silicon oxynitride, aluminum oxynitride, and a SiAlON (a combination of alumina and silicon nitride and can have a chemical formula, for example, Si₁₂₋ₘ₋ₙAlₘ₊ₙOₙN₁₆₋ₙ, Si₆₋ₙAlₙOₙN₈₋ₙ, or Si₂₋ₙAlₙO₁₊ₙN₂₋ₙ, where m, n, and the resulting subscripts are all non-negative integers).

In aspects, the foldable substrate 201 can be optically transparent. As used herein, “optically transparent” or “optically clear” means an average transmittance of 70% or more in the wavelength range of 400 nm to 700 nm through a 1.0 mm thick piece of a material. In aspects, the foldable substrate 201 may have an average transmittance of 75% or more, 80% or more, 85% or more, or 90% or more, 92% or more, 94% or more, 96% or more in the wavelength range of 400 nm to 700 nm through a 1.0 mm thick piece of the material. The average transmittance in the wavelength range of 400 nm to 700 nm is calculated by measuring the transmittance of whole number wavelengths from about 400 nm to about 700 nm and averaging the measurements.

As shown in FIGS. 2-4, the foldable apparatus 101, 301, and 401 comprise the foldable substrate 201 comprising a first major surface 203 and a second major surface 205 opposite the first major surface 203. As shown in FIGS. 2-4, the first major surface 203 can extend along a first plane 204a. The second major surface 205 can extend along a second plane 206a. In aspects, as shown, the second plane 206a can be parallel to the first plane 204a. As used herein, a substrate thickness 207 can be defined between the first major surface 203 and the second major surface 205 as a distance between the first plane 204a and the second plane 206a. In aspects, the substrate thickness 207 can be about 10 micrometers (μm) or more, about 25 μm or more, about 50 μm or more, about 70 μm or more, about 80 μm or more, about 90 μm or more, about 100 μm or more, about 125 μm or more, about 150 μm or more, about 200 μm or more, about 300 μm or more, about 2 millimeters (mm) or less, about 1 mm or less, about 800 μm or less, about 500 μm or less, about 300 μm or less, about 200 μm or less, about 180 μm or less, or about 160 μm or less. In aspects, the substrate thickness 207 can range from about 10 μm to about 2 mm, from about 25 μm to about 2 mm, from about 50 μm to about 2 mm, from about 70 μm to about 2 mm, from about 70 μm to about 1 mm, from about 70 μm to about 800 μm, from about 80 μm to about 500 μm, from about 90 μm 500 μm, from about 100 μm to about 200 μm, from about 125 μm to about 200 μm, from about 150 μm to about 200 μm, or any range or subrange therebetween.

As shown in FIGS. 2-4, the first portion 221 of the foldable substrate 201 can comprise a first surface area 223 and a second surface area 225 opposite the first surface area 223. The first portion 221 will now be described with reference to the foldable apparatus 101 of FIG. 2 with the understanding that such description of the first portion 221, unless otherwise stated, can also apply to any aspects of the disclosure, for example, the foldable apparatus 301, 401, 501, 701, and/or 901 illustrated in FIGS. 3-4, 6-7, and 9. In aspects, as shown, the first surface area 223 can comprise a planar surface, and/or the second surface area 225 of the first portion 221 can comprise a planar surface. In further aspects, as shown, the second surface area 225 can be parallel to the first surface area 223. In aspects, as shown, the first major surface 203 can comprise the first surface area 223 and the second major surface 205 can comprise the second surface area 225. In further aspects, the first surface area 223 can extend along the first plane 204a. In further aspects, the second surface area 225 can extend along the second plane 206a. In aspects, the substrate thickness 207 can correspond to the distance between the first surface area 223 of the first portion 221 and the second surface area 225 of the first portion 221. In aspects, the substrate thickness 207 can be substantially uniform across the first surface area 223. In aspects, a first thickness defined between the first surface area 223 and the second surface area 225 can be within one or more of the ranges discussed above with regards to the substrate thickness 207. In further aspects, the first thickness can comprise the substrate thickness 207. In further aspects, the first thickness of the first portion 221 may be substantially uniform between the first surface area 223 and the second surface area 225 across its corresponding length (i.e., in the direction 106 of the length 105 of the foldable apparatus) and/or its corresponding width (i.e., in the direction 104 of the width 103 of the foldable apparatus).

As shown in FIGS. 2-4, the second portion 231 of the foldable substrate 201 can comprise a third surface area 233 and a fourth surface area 235 opposite the third surface area 233. The second portion 231 will now be described with reference to the foldable apparatus 101 of FIG. 2 with the understanding that such description of the second portion 231, unless otherwise stated, can also apply to any aspects of the disclosure, for example, the foldable apparatus 301, 401, 501, 701, and/or 901 illustrated in FIGS. 3-4, 6-7, and 9. In aspects, as shown, the third surface area 233 of the second portion 231 can comprise a planar surface, and/or the fourth surface area 235 of the second portion 231 can comprise a planar surface. In further aspects, the third surface area 233 of the second portion 231 can be in a common plane with the first surface area 223 of the first portion 221. In further aspects, as shown, the fourth surface area 235 can be parallel to the third surface area 233. In further aspects, the fourth surface area 235 of the second portion 231 can be in a common plane with the second surface area 225 of the first portion 221. A second thickness can be defined between the third surface area 233 of the second portion 231 and the fourth surface area 235 of the second portion 231. In aspects, the second thickness can be within the range discussed above with regards to the substrate thickness 207. In further aspects, the second thickness can comprise the substrate thickness 207 and/or be substantially equal to the substrate thickness 207 (e.g., first thickness). In aspects, the second thickness of the second portion 231 may be substantially uniform between the third surface area 233 and the fourth surface area 235.

As shown in FIGS. 2-4, the foldable substrate 201 can comprise a central portion 281 positioned between the first portion 221 and the second portion 231. The central portion 281 comprises a first central surface area 213 and a second central surface area 243 opposite the first central surface area 213. As shown, the first central surface area 213 can be positioned between the first surface area 223 and the third surface area 233. In further aspects, the first central surface area 213 can correspond to a central region 248 of the central portion 281. In further aspects, as shown, the first central surface area 213 can extend along a third plane 204b when the foldable apparatus 101, 301, and/or 401 is in a flat configuration. A first recess 211 can be defined between the first central surface area 213 (e.g., third plane 204b) and the first plane 204a.

In aspects, the third plane 204b can be substantially parallel to the first plane 204a and/or the second plane 206a. In further aspects, as shown in FIGS. 2-3, the first central surface area 213 can be recessed from the first major surface 203 by a first distance 219. In further aspects, the first distance 219 that the first central surface area 213 is recessed from the first plane 204a can be about 5 μm or more, about 10 μm or more, about 25 μm or more, about 40 μm or more, about 80 μm or more, about 100 μm or more, about 125 μm or more, about 150 μm or more, about 1 mm or less, about 800 μm or less, about 500 μm or less, about 300 μm or less, about 200 μm or less, about 180 μm or less, or about 150 μm or less. In further aspects, the first distance 219 can range from about 5 μm to about 1 mm, from about 5 μm to about 500 μm, from about 10 μm to about 300 μm, from about 25 μm to about 200 μm, from about 40 μm to about 200 μm, from about 80 μm to about 200 μm, from about 100 μm to about 180 μm, from about 125 μm to about 150 μm, or any range or subrange therebetween. In further aspects, the first distance 219, as a percentage of the substrate thickness 207, can be about 1% or more, about 5% or more, about 10% or more, about 15% or more, about 20% or more, about 25% or more, about 75% or less, about 60% or less, about 50% or less, about 40% or less, about 35% or less, or about 30% or less. In further aspects, the first distance 219, as a percentage of the substrate thickness 207, can range from about 1% to about 75%, from about 1% to about 60%, from about 5% to about 60%, from about 10% to about 50%, from about 15% to about 45%, from about 20% to about 35%, from about 25% to about 30%, or any range or subrange therebetween.

As shown in FIGS. 2-4, the second central surface area 243 of the central portion 281 is positioned between the second surface area 225 and the fourth surface area 235. In aspects, as shown in FIGS. 2-3, the second central surface area 243 can extend along a fourth plane 206b when the foldable apparatus 101 and/or 301 is in a flat configuration. In further aspects, a second recess 241 is defined between the second central surface area 243 (e.g., fourth plane 206b) and the second plane 206a. As shown in FIG. 4, the second central surface area 243 can extend along the second plane 206a.

In aspects, as shown in FIGS. 2-3, the second central surface area 243 can be recessed from the second major surface 205 by a second distance 249. In further aspects, the second distance 249 can be within one or more of the ranges discussed above for the first distance 219. In further aspects, the first distance can be greater than the second distance. In even further aspects, the second distance 249 that the second central surface area 243 is recessed from the second plane 206a, as a percentage of the substrate thickness 207, can be about 1% or more, about 2% or more, about 5% or more, about 10% or more, about 12% or more, about 30% or less, about 25% or less, about 20% or less, about 18% or less, or about 15% or less. In even further aspects, the second distance 249, as a percentage of the substrate thickness 207, can range from about 1% to about 30%, from about 2% to about 25%, from about 5% to about 20%, from about 10% to about 18%, from about 12% to about 15%, or any range or subrange therebetween. In further aspects, as shown in FIG. 2, the first distance 219 can be substantially equal to the second distance 249. Providing the first distance substantially equal to the second distance can further reduce the incidence of mechanical instabilities in the central portion, for example, because the foldable substrate is symmetric about a plane comprising a midpoint in the substrate thickness and the central thickness. In further aspects, as shown in FIG. 4, the second central surface area 243 can be coplanar with the second surface area 225 and/or the fourth surface area 235, for example, forming a planar second major surface 205 extending along the second plane 206a.

A central thickness 209 can be defined between the first central surface area 213 and the second central surface area 243 as the distance between the third plane 204b and the fourth plane 206b. In aspects, the central thickness 209 can be about 10 μm or more, about 25 μm or more, about 40 μm or more, about 120 μm or less, about 100 μm or less, about 80 μm or less, about 60 μm or less, or about 50 μm or less. In aspects, the central thickness 209 can range from about 10 μm to about 120 μm, from about 10 μm to about 100 μm, from about 25 μm to about 80 μm, from about 40 μm to about 60 μm, or any range or subrange therebetween. In aspects, the central thickness 209 can be less than the substrate thickness 207 by about 10 μm or more, about 20 μm or more, about 30 μm or more, about 40 μm or more, about 50 μm or more, or about 60 μm or more. In aspects, the central thickness 209 as a percentage of the substrate thickness 207 can be about 0.5% or more, about 1% or more, about 2% or more, about 5% or more, about 40% or less, about 30% or less, about 20% or less, about 13% or less, about 10% or less, or about 8% or less. In aspects, the central thickness 209 as a percentage of the substrate thickness 207 can range from about 0.5% to about 40%, from about 0.5% to about 20%, from about 1% to about 13%, from about 2% to about 10%, from about 5% to about 8%, or any range or subrange therebetween. In aspects, the central region 248 of the central portion 281 can correspond to a region comprising the central thickness 209. By providing the first central surface area 213 of the central portion 281 extending along the third plane 204b parallel to the second central surface area 243 of the central portion 281 extending along the fourth plane 206b, a uniform central thickness 209 may extend across the central portion 281 that can provide enhanced folding performance at a predetermined thickness for the central thickness 209. A uniform central thickness 209 across the central portion 281 can improve folding performance by preventing stress concentrations that would occur if a portion of the central portion 281 was thinner than the rest of the central portion 281.

In aspects, as shown in FIGS. 2-4, the central portion 281 of the foldable substrate 201 can comprise a first transition region 212 comprising a first transition surface area 215 extending between the first surface area 223 and the first central surface area 213. In further aspects, as shown, a width (e.g., first transition width 214) of the first transition region 212 corresponding to the minimum distance in a direction 106 of the length 105 (see FIG. 1) between a portion of the first central surface area 213 extending along the third plane 204b and a portion of the first surface area 223. In even further aspects, the first transition width 214 of the first transition region 212 can be about 0.15 mm or more, about 0.3 mm or more, about 0.5 mm or more, about 0.6 mm or more, about 0.7 mm or more, about 0.8 mm or more, about 2 mm or less, about 1.8 mm or less, about 1.5 mm or less, about 1.2 mm or less, about 1 mm or less, about 0.8 mm or less, about 0.7 mm or less, or about 0.5 mm or less. In even further aspects, the first transition width 214 of the first transition region 212 can range from about 0.15 mm to about 2 mm, from about 0.3 mm to about 2 mm, from about 0.5 mm to about 1.8 mm, from about 0.6 mm to about 1.5 mm, from about 0.7 mm to about 1.2 mm, from about 0.8 mm to about 1 mm, or any range or subrange therebetween. In aspects, as shown in FIGS. 2-3, the first transition region 212 can comprise a second transition surface area 245 extending between the second surface area 225 and the second central surface area 243. A width of the second transition surface area 245 corresponding to the minimum distance in a direction 106 of the length 105 (see FIG. 1) between a portion of the second central surface area 243 extending along the fourth plane 206b and a portion of the second surface area 225 can be within one or more of the ranges discussed above for the first transition width 214 and/or substantially equal to the first transition width 214.

In aspects, as shown in FIGS. 2-4, a thickness of the first transition region 212 can decrease between the substrate thickness 207 of the first portion 221 and the central thickness 209 of the central portion 281. In further aspects, as shown, a thickness of the first transition region 212 can smoothly decrease, monotonically decrease, and/or smoothly and monotonically decrease between the substrate thickness 207 of the first portion 221 and the central thickness 209 of the central portion 281. As used herein, a thickness decreases smoothly if changes in the cross-sectional area are smooth (e.g., gradual) rather than abrupt (e.g., step) changes in thickness. As used herein, a thickness decreases monotonically in a direction if the thickness decreases for a portion and for the rest of the time either stays the same, decreases, or a combination thereof (i.e., the thickness decreases but never increases in the direction). A smooth shape of the first transition region and/or the second transition region can reduce optical distortions.

In aspects, as shown in FIGS. 2-4, the first transition surface area 215 can comprise a linearly inclined surface extending between the first central surface area 213 and the first surface area 223. In aspects, although not shown, the first transition surface area can comprise a concave up shape, for example, with a local slope of the first transition surface area smoothly transitioning to a slope of the first central surface area 213 while a local slope of the first transition surface area is substantially different from a slope of the first surface area 223. In aspects, although not shown, the first transition surface area can comprise a sigmoid shape. In aspects, although not shown, a local slope of the first transition surface area can be greater at a midpoint of the first transition surface area than where the first transition surface area meets the first central surface area 213 and where the first transition surface area meets the first surface area 223. In aspects, although not shown, the first transition surface area can comprise a convex up shape, for example, with a local slope of the first transition surface area smoothly transitioning to a slope of the first surface area 223 while a local slope of the first transition surface area is substantially different from a slope of the first central surface area 213. In aspects, the second transition surface area can comprise one of the shapes or properties discussed above in this paragraph for the first transition surface area. For example, as shown in FIG. 2, the second transition surface area 245 can comprise a linearly inclined surface extending between the second central surface area 243 and the second surface area 225.

In aspects, as shown in FIGS. 2-4, a thickness of the first transition region 212 can decrease at a constant rate (e.g., linearly change) from the substrate thickness 207 to the central thickness 209. In aspects, although not shown, a thickness of the first transition region can decrease slower where the first transition surface area meets the first central surface area 213 than at a midpoint of the first transition region and/or than where the first transition surface area meets the first surface area 223 (e.g., first portion 221). In aspects, although not shown, a thickness of the first transition region can decrease faster where the first transition surface area meets the first central surface area 213 than at a midpoint of the first transition region and/or than where the first transition surface area meets the first surface area 223. Providing a non-uniform slope of a surface area of the first transition region and/or the second transition region can reduce an amount of the corresponding transition region comprising intermediate thicknesses, for example, comprising a chemical strengthening induced expansion strain less than a portion of the corresponding transition region closer to the first central surface area and/or the second central surface area and/or than the first central surface area and/or the second central surface area.

Throughout the disclosure, an average angle of a transition surface area relative to a central surface area is measured as an angle between a transition surface area and a central surface area. An angle is calculated for a location on the corresponding transition surface area relative to the corresponding central surface area with the location of the corresponding central surface area approximated as a plane fitted from measurements at 20 locations evenly spaced over the corresponding central surface area in the direction 106 of the length 105. The angle measured is an external angle for the foldable substrate, meaning that it extends from the plane fitted to the corresponding central surface area to the location on the corresponding transition surface area without passing through the material of the foldable substrate other than an incidental amount at the endpoints. The average angle is calculated from 10 locations on the corresponding transition surface area that are located in a region comprising 80% of a distance that the corresponding central surface area is recessed from the corresponding major surface with the region centered at the midpoint between the corresponding central surface area and the corresponding major surface in the direction 202 of the thickness (e.g., substrate thickness 207, central thickness 209). In aspects, as shown in FIGS. 2-4, the first transition surface area 215 of the first transition region 212 extends between the first surface area 223 and the first central surface area 213 with a first average angle 282 relative to the first central surface area 213. As described above, the first average angle 282 is an external angle because it does not pass through the material of the foldable substrate 201 other than an incidental amount at the endpoints. In further aspects, the first average angle 282 can be about 160° or more, about 162° or more, about 165° or more, about 167° or more, about 170° or more, about 171° or more, about 172° or more, about 179° or less, about 176° or less, about 175° or less, about 174° or less, or about 173° or less. In further aspects, the first average angle 282 can range from about 160° to about 179°, from about 162° to about 176°, from about 165° to about 176°, from about 167° to about 175°, from about 170° to about 175°, from about 171° to about 174°, from about 172° to about 173°, or any range or subrange therebetween. For example, a first transition surface comprising a linear (e.g., planar) surface area with a first transition width of 500 μm and height (i.e., a difference between the first central surface area 213 and the first major surface 203 corresponding to the first distance 219) of 30 μm corresponds to a first average angle of about 176.6°.

In aspects, as shown in FIGS. 2-4, the third transition surface area 217 of the second transition region 218 extends between the third surface area 233 and the first central surface area 213 with a third average angle 286 relative to the first central surface area 213. In further aspects, the third average angle 286 can be within one or more of the ranges discussed above for the first average angle 282. In further aspects, the first average angle 282 can be substantially equal to the third average angle 286.

In aspects, as shown in FIGS. 2-4, the central portion 281 of the foldable substrate 201 can comprise a second transition region 218 comprising a third transition surface area 217 extending between the third surface area 233 and the first central surface area 213. In further aspects, as shown, a width (e.g., second transition width 216) of the second transition region 218 can be measured as the minimum distance in a direction 106 of the length 105 (see FIG. 1) between a portion of the first central surface area 213 extending along the third plane 204b and a portion of the third surface area 233. In even further aspects, the second transition width 216 of the second transition region 218 can be within one or more of the ranges discussed above for the first transition width 214. In still further aspects, the second transition width 216 of the second transition region 218 can be substantially equal to (e.g., equal to) the first transition width 214.

In aspects, as shown in FIGS. 2-3, the second transition region 218 can comprise a fourth transition surface area 247 extending between the fourth surface area 235 and the second central surface area 243. In further aspects, a width of the fourth transition surface area 247 can be measured as the minimum distance in a direction 106 of the length 105 (see FIG. 1) between a portion of the second central surface area 243 extending along the fourth plane 206b and a portion of the fourth surface area 235. In even further aspects, the width of the fourth transition surface area 247 can be substantially equal to (e.g., equal to) the second transition width 216. In aspects, as shown in FIGS. 2-3, a thickness of the second transition region 218 can decrease between the substrate thickness 207 of the second portion 231 and the central thickness 209 of the central portion 281. In further aspects, as shown, a thickness of the first transition region 212 can smoothly decrease, monotonically decrease, or smoothly and monotonically decrease between the substrate thickness 207 of the second portion 231 and the central thickness 209 of the central portion 281. In aspects, as shown in FIG. 4, the portion of the second transition region 218 extending between the fourth surface area 235 and the second central surface area 243 can be coplanar with one or both surface areas.

In aspects, as shown in FIGS. 2-4, the third transition surface area 217 can comprise a linearly inclined surface extending between the first central surface area 213 and the third surface area 233. In aspects, the third transition surface area 217 and/or the fourth transition surface area 247 can comprise one of the shapes or properties discussed above with reference to the first transition surface area. In aspects, the fourth transition surface area 247 can comprise one of the shapes or properties discussed above in this paragraph for the first transition surface area. For example, as shown in FIGS. 2-4, the fourth transition surface area 247 can comprise a linearly inclined surface extending between the second central surface area 243 and the fourth surface area 235. In aspects, as shown in FIGS. 2-4, a thickness of the second transition region 218 can decrease at a constant rate (e.g., linearly change) from the substrate thickness 207 to the central thickness 209. In aspects, although not shown, a thickness of the second transition region can decrease slower where the third transition surface area meets the first central surface area 213 than at a midpoint of the second transition region and/or than where the third transition surface area meets the third surface area 233 (e.g., first portion 221). In aspects, although not shown, a thickness of the second transition region can decrease faster where the third transition surface area meets the first central surface area 213 than at a midpoint of the second transition region and/or than where the third transition surface area meets the third surface area 233.

In aspects, as shown in FIGS. 2-3, the second transition surface area 245 of the first transition region 212 extends between the second surface area 225 and the second central surface area 243 with a second average angle 284 relative to the second central surface area 243. In further aspects, the second average angle 284 can be within one or more of the ranges discussed above for the first average angle 282 and/or substantially equal to the first average angle 282. Providing an average angle within one of the above-mentioned ranges can provide reduced visibility of the transition region. In aspects, as shown in FIGS. 2-3, the fourth transition surface area 247 of the second transition region 218 extends between the fourth surface area 235 and the second central surface area 243 with a fourth average angle 288 relative to the second central surface area 243. In further aspects, the fourth average angle 288 can be within one or more of the ranges discussed above for the second average angle 284. In further aspects, the second average angle 284 can be substantially equal to the fourth average angle 288. In further aspects, the first average angle 282 and/or the third average angle 286 can be substantially equal to the fourth average angle 288.

As used herein, if a first layer and/or component is described as “disposed over” a second layer and/or component, other layers may or may not be present between the first layer and/or component and the second layer and/or component. Furthermore, as used herein, “disposed over” does not refer to a relative position with reference to gravity. For example, a first layer and/or component can be considered “disposed over” a second layer and/or component, for example, when the first layer and/or component is positioned underneath, above, or to one side of a second layer and/or component. As used herein, a first layer and/or component described as “bonded to” a second layer and/or component means that the layers and/or components are bonded to each other, either by direct contact and/or bonding between the two layers and/or components or via an adhesive layer. As used herein, a first layer and/or component described as “contacting” or “in contact with” a second layer and/or components refers to direct contact and includes the situations where the layers and/or components are bonded to each other.

As shown in FIGS. 2-4, the foldable apparatus 101 can comprise an adhesive layer 261. As shown, the adhesive layer 261 can comprise a first contact surface 263 and a second contact surface 265 that can be opposite the first contact surface 263. In aspects, as shown in FIGS. 2-4, the second contact surface 265 of the adhesive layer 261 can comprise a planar surface. In aspects, as shown in FIGS. 2-4, the first contact surface 263 of the adhesive layer 261 can comprise a planar surface. An adhesive thickness 267 of the adhesive layer 261 can be defined as a minimum distance between the first contact surface 263 and the second contact surface 265. In aspects, the adhesive thickness 267 of the adhesive layer 261 can be about 1 μm or more, about 5 μm or more, about 10 μm or more, about 100 μm or less, about 60 μm or less, about 30 μm or less, or about 20 μm or less. In aspects, the adhesive thickness 267 of the adhesive layer 261 can range from about 1 μm to about 100 μm, from about 5 μm to about 60 μm, from about 10 μm to about 30 μm, from about 10 μm to about 20 μm, or any range or subrange therebetween.

In aspects, as shown in FIGS. 2-4, the second contact surface 265 of the adhesive layer 261 can face and/or contact the first major surface 273 of a release liner 271 (described below). In aspects, as shown in FIGS. 2-3, the first contact surface 263 of the adhesive layer 261 can face and/or contact the second surface area 225 of the first portion 221. In aspects, as shown in FIGS. 2-3, the first contact surface 263 of the adhesive layer 261 can face and/or contact the fourth surface area 235 of the second portion 231. In aspects, as shown in FIG. 2, the first contact surface 263 of the adhesive layer 261 can face the second central surface area 243 of the central portion 281. In aspects, as shown in FIG. 4, the first contact surface 263 of the adhesive layer 261 can face and/or contact the first surface area 223 of the first portion 221. In aspects, as shown in FIG. 4, the first contact surface 263 of the adhesive layer 261 can face and/or contact the third surface area 233 of the second portion 231. In aspects, as shown in FIG. 4, the first contact surface 263 of the adhesive layer 261 can face the first central surface area 213 of the central portion 281. In aspects, as shown in FIG. 2, the first contact surface 263 of the adhesive layer 261 can face the second central surface area 243 of the central portion 281. In further aspects, although not shown, the first contact surface 263 of the adhesive layer 261 can contact the second central surface area 243 of the central portion 281, for example by filling the region (e.g., second recess 241) indicated as occupied by the second polymer-based portion 299 in FIG. 2. In aspects, although not shown, the second recess may not be totally filled, for example, to leave room for electronic devices and/or mechanical devices. In aspects, although not shown, the foldable substrate 201 of FIG. 4 can be configured with the adhesive layer 261 contacting the second major surface 205 rather than the first major surface 203 while the second polymer-based portion 299 or a coating 251 in place of the second polymer-based portion 299 can be positioned at least partially in the first recess 211.

In aspects, the adhesive layer 261 can comprise one or more of a polyolefin, a polyamide, a halide-containing polymer (e.g., polyvinylchloride or a fluorine-containing polymer), an elastomer, a urethane, phenolic resin, parylene, polyethylene terephthalate (PET), and polyether ether ketone (PEEK). Example aspects of polyolefins include low molecular weight polyethylene (LDPE), high molecular weight polyethylene (HDPE), ultrahigh molecular weight polyethylene (UHMWPE), and polypropylene (PP). Example aspects of fluorine-containing polymers include polytetrafluoroethylene (PTFE), polyvinylfluoride (PVF), polyvinylidene fluoride (PVDF), perfluoropolyether (PFPE), perfluorosulfonic acid (PFSA), a perfluoroalkoxy (PFA), fluorinated ethylene propylene (FEP) polymers, and ethylene tetrafluoro ethylene (ETFE) polymers. Example aspects of elastomers include rubbers (e.g., polybutadiene, polyisoprene, chloroprene rubber, butyl rubber, nitrile rubber) and block copolymers (e.g., styrene-butadiene, high-impact polystyrene, poly(dichlorophosphazene)). In further aspects, the adhesive layer 261 can comprise an optically clear adhesive. In even further aspects, the optically clear adhesive can comprise one or more optically transparent polymers: an acrylic (e.g., polymethylmethacrylate (PMMA)), an epoxy, silicone, and/or a polyurethane. Examples of epoxies include bisphenol-based epoxy resins, novolac-based epoxies, cycloaliphatic-based epoxies, and glycidylamine-based epoxies. In even further aspects, the optically clear adhesive can comprise, but is not limited to, acrylic adhesives, for example, 3M 8212 adhesive, or an optically transparent liquid adhesive, for example, a LOCTITE optically transparent liquid adhesive. Exemplary aspects of optically clear adhesives comprise transparent acrylics, epoxies, silicones, and polyurethanes. For example, the optically transparent liquid adhesive could comprise one or more of LOCTITE AD 8650, LOCTITE AA 3922, LOCTITE EA E-05MR, LOCTITE UK U-09LV, which are all available from Henkel.

Throughout the disclosure, a tensile strength, ultimate elongation (e.g., strain at failure), and yield point of a polymeric material (e.g., adhesive, polymer-based portion) is determined using ASTM D638 using a tensile testing machine, for example, an Instron 3400 or Instron 6800, at 23° C. and 50% relative humidity with a type I dogbone shaped sample. In aspects, the adhesive layer 261 can comprise an elastic modulus of about 0.001 MegaPascals (MPa) or more, about 0.01 MPa or more, about 0.1 MPa or more, about 0.5 MPa or more, about 50 MPa or less, about 20 MPa or less, about 10 MPa or less, about 5 MPa or less, about 1 MPa or less, about 0.5 MPa or less, about 0.1 MPa or less, or about 0.05 MPa or less. In aspects, the adhesive layer 261 can comprise an elastic modulus in a range from about 0.001 MPa to about 50 MPa, from about 0.001 MPa to about 20 MPa, from about 0.01 MPa to about 10 MPa, from about 0.1 MPa to about 5 MPa, from about 0.5 MPa to about 1 MPa, or any range or subrange therebetween.

In aspects, as shown in FIG. 3, the foldable apparatus 301 can comprise a second adhesive layer 361 disposed over the first major surface 203, the first polymer-based portion 289, and/or the first central surface area 213. The second adhesive layer 361 can comprise a second adhesive thickness 367 defined between the fifth contact surface 363 and the sixth contact surface 365 opposite the fifth contact surface 363. In further aspects, the second adhesive thickness 367 can be within one or more of the ranges discussed above for the adhesive thickness 267. In aspects, the second adhesive layer 361 can comprise one or more of the materials discussed above for the adhesive layer 261. In further aspects, the second adhesive layer 361 can comprise the same material as the adhesive layer 261. In aspects, an elastic modulus of the second adhesive layer 361 can be within one or more of the ranges discussed above for the elastic modulus of the adhesive layer 261. In further aspects, the elastic modulus of the second adhesive layer 361 can be substantially equal to the adhesive layer 261. In further aspects, as shown, the sixth contact surface 365 of the second adhesive layer 361 can contact the first contact surface 283 of the first polymer-based portion 289. In further aspects, the sixth contact surface 365 of the second adhesive layer 361 can contact the first major surface 203 (e.g., first surface area 223, third surface area 233).

As shown in FIGS. 2-4, the polymer-based portion 289 and/or 299 of the foldable apparatus 101 can be positioned between the first portion 221 and the second portion 231. In aspects, as shown, the polymer-based portion can comprise a first polymer-based portion 289 at least partially positioned in and/or filling the first recess 211. In aspects, as shown in FIGS. 2-3, the polymer-based portion can comprise a second polymer-based portion 299 at least partially positioned in and/or filling the second recess 241. In aspects, as shown in FIG. 4, the polymer-based portion can comprise a second polymer-based portion 299 at least partially positioned in and/or filling the first recess 211. In aspects, although not shown, the second recess may not be totally filled, for example, to leave room for electronic devices and/or mechanical devices.

As shown in FIGS. 2-3, the first polymer-based portion 289 can comprise a second contact surface 285 opposite the first contact surface 283. In aspects, as shown, the first contact surface 283 can comprise a planar surface, for example, substantially coplanar (e.g., extend along a common plane, first plane 204a) with the first surface area 223 and the third surface area 233. Although not shown, in aspects, the first contact surface 283 can extend over (e.g., cover) at least a portion of the first major surface 203 (e.g., with a minimum thickness of about 5 μm or more for the first polymer-based portion 289 over the first major surface 203). In aspects, as shown in FIGS. 2-3, the fourth major surface 255 of the coating 251 can face and/or contact the first contact surface 283 of the first polymer-based portion 289. In aspects, the second contact surface 285 can comprise a planar surface, for example, substantially coplanar (e.g., extend along a common plane, third plane 204b) with the first central surface area 213. In further aspects, the second contact surface 285 can contact the first central surface area 213, the first transition surface area 215, and/or the third transition surface area 217.

As shown in FIGS. 2-4, the second polymer-based portion 299 can comprise a fourth contact surface 295 opposite the third contact surface 293. In further aspects, as shown in FIGS. 2-3, the third contact surface 293 can contact the second central surface area 243, the second transition surface area 245, and/or the fourth transition surface area 247. In aspects, as shown in FIGS. 2-3, the third contact surface 293 can comprise a planar surface, for example, being substantially coplanar (e.g., extend along a common plane with the fourth plane 206b) with the second central surface area 243. In aspects, as shown in FIGS. 2-3, the fourth contact surface 295 can comprise a planar surface, for example, being substantially coplanar (e.g., extend along a common plane with the second plane 206a) with the second surface area 225 and the fourth surface area 235.

In aspects, as shown in FIG. 4, the third contact surface 293 can contact the first central surface area 213, the first transition surface area 215, and/or the third transition surface area 217. In aspects, as shown in FIG. 4, the third contact surface 293 can comprise a planar surface, for example, being substantially coplanar (e.g., extend along a common plane with the third plane 204b) with the first central surface area 213. In aspects, as shown, the third contact surface 293 can comprise a planar surface, for example, substantially coplanar (e.g., extend along a common plane with the third plane 204b) with the first central surface area 213. In aspects, as shown in FIG. 4, the fourth contact surface 295 can be coplanar (e.g., extend along a common plane with the first plane 204a) with the first surface area 223 and the third surface area 233. In aspects, as shown in FIGS. 2 and 4, the first contact surface 263 of the adhesive layer 261 can face and/or contact the fourth contact surface 295 of the second polymer-based portion 299.

The polymer-based portion 289 and/or 299 comprises a polymer (e.g., optically transparent polymer). In aspects, the first polymer-based portion 289 and/or the second polymer-based portion 299 can comprise one or more of the materials discussed above for the polymer-based portion 289 and/or 299 (e.g., having urethane-acrylate branching points and/or branching points, comprising epoxy and an inorganic filler). In further aspects, the first polymer-based portion 289 can comprise one or more of the materials discussed above for the polymer-based portion 289 and/or 299 (e.g., having urethane-acrylate branching points and/or branching points, comprising epoxy and an inorganic filler) while the second polymer-based portion 299 can comprise one or more of the materials discussed below in this paragraph. In further aspects, the second polymer-based portion 299 can comprise one or more of the materials discussed above for the polymer-based portion 289 and/or 299 (e.g., having urethane-acrylate branching points and/or branching points, comprising epoxy and an inorganic filler) while the first polymer-based portion 289. In further aspects, one of the first polymer-based portions (e.g., second polymer-based portion 299) can comprise one or more of an optically transparent: an acrylic (e.g., polymethylmethacrylate (PMMA)), an epoxy, a silicone, and/or a polyurethane. Examples of epoxies include bisphenol-based epoxy resins, novolac-based epoxies, cycloaliphatic-based epoxies, and glycidylamine-based epoxies. In further aspects, the polymer-based portion 289 and/or 299 comprise one or more of a polyolefin, a polyamide, a halide-containing polymer (e.g., polyvinylchloride or a fluorine-containing polymer), an elastomer, a urethane, phenolic resin, parylene, polyethylene terephthalate (PET), and polyether ether ketone (PEEK). Example aspects of elastomers include rubbers and block copolymers, for example, comprising one or more of polystyrene, polydichlorophosphazene, and poly(5-ethylidene-2-norbornene). In aspects, the polymer-based portion can comprise a sol-gel material. Example aspects of polyurethanes comprise thermoset polyurethanes, for example, Dispurez 102 available from Incorez and thermoplastic polyurethanes, for example, KrystalFlex PE505 available from Huntsman. In even further aspects, the second portion can comprise an ethylene acid copolymer. An exemplary aspect of an ethylene acid copolymer includes SURLYN available from Dow (e.g., Surlyn PC-2000, Surlyn 8940, Surlyn 8150). An additional exemplary aspect for the second portion comprises Eleglass w802-GL044 available from Axalta with from 1 wt % to 2 wt % cross-linker. In aspects, the polymer-based portion 289 and/or 299 can further comprise nanoparticles, for example, carbon black, carbon nanotubes, silica nanoparticles, or nanoparticles comprising a polymer. In aspects, the polymer-based portion can further comprise fibers to form a polymer-fiber composite.

In aspects, the polymer-based portion 289 and/or 299 can be within one or more of the ranges discussed above for the elastic modulus of the polymer-based portion 289 and/or 299. In aspects, the polymer-based portion 289 and/or 299 can comprise an elastic modulus of about 0.01 MegaPascals (MPa) or more, about 0.1 MPa or more, about 1 MPa or more, about 10 MPa or more, about 20 MPa or more, about 100 MPa or more, about 200 MPa or more, about 1,000 MPa or more, about 5,000 MPa or less, about 3,000 MPa or less, about 1,000 MPa or less, about 800 MPa or less, about 500 MPa or less, or about 200 MPa or less. In aspects, the polymer-based portion 289 and/or 299 can comprise an elastic modulus in a range from about 0.01 MPa to about 5,000 MPa, from about 0.1 MPa to about 3,000 MPa, from about 1 MPa to about 1,000 MPa, from about 10 MPa to about 800 MPa, from about 20 MPa to about 500 MPa, from about 100 MPa to about 200 MPa, or any range or subrange therebetween. In aspects, the adhesive layer 261 comprises an elastic modulus greater than the elastic modulus of the polymer-based portion 289 and/or 299, which arrangement provides improved performance in puncture resistance. In aspects, the elastic modulus of the polymer-based portion 289 and/or 299 can be less than the elastic modulus of the foldable substrate 201, and/or the elastic modulus of the adhesive layer 261 can be less than elastic modulus of the polymer-based portion 289 and/or 299.

In aspects, as shown in FIG. 3, the foldable apparatus 301 can comprise a cover substrate 371 disposed over the first major surface 203, the first central surface area 213, the first polymer-based portion 289, and/or the second adhesive layer 361. In further aspects, the cover substrate can comprise a glass-based material, a ceramic-based material, or a polymer-based material (e.g., PET, PMMA). The cover substrate 371 can comprise a cover thickness 377 defined between a fifth major surface 373 and a sixth major surface 375 opposite the fifth major surface 373, which can be within one or more of the ranges discussed above for the central thickness 209. In further aspects, an elastic modulus of the cover substrate 371 can be about 5 GPa or more, about 10 GPa or more, about 20 GPa or more, about 50 GPa or more, about 70 GPa or more, about 200 GPa or less, about 150 GPa or less, about 100 GPa or less, about 90 GPa or less, about 50 GPa or less, or about 20 GPa or less, for example, in a range from about 5 GPa to about 200 GPa, from about 10 GPa to about 150 GPa, from about 20 GPa to about 100 GPa, from about 50 GPa to about 90 GPa, or any range or subrange therebetween. In further aspects, as shown, the sixth major surface 375 can contact and/or be bonded to the fifth contact surface 363 of the second adhesive layer 361. In further aspects, although not shown, the cover substrate 371 can contact and/or be bonded to the first polymer-based portion 289, for example, if the second adhesive layer 361 is not present and/or if the first polymer-based portion 289 extends over (e.g., covers) the first major surface 203.

In aspects, as shown in FIG. 2, a coating 251 can be disposed over the first major surface 203 of the foldable substrate 201. In further aspects, the coating 251 can be disposed over the first portion 221, the second portion 231, and the central portion 281. In aspects, the coating 251 can comprise a third major surface 253 and a fourth major surface 255 opposite the third major surface 253. In further aspects, the coating 251 (e.g., fourth major surface 255) can contact the foldable substrate 201 (e.g., first major surface 203). In further aspects, although not shown, at least a part of the coating 251 can be positioned in the first recess 211. In even further aspects, the coating 251 can fill the first recess 211. In further aspects, although not shown, a second adhesive layer can be positioned between the first major surface 203 and the coating 251. In further aspects, the coating 251 can comprise a coating thickness 257 defined between the third major surface 253 and the fourth major surface 255. In further aspects, the coating thickness 257 can be about 0.1 μm or more, about 1 μm or more, about 5 μm or more, about 10 μm or more, about 20 μm or more, about 25 μm or more, about 40 μm or more, about 80 μm or more, about 200 μm or less, about 100 μm or less, or about 50 μm or less, about 25 μm or less, about 20 μm or less, about 20 μm or less, about 15 μm or less, or about 10 μm or less. In aspects, the coating thickness 257 can range from about 0.1 μm to about 200 μm, from about 1 μm to about 100 μm, from about 10 μm to about 50 μm, from about 20 μm to about 50 μm, or any range or subrange therebetween.

In aspects, the coating 251 can comprise a polymeric hard coating. In further aspects, the polymeric hard coating can comprise one or more of an ethylene-acid copolymer, a polyurethane-based polymer, an acrylate resin, and a mercapto-ester resin. Example aspects of ethylene-acid copolymers include ethylene-acrylic acid copolymers, ethylene-methacrylic acid copolymers, and ethylene-acrylic-methacrylic acid terpolymers (e.g., Nucrel, manufactured by DuPont), ionomers of ethylene acid copolymers (e.g., Surlyn, manufactured by DuPont), and ethylene-acrylic acid copolymer amine dispersions (e.g., Aquacer, manufactured by BYK). Example aspects of polyurethane-based polymers include aqueous modified polyurethane dispersions (e.g., Eleglas®, manufactured by Axalta). Example aspects of acrylate resins that can be UV curable include acrylate resins (e.g., Uvekol® resin, manufactured by Allinex), cyanoacrylate adhesives (e.g., Permabond® UV620, manufactured by Krayden), and UV radical acrylic resins (e.g., Ultrabond windshield repair resin, for example, Ultrabond (45CPS)). Example aspects of mercapto-ester resins include mercapto-ester triallyl isocyanurates (e.g., Norland optical adhesive NOA 61). In further aspects, the polymeric hard coating can comprise ethylene-acrylic acid copolymers and ethylene-methacrylic acid copolymers, which may be ionomerized to form ionomer resins through neutralization of the carboxylic acid residue with typically alkali-metal ions, for example, sodium and potassium, and also zinc. Such ethylene-acrylic acid and ethylene-methacrylic acid ionomers may be dispersed in water and coated onto the substrate to form an ionomer coating. Alternatively, such acid copolymers may be neutralized with ammonia which, after coating and drying liberates the ammonia to reform the acid copolymer as the coating. By providing a coating comprising a polymeric coating, the foldable apparatus can comprise low energy fracture.

In aspects, the coating can comprise a polymeric hard coating comprising an optically transparent polymeric hard-coat layer. Suitable materials for an optically transparent polymeric hard-coat layer include but are not limited to a cured acrylate resin material, an inorganic-organic hybrid polymeric material, an aliphatic or aromatic hexafunctional urethane acrylate, a siloxane-based hybrid material, and a nanocomposite material, for example, an epoxy and urethane material with nanosilicate. In aspects, an optically transparent polymeric hard-coat layer may consist essentially of one or more of these materials. In aspects, an optically transparent polymeric hard-coat layer may consist of one or more of these materials. As used herein, “inorganic-organic hybrid polymeric material” means a polymeric material comprising monomers with inorganic and organic components. An inorganic-organic hybrid polymer is obtained by a polymerization reaction between monomers having an inorganic group and an organic group. An inorganic-organic hybrid polymer is not a nanocomposite material comprising separate inorganic and organic constituents or phases, for example, inorganic particulates dispersed within an organic matrix. More specifically, suitable materials for an optically transparent polymeric (OTP) hard-coat layer include, but are not limited to, a polyimide, a polyethylene terephthalate (PET), a polycarbonate (PC), a poly methyl methacrylate (PMMA), organic polymer materials, inorganic-organic hybrid polymeric materials, and aliphatic or aromatic hexafunctional urethane acrylates. In aspects, an OTP hard-coat layer may consist essentially of an organic polymer material, an inorganic-organic hybrid polymeric material, or aliphatic or aromatic hexafunctional urethane acrylate. In aspects, an OTP hard-coat layer may consist of a polyimide, an organic polymer material, an inorganic-organic hybrid polymeric material, or aliphatic or aromatic hexafunctional urethane acrylate. In aspects, an OTP hard-coat layer may include a nanocomposite material. In aspects, an OTP hard-coat layer may include a nano-silicate at least one of epoxy and urethane materials. Suitable compositions for such an OTP hard-coat layer are described in U.S. Pat. Pub. No. 2015/0110990, which is hereby incorporated by reference in its entirety by reference thereto. As used herein, “organic polymer material” means a polymeric material comprising monomers with only organic components. In aspects, an OTP hard-coat layer may comprise an organic polymer material manufactured by Gunze Limited and having a hardness of 9H, for example Gunze's “Highly Durable Transparent Film.” As used herein, “inorganic-organic hybrid polymeric material” means a polymeric material comprising monomers with inorganic and organic components. An inorganic-organic hybrid polymer is obtained by a polymerization reaction between monomers having an inorganic group and an organic group. An inorganic-organic hybrid polymer is not a nanocomposite material comprising separate inorganic and organic constituents or phases, for example, inorganic particulates dispersed within an organic matrix. In aspects, the inorganic-organic hybrid polymeric material may include polymerized monomers comprising an inorganic silicon-based group, for example, a silsesquioxane polymer. A silsesquioxane polymer may be, for example, an alkyl-silsesquioxane, an aryl-silsesquioxane, or an aryl alkyl-silsesquioxane having the following chemical structure: (RSiO_{1.5})ₙ, where R is an organic group for example, but not limited to, methyl or phenyl. In aspects, an OTP hard-coat layer may comprise a silsesquioxane polymer combined with an organic matrix, for example, SILPLUS manufactured by Nippon Steel Chemical Co., Ltd. In aspects, an OTP hard-coat layer may comprise 90 wt % to 95 wt % aromatic hexafunctional urethane acrylate (e.g., PU662NT (Aromatic hexafunctional urethane acrylate) manufactured by Miwon Specialty Chemical Co.) and 10 wt % to 5 wt % photo-initiator (e.g., Darocur 1173 manufactured by BASF) with a hardness of 8H or more. In aspects, an OTP hard-coat layer composed of an aliphatic or aromatic hexafunctional urethane acrylate may be formed as a stand-alone layer by spin-coating the layer on a polyethylene terephthalate (PET) substrate, curing the urethane acrylate, and removing the urethane acrylate layer from the PET substrate. In aspects, an OTP hard-coat layer may be an aliphatic or aromatic hexafunctional urethane acrylate material layer having a thickness within one or more of the thickness ranges discussed above for the coating thickness 257.

In aspects, the coating 251, if provided, may also comprise one or more of an easy-to-clean coating, a low-friction coating, an oleophobic coating, a diamond-like coating, a scratch-resistant coating, or an abrasion-resistant coating. A scratch-resistant coating may comprise an oxynitride, for example, aluminum oxynitride or silicon oxynitride with a thickness of about 500 micrometers or more. In such aspects, the abrasion-resistant layer may comprise the same material as the scratch-resistant layer. In aspects, a low friction coating may comprise a highly fluorinated silane coupling agent, for example, an alkyl fluorosilane with oxymethyl groups pendant on the silicon atom. In such aspects, an easy-to-clean coating may comprise the same material as the low friction coating. In other aspects, the easy-to-clean coating may comprise a protonatable group, for example an amine, for example, an alkyl aminosilane with oxymethyl groups pendant on the silicon atom. In such aspects, the oleophobic coating may comprise the same material as the easy-to-clean coating. In aspects, a diamond-like coating comprises carbon and may be created by applying a high voltage potential in the presence of a hydrocarbon plasma.

In aspects, as shown in FIGS. 2 and 4, the foldable apparatus 101 can comprise the release liner 271 although other substrates (e.g., glass-based substrate and/or ceramic-based substrate discussed throughout the application) may be used in further aspects rather than the illustrated release liner 271. In further aspects, as shown, the release liner 271, or another substrate, can be disposed over the adhesive layer 261. In even further aspects, as shown, the release liner 271, or another substrate, can directly contact the second contact surface 265 of the adhesive layer 261. The release liner 271, or another substrate, can comprise a first major surface 273 and a second major surface 275 opposite the first major surface 273. As shown, the release liner 271, or another substrate, can be disposed on the adhesive layer 261 by attaching the second contact surface 265 of the adhesive layer 261 to the first major surface 273 of the release liner 271, or another substrate. In aspects, as shown, the first major surface 273 of the release liner 271, or another substrate, can comprise a planar surface. In aspects, as shown, the second major surface 275 of the release liner 271, or another substrate, can comprise a planar surface. A substrate comprising the release liner 271 can comprise a paper and/or a polymer, for example polyesters (e.g., polyethylene terephthalate (PET)) and polyolefins.

Aspects of the disclosure can comprise a consumer electronic product. The consumer electronic product can comprise a front surface, a back surface, and side surfaces. The consumer electronic product can further comprise electrical components at least partially within the housing. The electrical components can comprise a controller, a memory, and a display. The display can be at or adjacent to the front surface of the housing. The display can comprise liquid crystal display (LCD), an electrophoretic displays (EPD), an organic light-emitting diode (OLED) display, or a plasma display panel (PDP). The consumer electronic product can comprise a cover substrate disposed over the display. In aspects, at least one of a portion of the housing or the cover substrate comprises the foldable apparatus discussed throughout the disclosure. The consumer electronic product can comprise a portable electronic device, for example, a smartphone, a tablet, a wearable device, or a laptop.

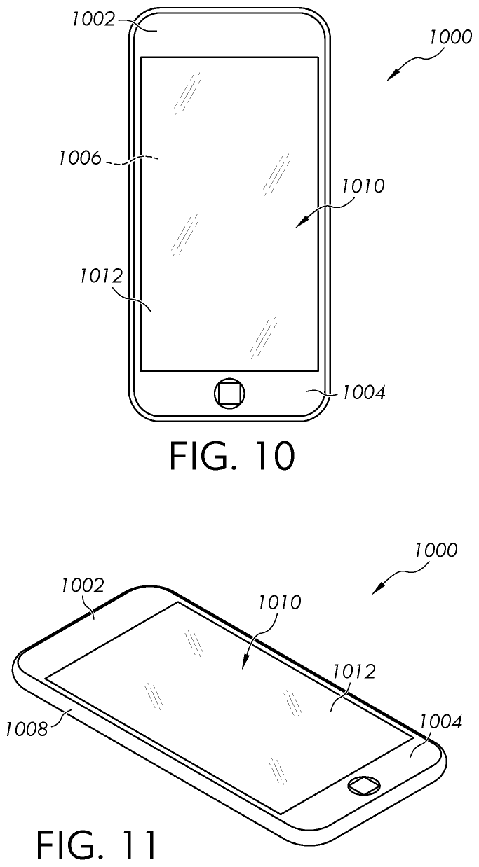

The foldable apparatus disclosed herein may be incorporated into another article, for example, an article with a display (or display articles) (e.g., consumer electronics, including mobile phones, tablets, computers, navigation systems, wearable devices (e.g., watches), and the like), architectural articles, transportation articles (e.g., automotive, trains, aircraft, sea craft, etc.), appliance articles, or any article that may benefit from some transparency, scratch-resistance, abrasion resistance or a combination thereof. An exemplary article incorporating any of the foldable apparatus disclosed herein is shown in FIGS. 10-11. Specifically, FIGS. 10-11 show a consumer electronic device 1000 including a housing 1002 having front 1004, back 1006, and side surfaces 1008. Although not shown, the consumer electronic device can comprise electrical components that are at least partially inside or entirely within the housing. For example, electrical components include at least a controller, a memory, and a display. As shown in FIGS. 10-11, the display 1010 can be at or adjacent to the front surface of the housing 1002. The consumer electronic device can comprise a cover substrate 1012 at or over the front surface of the housing 1002 such that it is over the display 1010. In aspects, at least one of the cover substrate 1012 or a portion of housing 1002 may include any of the foldable apparatus disclosed herein, for example, the foldable substrate.

In aspects, the foldable substrate 201 comprising a glass-based substrate and/or a ceramic-based substrate, and the first portion 221, the second portion 231, and/or the central portion 281 can comprise one or more compressive stress regions. In aspects, a compressive stress region may be created by chemically strengthening. Chemically strengthening may comprise an ion exchange process, where ions in a surface layer are replaced by—or exchanged with—larger ions having the same valence or oxidation state. Methods of chemically strengthening will be discussed later. Without wishing to be bound by theory, chemically strengthening the first portion 221, the second portion 231, and/or the central portion 281 can enable good impact and/or puncture resistance (e.g., resists failure for a pen drop height of about 15 centimeters (cm) or more, about 20 cm or more, about 50 cm or more). Without wishing to be bound by theory, chemically strengthening the first portion 221, the second portion 231, and/or the central portion 281 can enable small (e.g., smaller than about 10 mm or less) parallel plate distance because the compressive stress from the chemical strengthening can counteract the bend-induced tensile stress on the outermost surface of the substrate. A compressive stress region may extend into a portion of the first portion and/or the second portion for a depth called the depth of compression (DOC). As used herein, depth of compression means the depth at which the stress in the chemically strengthened substrates and/or portions described herein changes from compressive stress to tensile stress. Depth of compression may be measured by a surface stress meter or a scattered light polariscope (SCALP, wherein values reported herein were made using SCALP-5 made by Glasstress Co., Estonia) depending on the ion exchange treatment and the thickness of the article being measured. Where the stress in the substrate and/or portion is generated by exchanging potassium ions into the substrate, a surface stress meter, for example, the FSM-6000 (Orihara Industrial Co., Ltd. (Japan)), is used to measure depth of compression. Unless specified otherwise, compressive stress (including surface CS) is measured by surface stress meter (FSM) using commercially available instruments, for example the FSM-6000, manufactured by Orihara. Surface stress measurements rely upon the accurate measurement of the stress optical coefficient (SOC), which is related to the birefringence of the glass. Unless specified otherwise, SOC is measured according to Procedure C (Glass Disc Method) described in ASTM standard C770-16, entitled “Standard Test Method for Measurement of Glass Stress-Optical Coefficient,” the contents of which are incorporated herein by reference in their entirety. Where the stress is generated by exchanging sodium ions into the substrate, and the article being measured is thicker than about 400 μm, SCALP is used to measure the depth of compression and central tension (CT). Where the stress in the substrate and/or portion is generated by exchanging both potassium and sodium ions into the substrate and/or portion, and the article being measured is thicker than about 400 μm, the depth of compression and CT are measured by SCALP. Without wishing to be bound by theory, the exchange depth of sodium may indicate the depth of compression while the exchange depth of potassium ions may indicate a change in the magnitude of the compressive stress (but not the change in stress from compressive to tensile). The refracted near-field (RNF; the RNF method is described in U.S. Pat. No. 8,854,623, entitled “Systems and methods for measuring a profile characteristic of a glass sample”, which is incorporated herein by reference in its entirety) method also may be used to derive a graphical representation of the stress profile. When the RNF method is utilized to derive a graphical representation of the stress profile, the maximum central tension value provided by SCALP is utilized in the RNF method. The graphical representation of the stress profile derived by RNF is force balanced and calibrated to the maximum central tension value provided by a SCALP measurement. As used herein, “depth of layer” (DOL) means the depth that the ions have exchanged into the substrate and/or portion (e.g., sodium, potassium). Throughout the disclosure, DOL is measured in accordance with ASTM C-1422. Without wishing to be bound by theory, a DOL is usually greater than or equal to the corresponding DOC. Through the disclosure, when the maximum central tension cannot be measured directly by SCALP (as when the article being measured is thinner than about 400 μm) the maximum central tension can be approximated by a product of a maximum compressive stress and a depth of compression divided by the difference between the thickness of the substrate and twice the depth of compression, wherein the compressive stress and depth of compression are measured by FSM.

In aspects, the first portion 221 may comprise a first compressive stress region at the first surface area 223 extending to a first depth of compression from the first surface area 223 and/or a second compressive stress region at the second surface area 225 extending to a second depth of compression from the second surface area 225. In aspects, the first depth of compression and/or the second depth of compression, as a percentage of the substrate thickness 207, can be about 5% or more, about 10% or more, about 12% or more, about 15% or more, about 30% or less, about 25% or less, about 22% or less, about 20% or less, about 17% or less, or about 15% or less. In aspects, the first depth of compression and/or the second depth of compression, as a percentage of the substrate thickness 207, can range from about 5% to about 30%, from about 10% to about 25%, from about 10% to about 22%, from about 12% to about 20%, from about 15% to about 17%, or any range or subrange therebetween. In aspects, the first depth of compression and/or the second depth of compression can be about 1 μm or more, about 10 μm or more, about 15 μm or more, about 20 μm or more, about 25 μm or more, about 30 μm or more, about 200 μm or less, about 150 μm or less, about 100 μm or less, about 60 μm or less, about 45 μm or less, about 30 μm or less, or about 20 μm or less. In aspects, the first depth of compression and/or the second depth of compression can range from about 1 μm to about 200 μm, from about 1 μm to about 150 μm, from about 10 μm to about 100 μm, from about 15 μm to about 60 μm, from about 20 μm to about 45 μm, from about 20 μm to about 30 μm, or any range or subrange therebetween. By providing a first portion comprising a first glass-based and/or ceramic-based portion comprising a first depth of compression and/or a second depth of compression in a range from about 1% to about 30% of the first thickness, good impact and/or puncture resistance can be enabled.

In aspects, the first compressive stress region can comprise a first maximum compressive stress, and/or the second compressive stress region can comprise a second maximum compressive stress. In further aspects, the first maximum compressive stress and/or the second maximum compressive stress can be about 100 MegaPascals (MPa) or more, about 300 MPa or more, 400 MPa or more, about 500 MPa or more, about 600 MPa or more, about 700 MPa or more, about 1,500 MPa or less, about 1,200 MPa or less, about 1,000 MPa or less, or about 800 MPa or less. In further aspects, the first maximum compressive stress and/or the second maximum compressive stress can range from about 100 MPa to about 1,500 MPa, from about 300 MPa to about 1,500 MPa, from about 400 MPa to about 1,200 MPa, from about 500 MPa to about 1,000 MPa, from about 600 MPa to about 900 MPa, from about 700 MPa to about 800 MPa, or any range or subrange therebetween. By providing a first maximum compressive stress and/or a second maximum compressive stress in a range from about 100 MPa to about 1,500 MPa, good impact and/or puncture resistance can be enabled.

The first portion 221 may comprise a first tensile stress region positioned between the first compressive stress region and the second compressive stress region. In aspects, the first tensile stress region can comprise a first maximum tensile stress of about 10 MPa or more, about 20 MPa or more, about 30 MPa or more, about 100 MPa or less, about 80 MPa or less, or about 60 MPa or less. In further aspects, the first maximum tensile stress can range from about 10 MPa to about 100 MPa, from about 20 MPa to about 80 MPa, from about 30 MPa to about 60 MPa, or any range or subrange therebetween. Providing a first maximum tensile stress in a range from about 10 MPa to about 100 MPa can enable good impact and/or puncture resistance while providing low energy fractures, as discussed below.

In aspects, the second portion 231 may comprise a third compressive stress region at the third surface area 233 extending to a third depth of compression from the third surface area 233, and/or the second portion 231 may comprise a fourth compressive stress region at the fourth surface area 235 extending to a fourth depth of compression from the fourth surface area 235. In aspects, the third depth of compression and/or the fourth depth of compression, as a percentage of the substrate thickness 207, can be within one or more of the ranges discussed above for the first depth of compression and/or the second depth of compression. In further aspects, the third depth of compression can be substantially equal to the fourth depth of compression. The third compressive stress region can comprise a third maximum compressive stress, and/or the fourth compressive stress region can comprise a fourth maximum compressive stress. In aspects, the third maximum compressive stress and/or the fourth maximum compressive stress can be within one or more of the ranges discussed above for the first maximum compressive stress and/or the second maximum compressive stress. The second portion 231 may comprise a second tensile stress region positioned between the third compressive stress region and the fourth compressive stress region. In aspects, the second tensile stress region can comprise a second maximum tensile stress that can be within one or more of the ranges discussed above for the first maximum tensile stress. In further aspects, the first maximum tensile stress can be substantially equal to the second maximum tensile stress.

In aspects, the first depth of compression can be substantially equal to the third depth of compression. In aspects, the second depth of compression can be substantially equal to the fourth depth of compression. In aspects, the first maximum compressive stress can be substantially equal to the third maximum compressive stress. In aspects, the second maximum compressive stress can be substantially equal to the fourth maximum compressive stress. In aspects, the first depth of layer of one or more alkali-metal ions can be substantially equal to the third depth of layer of one or more alkali-metal ions. In aspects, the second depth of layer of one or more alkali-metal ions can be substantially equal to the fourth depth of layer of one or more alkali-metal ions.

In aspects, the central portion 281 can comprise a first central compressive stress region at the first central surface area 213 extending to a first central depth of compression from the first central surface area 213, and/or the central portion 281 can comprise a second central compressive stress region at the second central surface area 243 extending to a second central depth of compression from the second central surface area 243. In further aspects, the first central depth of compression and/or the second central depth of compression, as a percentage of the central thickness 209, can be within one or more of the ranges discussed above for the first depth of compression and/or the second depth of compression, as a percentage of the substrate thickness 207. In further aspects, the first central depth of compression and/or the second central depth of compression as a percentage of the central thickness 209 can be about 1% or more, about 2% or more, about 5% or more, about 8% or more, about 10% or more, about 12% or more, about 25% or less, about 20% or less, about 17% or less, about 15% or less, about 12% or less, about 10% or less, about 7% or less, or about 5% or less. For example, the first central depth of compression and/or the second central depth of compression as a percentage of the central thickness 209 can range from about 1% to about 25%, from about 2% to about 20%, from about 5% to about 17%, from about 7% to about 12%, or any range or subrange therebetween. In further aspects, the first central depth of compression can be substantially equal to the second central depth of compression. In further aspects, the first central depth of compression and/or the second central depth of compression can be within one or more of the ranges discussed above for the first depth of compression and/or the second depth of compression. In further aspects, the first central depth of compression and/or the second central depth of compression can be about 1 μm or more about 2 μm or more, about 4 μm or more, about 6 μm or more, about 20 μm or less, about 15 μm or less, about 10 μm or less, or about 8 μm or less. For example, the first central depth of compression and/or the second central depth of compression can range from about 1 μm to about 20 μm, from about 2 μm to about 15 μm, from about 4 μm to about 10 μm, from about 6 μm to about 8 μm, or any range or subrange therebetween. By providing a central portion comprising a glass-based and/or ceramic-based portion comprising a first central depth of compression and/or a second central depth of compression in a range from about 1% to about 25% of the central thickness, good impact and/or puncture resistance can be enabled.

The first central compressive stress region can comprise a first central maximum compressive stress, and/or the second central compressive stress region can comprise a second central maximum compressive stress. In aspects, the first central maximum compressive stress and/or the second central maximum compressive stress can be within one or more of the ranges discussed above for the first maximum compressive stress and/or the second maximum compressive stress. By providing a first central maximum compressive stress and/or a second central maximum compressive stress in a range from about 100 MPa to about 1,500 MPa, good impact and/or puncture resistance can be enabled.

The central portion 281 may comprise a central tensile stress region positioned between the first central compressive stress region and the second central compressive stress region. In aspects, the central tensile stress region can comprise a central maximum tensile stress of about 25 MPa or more, about 50 MPa or more, about 75 MPa or more, about 100 MPa or more, about 150 MPa or more, about 375 MPa or less, about 300 MPa or less, about 250 MPa or less, or about 200 MPa or less. In further aspects, the central maximum tensile stress can range from about 25 MPa to about 375 MPa, from about 50 MPa to about 300 MPa, from about 75 MPa to about 250 MPa, from about 100 MPa to about 250 MPa, from about 150 MPa to about 200 MPa, or any range or subrange therebetween. Providing a central maximum tensile stress in a range from about 125 MPa to about 375 MPa can enable low minimum parallel plate distance.

In aspects, the polymer-based portion 289 and/or 299 can be optically clear and/or comprise a first refractive index within one or more of the ranges discussed above for the polymer-based portion 289 and/or 299. In aspects, the foldable substrate 201 can comprise a second refractive index of about 1.4 or more, about 1.45 or more, about 1.49 or more, about 1.7 or less, about 1.6 or less, or about 1.55 or less. In aspects, the second refractive index of the foldable substrate 201 can range from about 1.4 to about 1.7, from about 1.4 to about 1.6, from about 1.45 to about 1.55, from about 1.49 to about 1.55, or any range or subrange therebetween. In aspects, a differential equal to the absolute value of the difference between the second refractive index of the foldable substrate 201 and the first refractive index of the polymer-based portion 289 and/or 299 can be about 0.1 or less, about 0.07 or less, about 0.05 or less, about 0.001 or more, about 0.01 or more, or about 0.02 or more. In aspects, the differential is in a range from about 0.001 to about 0.1, from about 0.01 to about 0.07, from about 0.02 to about 0.05, or any range or subrange therebetween. In aspects, the second refractive index of the foldable substrate 201 may be greater than the first refractive index of the polymer-based portion 289 and/or 299. In aspects, the second refractive index of the foldable substrate 201 may be less than the first refractive index of the polymer-based portion 289 and/or 299.

In aspects, the adhesive layer 261 can comprise a third refractive index that can be within one or more of the ranges discussed above with regards to the first refractive index of the polymer-based portion 289 and/or 299. In aspects, a differential equal to the absolute value of the difference between the third refractive index of the adhesive layer 261 and the first refractive index of the polymer-based portion 289 and/or 299 can be within one or more of the ranges discussed above for the differential between the second refractive index and the first refractive index. In aspects, the third refractive index of the adhesive layer 261 may be greater than the first refractive index of the polymer-based portion 289 and/or 299. In aspects, the third refractive index of the adhesive layer 261 may be less than the first refractive index of the polymer-based portion 289 and/or 299. In aspects, a differential equal to the absolute value of the difference between the third refractive index of the adhesive layer 261 and the second refractive index of the foldable substrate 201 can be within one or more of the ranges discussed above for the differential between the second refractive index and the first refractive index. In aspects, the third refractive index of the adhesive layer 261 may be greater than the second refractive index of the foldable substrate 201. In aspects, the third refractive index of the adhesive layer 261 may be less than the second refractive index of the foldable substrate 201.

In aspects, the coating 251 can comprise a fourth refractive index. In aspects, the fourth refractive index of the coating 251 can be within one or more of the ranges discussed above with regards to the first refractive index of the polymer-based portion 289 and/or 299. In aspects, a differential equal to the absolute value of the difference between the fourth refractive index of the coating 251 and the first refractive index of the polymer-based portion 289 and/or 299 can be within one or more of the ranges discussed above for the differential between the second refractive index and the first refractive index. In aspects, the fourth refractive index of the coating 251 may be greater than the first refractive index of the polymer-based portion 289 and/or 299. In aspects, the fourth refractive index of the coating 251 may be less than the first refractive index of the polymer-based portion 289 and/or 299. In aspects, a differential equal to the absolute value of the difference between the fourth refractive index of the coating 251 and the second refractive index of the foldable substrate 201 can be within one or more of the ranges discussed above for the differential between the second refractive index and the first refractive index. In aspects, the fourth refractive index of the coating 251 may be greater than the second refractive index of the foldable substrate 201. In aspects, the fourth refractive index of the coating 251 may be less than the second refractive index of the foldable substrate 201. In aspects, a differential equal to the absolute value of the difference between the fourth refractive index of the coating 251 and the third refractive index of the adhesive layer 261 can be within one or more of the ranges discussed above for the differential between the second refractive index and the first refractive index. In aspects, the fourth refractive index of the coating 251 may be greater than the third refractive index of the adhesive layer 261. In aspects, the fourth refractive index of the coating 251 may be less than the third refractive index of the adhesive layer 261.

FIGS. 6-7 and 9 schematically illustrate aspects of a foldable apparatus 501, 701, and/or 901 in accordance with aspects of the disclosure in a folded configuration. As shown in FIG. 6, the foldable apparatus 501 is folded such that the second major surface 205 of the foldable substrate 201 is on the inside of the folded foldable apparatus 501, for example, foldable apparatus 301 can be folded to form foldable apparatus 501. For example, a display could be located on the side of the second major surface 205, and a viewer would view the display from the side of the first major surface 203. Alternatively, a display could be located on the side of the first major surface 203, and a viewer would view the display from the side of the second major surface 205. For example, a display could be located on the side of the second major surface 205, and a viewer would view the display from the side of the first major surface 203. Alternatively, a display could be located on the side of the first major surface 203, and a viewer would view the display from the side of the second major surface 205.

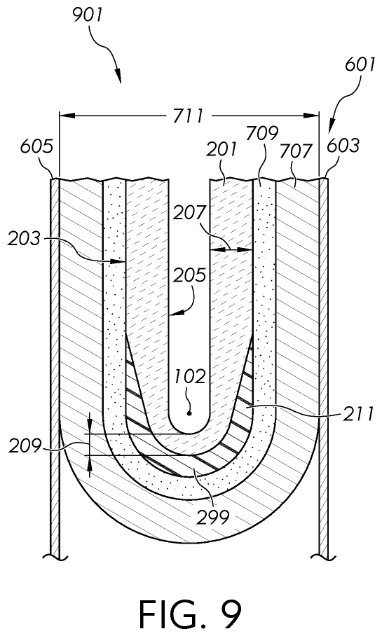

As shown in FIG. 7, the foldable apparatus 101 shown in FIG. 1 (modified as described in the Parallel Plate Test below) is folded to form folded foldable apparatus 701 such that the first major surface 203 of the foldable substrate 201 is on the inside of the folded foldable apparatus 701. In FIG. 7, a user would view a display device in place of the 50 μm sheet 707 of PET through the foldable substrate 201 and, thus, would be positioned on the side of the first major surface 203. In aspects, as shown in FIG. 7, the foldable apparatus 701 can comprise a coating 251 disposed over the foldable apparatus 701 (e.g., second major surface 205). In further aspects, a user would view a display device in place of the 50 μm sheet 707 of PET through the coating 251. In aspects, as shown in FIG. 7, the polymer-based portion 289 and/or 299 can be disposed over the foldable substrate 201. In further aspects, although not shown, an additional substrate (e.g., glass-based substrate and/or ceramic-based substrate in place of release liner 271 or 50 μm sheet 707 of PET), and the additional substrate can be disposed over a display device. As shown in FIG. 9, the foldable apparatus 401 shown in FIG. 4 (modified as described in the Parallel Plate Test below) is folded to form folded foldable apparatus 901 such that the first major surface 203 of the foldable substrate 201 is on the inside of the folded foldable apparatus 901. In FIG. 9, a user would view a display device in place of the 50 μm sheet 707 of PET through the foldable substrate 201 and, thus, would be positioned on the side of the first major surface 203. In aspects, as shown in FIG. 9, the second polymer-based portion 299 can be disposed over the foldable substrate 201 (e.g., in the first recess 211). In further aspects, although not shown, an additional substrate (e.g., glass-based substrate and/or ceramic-based substrate in place of release liner 271 or 50 μm sheet 707 of PET), and the additional substrate can be disposed over a display device. It is to be understood that the foldable apparatus can be designed to fold such that the display device is on the inside of the bend, on the outside of the bend, or such that the foldable apparatus can be folded in either direction.

As used herein, the “parallel plate distance” of a foldable apparatus and/or foldable substrate is measured with the following test configuration and process using a parallel plate apparatus 601 (see FIGS. 6-7 and 9) that comprises a pair of parallel rigid stainless-steel plates 603, 605 comprising a first rigid stainless-steel plate 603 and a second rigid stainless-steel plate 605. When measuring the “parallel plate distance” for the foldable substrate 201 (e.g., the foldable apparatus 301 shown in FIG. 3 consisting of foldable substrate 201), as shown in FIG. 6, the foldable substrate 201 is placed between the pair of plates 603 and 605 such that the first major surface 203 is in contact with the pair of plates 603 and 605. When measuring the “parallel plate distance” for a foldable apparatus resembling the foldable apparatus 101 and 401 shown in FIGS. 2 and 4, respectively, the adhesive layer 261 is removed and is replaced by a test adhesive layer 709 comprises a thickness of 50 μm. Further, the test is conducted with a 50 μm thick sheet 707 of polyethylene terephthalate (PET) rather than with the release liner 271 of FIGS. 2 and 4. Thus, during the test to determine the “parallel plate distance” of a configuration of a foldable apparatus, the foldable apparatus 701 is produced by using the 50 μm thick sheet 707 of polyethylene terephthalate (PET) rather than with the release liner 271 of FIGS. 2 and 4.

When preparing the foldable apparatus 701, the 50 μm thick sheet 707 of polyethylene terephthalate (PET) is attached to the test adhesive layer 709 in an identical manner that the release liner 271 is attached to the second contact surface 265 of the adhesive layer 261 as shown in FIG. 2. To test the foldable apparatus 701 of FIG. 7, the test adhesive layer 709 and the 50 μm sheet 707 of PET can likewise be installed as shown in the configuration of FIG. 7 to conduct the test on the foldable apparatus 701. The foldable apparatus 701 is placed between the pair of parallel rigid stainless-steel plates 603 and 605 such that the foldable substrate 201 will be on the inside of the bend, similar to the configuration shown in FIG. 7. Similarly, when preparing the foldable apparatus 901, the foldable apparatus 401 shown in FIG. 4 is prepared for testing by replacing the adhesive layer 261 and the release liner 271 with the test adhesive layer 709 and the 50 μm thick sheet 707 of PET. For determining a “parallel plate distance”, the distance between the parallel plates is reduced at a rate of 50 μm/second until the parallel plate distance 611 or 711 is equal to the “parallel plate distance” to be tested. Then, the parallel plates are held at the “parallel plate distance” to be tested for 24 hours at about 85° C. and about 85% relative humidity. As used herein, the “minimum parallel plate distance” is the smallest parallel plate distance that the foldable apparatus can withstand without failure under the conditions and configuration described above.

In aspects, the foldable apparatus 101, 301, 401, 501, 701, and/or 901 and/or foldable substrate 201 can achieve a parallel plate distance of 100 mm or less, 50 mm or less, 20 mm or less, 10 mm or less, 5 mm or less, or 3 mm or less. In further aspects, the foldable apparatus and/or foldable substrate can achieve a parallel plate distance of 50 millimeters (mm), or 20 mm, or 10 mm, of 5 mm, or 3 mm. In aspects, the foldable apparatus and/or foldable substrate can comprise a minimum parallel plate distance of about 40 mm or less, about 20 mm or less, about 10 mm or less, about 5 mm or less, about 3 mm or less, about 1 mm or less, about 1 mm or more, about 3 mm or more, about 5 mm or more, or about 10 mm or more. In aspects, the foldable apparatus and/or foldable substrate can comprise a minimum parallel plate distance in a range from about 1 mm to about 40 mm, from about 1 mm to about 20 mm, from about 1 mm to about 10 mm, from about 1 mm to about 5 mm, from about 1 mm to about 3 mm. In aspects, the foldable apparatus and/or foldable substrate can achieve a minimum parallel plate distance in a range from about 2 mm to about 40 mm, from about 2 mm to about 20 mm, from about 3 mm to about 10 mm, from about 3 mm to about 5 mm, or any range or subrange therebetween.

A width 287 of the central portion 281 of the foldable substrate 201 is defined between the first portion 221 and the second portion 231 in the direction 106 of the length 105. In aspects, the width 287 of the central portion 281 of the foldable substrate 201 can extend from the first portion 221 to the second portion 231. A width 210 of the first central surface area 213 and the second central surface area 243 of the foldable substrate 201 is defined between the first transition region 212 and the second transition region 218, for example, as the portion comprising the central thickness 209, in the direction 106 of the length 105. In aspects, the width 287 of the central portion 281 of the foldable substrate 201 and/or the width 210 of the first central surface area 213 of the foldable substrate 201 can be about 1.4 times or more, about 1.6 times or more, about 2 times or more, about 2.2 times or more, about 3 times or less, or about 2.5 times or less the minimum parallel plate distance. In aspects, the width 287 of the central portion 281 of the foldable substrate 201 and/or the width 210 of the first central surface area 213 of the foldable substrate 201 as a multiple of the minimum parallel plate distance can range from about 1.4 times to about 3 times, from about 1.6 times to about 2.5 times, from about 2 times to about 2.5 times, from about 2.2 times to about 2.5 times, or any range or subrange therebetween. Without wishing to be bound by theory, the length of a bent portion in a circular configuration between parallel plates can be about 1.6 times the parallel plate distance. Without wishing to be bound by theory, the length of a bend portion in an elliptical configuration between parallel plates can be about 2.2 times the parallel plate distance. In aspects, the width 287 of the central portion 281 and/or the width 210 of the first central surface area 213 as a percentage of the length 105 of the foldable apparatus can be about 30% or more, about 35% or more, about 40% or more, about 45% or more, about 70% or less, about 60% or less, about 55% or less, or about 50% or less. In aspects, the width 287 of the central portion 281 and/or the width 210 of the first central surface area 213 as a percentage of the length 105 of the foldable apparatus can range from about 30% to about 70%, from about 35% to about 60%, from about 40% to about 55%, from about 45% to about 50%, or any range or subrange therebetween. In aspects, the width 287 of the central portion 281 of the foldable substrate 201 and/or the width 210 of the first central surface area 213 of the foldable substrate 201 can be about 1 mm or more, about 3 mm or more, about 5 mm or more, about 8 mm or more, about 10 mm or more, about 15 mm or more, about 20 mm or more, about 60 mm or less, about 50 mm or less, about 40 mm or less, about 35 mm or less, about 30 mm or less, or about 25 mm or less. In aspects, the width 287 of the central portion 281 of the foldable substrate 201 and/or the width 210 of the first central surface area 213 of the foldable substrate 201 can range from about 1 mm to about 100 mm, from about 3 mm to about 60 mm, from about 5 mm to about 50 mm, from about 8 mm to about 40 mm, from about 10 mm to about 40 mm, from about 15 mm to about 35 mm, from about 20 mm to about 30 mm, or any range of subrange therebetween. In aspects, the width 287 of the central portion 281 of the foldable substrate 201 and/or the width 210 of the first central surface area 213 of the foldable substrate 201 can be about 2.8 mm or more, about 6 mm or more, about 9 mm or more, about 60 mm or less, about 40 mm, or less, or about 24 mm or less. In aspects, the width 287 of the central portion 281 of the foldable substrate 201 and/or the width 210 of the first central surface area 213 of the foldable substrate 201 can range from about 2.8 mm to about 40 mm, from about 6 mm to about 24 mm, or any range of subrange therebetween. In aspects, the first central surface area 213, the central portion 281 (e.g., centerline of the central portion 281), and/or the fold plane 109 can correspond to a midpoint between opposing ends of the foldable substrate and/or the foldable apparatus in the direction 106 of the length 105. By providing a width within the above-noted ranges for the central portion, folding of the foldable apparatus without failure can be facilitated.

The foldable apparatus 101, 301, 401, 501, 701, and/or 901 may have an impact resistance defined by the capability of a region of the foldable apparatus (e.g., a region comprising the first portion 221, a region comprising the second portion 231, a region comprising the polymer-based portion 289 and/or 299 and/or central portion 281) to avoid failure at a pen drop height (e.g., 5 centimeters (cm) or more, 10 centimeters or more, 20 cm or more), when measured according to the “Pen Drop Test.” As used herein, the “Pen Drop Test” is conducted such that samples of foldable apparatus are tested with the load (i.e., from a pen dropped from a certain height) imparted to an outer surface of the PET sheet with the foldable apparatus configured as in the parallel plate test with 50 μm thick sheet 707 of PET attached to the test adhesive layer 709 having a thickness of 50 μm instead of the release liner 271 shown in FIG. 2. During testing, the foldable apparatus bonded to the PET sheet is placed on an aluminum plate (6063 aluminum alloy, as polished to a surface roughness with 400 grit paper) with the outer surface opposite the PET sheet in contact with the aluminum plate. No tape is used on the side of the sample resting on the aluminum plate.

A tube is used for the Pen Drop Test to guide a pen to an outer surface of the foldable apparatus. For the foldable apparatus 101, 301, 401, 501, 701, and/or 901 in FIGS. 2-4, 6-7, and 9, the pen is guided to the outer surface of the PET sheet, and the tube is placed in contact with the outer surface of the PET sheet so that the longitudinal axis of the tube is substantially perpendicular to the outer major surface with the longitudinal axis of the tube extending in the direction of gravity. The tube has an outside diameter of 1 inch (2.54 cm), an inside diameter of nine-sixteenths of an inch (1.4 cm), and a length of 90 cm. An acrylonitrile butadiene (ABS) shim is employed to hold the pen at a predetermined height for each test. After each drop, the tube is relocated relative to the sample to guide the pen to a different impact location on the sample. The pen employed in Pen Drop Test is a BIC Easy Glide Pen, Fine, having a tungsten carbide ballpoint tip of 0.7 mm (0.68 mm) diameter, and a weight of 5.73 grams (g) including the cap.

For the Pen Drop Test, the pen is dropped with the cap attached to the top end (i.e., the end opposite the tip) so that the ballpoint can interact with the test sample. In a drop sequence according to the Pen Drop Test, one pen drop is conducted at an initial height of 1 cm, followed by successive drops in 0.5 cm increments up to 20 cm, and then after 20 cm, 2 cm increments until failure of the test sample. After each drop is conducted, the presence of any observable fracture, failure, or other evidence of damage to the sample is recorded along with the particular pen drop height. Using the Pen Drop Test, multiple samples can be tested according to the same drop sequence to generate a population with improved statistical accuracy. For the Pen Drop Test, the pen is to be changed to a new pen after every 5 drops, and for each new sample tested. In addition, all pen drops are conducted at random locations on the sample at or near the center of the sample, with no pen drops near or on the edge of the samples.

For purposes of the Pen Drop Test, “failure” means the formation of a visible mechanical defect in a laminate. The mechanical defect may be a crack or plastic deformation (e.g., surface indentation). The crack may be a surface crack or a through crack. The crack may be formed on an interior or exterior surface of a laminate. The crack may extend through all or a portion of the foldable substrate 201 and/or coating. A visible mechanical defect has a minimum dimension of 0.2 mm or more.

In aspects, the foldable apparatus can resist failure for a pen drop in a region comprising the first portion 221 or the second portion 231 at a pen drop height of 10 centimeters (cm), 12 cm, 14 cm, 16 cm, or 20 cm. In aspects, a maximum pen drop height that the foldable apparatus can withstand without failure over a region comprising the first portion 221 or the second portion 231 may be about 10 cm or more, about 12 cm or more, about 14 cm or more, about 16 cm or more, about 40 cm or less, or about 30 cm or less, about 20 cm or less, about 18 cm or less. In aspects, a maximum pen drop height that the foldable apparatus can withstand without failure over a region comprising the first portion 221 or the second portion 231 can range from about 10 cm to about 40 cm, from about 12 cm to about 30 cm, from about 14 cm to about 20 cm, from about 16 cm to about 20 cm, from about 18 cm to about 20 cm, or any range or subrange therebetween.

In aspects, the foldable apparatus can resist failure for a pen drop in a region (e.g., central portion 281) comprising the polymer-based portion 289 and/or 299 between the first portion 221 and the second portion 231 in the Pen Drop Test at a pen drop height of 5 cm or more, 8 cm or more, 9 cm or more, 10 cm or more, 11 cm or more, 12 cm or more, 13 cm or more, 14 cm, 15 cm or more, or 20 cm. In aspects, a maximum pen drop height that the foldable apparatus can withstand without failure over a region comprising the polymer-based portion 289 and/or 299 between the first portion 221 and the second portion 231 in the Pen Drop Test may be of 5 cm or more, 8 cm or more, 9 cm or more, 10 cm or more, 11 cm or more, 12 cm or more, 13 cm or more, 14 cm or more, 15 cm or more, 20 cm or less, 15 cm or less, or 13 cm or less. In aspects, a maximum pen drop height that the foldable apparatus can withstand without failure over a region comprising the polymer-based portion 289 and/or 299 between the first portion 221 and the second portion 231 in the Pen Drop Test can range from about 5 cm to about 20 cm, from about 10 cm to about 15 cm, from about 11 cm to about 13 cm, or any range or subrange therebetween.

The foldable apparatus can exhibit a puncture resistance in a portion comprising the polymer-based portion 289 and/or 299 as measured in a Quasi-Static Puncture Test. For the “Quasi-Static Puncture Test”, a test apparatus identical to the test apparatus discussed above for the Pen Drop Test is used, where the foldable apparatus is configured with 50 μm thick sheet 707 of PET attached to the test adhesive layer 709 having a thickness of 50 μm instead of the release liner 271 shown in FIG. 2. During testing, the foldable apparatus bonded to the PET sheet is placed on an aluminum plate (6063 aluminum alloy, as polished to a surface roughness with 400 grit paper) with the outer surface opposite the PET sheet in contact with the aluminum plate. No tape is used on the side of the sample resting on the aluminum plate. In the Quasi-Static Puncture Test, a tungsten carbide ball with a predetermined diameter is placed on the outer surface of PET sheet in a portion of the foldable apparatus comprising the polymer-based portion 289 and/or 299 and a load is applied to the tungsten carbide ball at a rate of 0.1 kilogram-force (kgf) per minute until failure. In aspects, the foldable apparatus can withstand a load of about 0.5 kgf or more, about 0.8 kgf or more, about 0.9 kgf or more, about 1 kgf or more, about 1.1 kgf or more, about 1.2 kgf or more applied through a 0.25 millimeter diameter tungsten carbide ball in the Quasi-Static Puncture Test. In aspects, the foldable apparatus can withstand a load of about 0.5 kgf or more, about 1 kgf or more, about 1.5 kgf or more, about 1.8 kgf or more, about 1.9 kgf or more, about 2 kgf or more, about 2.1 kgf or more, about 2.2 kgf or more, about 2.5 kgf or more applied through a 0.5 millimeter diameter tungsten carbide ball in the Quasi-Static Puncture Test.

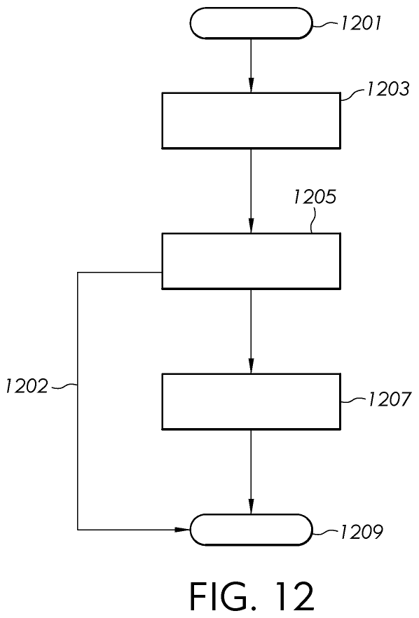

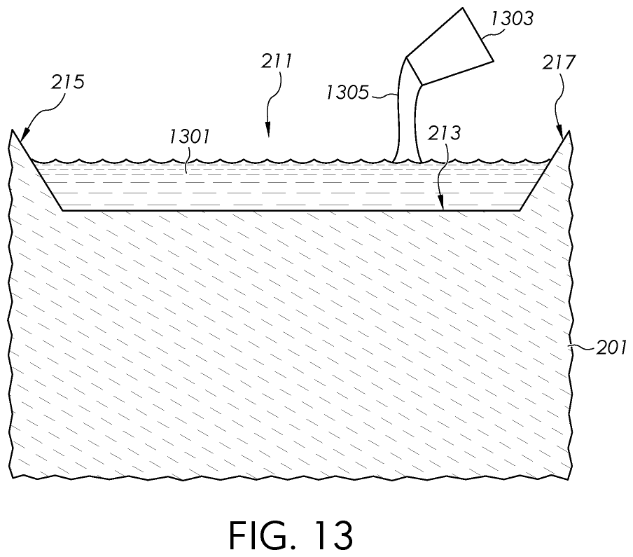

Aspects of methods of making the foldable apparatus and/or foldable substrate in accordance with aspects of the disclosure will be discussed with reference to the flow chart in FIG. 12 and example method steps illustrated in FIGS. 13-18.

Example aspects of making the foldable apparatus 101, 301 and/or 701 and/or foldable substrate 201 illustrated in FIGS. 2-3 and 7 will now be discussed with reference to FIGS. 13-18 and the flow chart in FIG. 12. However, it is to be understood that the foldable apparatus 401 and 901 illustrated in FIGS. 4 and 9 can be formed by modifying the method discussed here to use a foldable substrate with a single recess and only disposing a polymer-based material over and/or within the single recess. In a first step 1201 of methods of the disclosure, methods can start with obtaining a foldable substrate 21 (see FIG. 13). In aspects, the foldable substrate 201 may be provided by purchase or otherwise obtaining a substrate or by forming the foldable substrate. In aspects, the foldable substrate 201 can comprise a glass-based substrate and/or a ceramic-based substrate. In further aspects, glass-based substrates and/or ceramic-based substrates can be provided by forming them with a variety of ribbon forming processes, for example, slot draw, down-draw, fusion down-draw, up-draw, press roll, redraw, or float. In further aspects, ceramic-based substrates can be provided by heating a glass-based substrate to crystallize one or more ceramic crystals. The foldable substrate 201 may comprise one or more recesses and associated transition regions. For example, as shown in FIG. 13, the foldable substrate 201 can comprise a first central surface area 213, a first transition surface area 215, and a third transition surface area 217. The one or more recesses can be formed, for example, by etching a central region of the foldable substrate. At the end of step 1201, the foldable substrate 201 can comprise one or more compressive stress regions as discussed above.

After step 1201, as shown in FIG. 13, methods can proceed to step 1203 comprising disposing a layer 1301 of the precursor liquid 1305 over the first central surface area 213 of the foldable substrate. In aspects, the precursor liquid 1305 can comprise one of the compositions discussed above with reference to the multi-functional acrylate, multi-functional urethane-acrylate oligomer, and/or the epoxy and inorganic filler. In aspects, as shown, the precursor liquid 1305 can be dispensed from a container 1303 (e.g., conduit, flexible tube, micropipette, or syringe) to form the layer 1301 in the first recess 211. In further aspects, although not shown, disposing the layer 1301 of the precursor liquid 1305 can further comprise drawing an applicator bar across the first central surface area 213 to achieve a layer of a predetermined thickness, by controlling a height of the applicator bar. In even further aspects, a predetermined thickness of the layer can be within one or more of the ranges discussed above with reference to the polymer-based portion 289 and/or 299. In further aspects, although not shown, depositing the composition can comprise using a knife (e.g., doctor blade or knife over roll coating) to achieve a predetermined thickness. In further aspects, although not shown, depositing the composition can comprise using a roller (e.g., gravure or knife over roll coating). In further aspects, the layer 1301 of the precursor liquid 1305 can naturally spread over the first central surface area 213. In further aspects, as shown, the layer 1301 can contact and/or extend over (e.g., cover) at least a portion of the first transition surface area 215 and/or the third transition surface area 217. In aspects, although not shown, the layer 1301 can further extend over (e.g., cover) a portion of the first major surface 203 (e.g., first surface area 223, third surface area 233), for example with a thickness of about 5 μm or more over the first major surface 203. In aspects, the layer 1301 can fill and/or occupy the first recess 211.

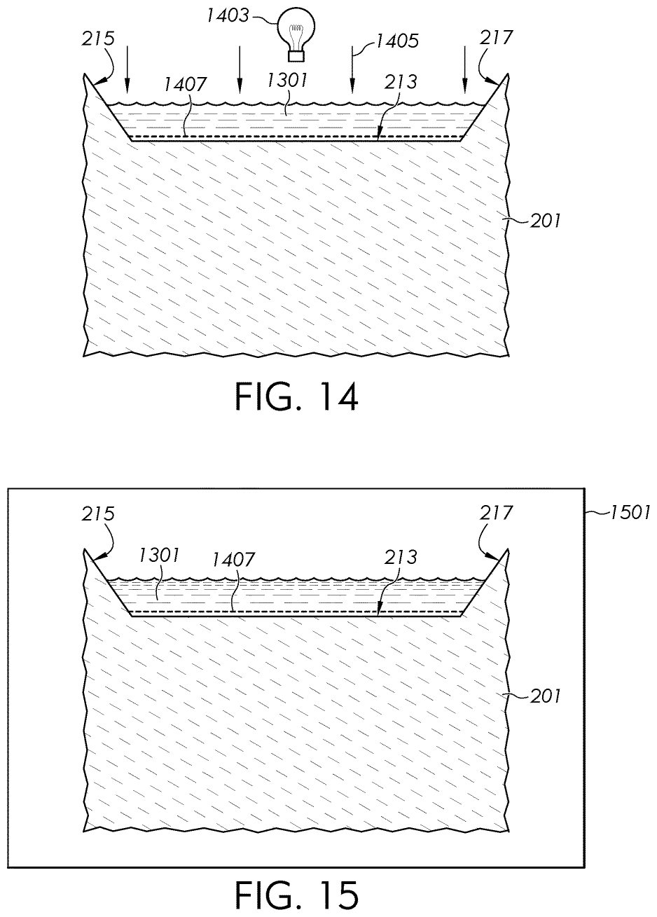

In further aspects, as indicated by dashed line 1407 in FIGS. 14-15, a layer of a silane coupling agent can be deposited over the first central surface area 213 of the foldable substrate 201 before the layer 1301 of the precursor liquid 1305 is disposed over the first central surface area 213. In even further aspects, although not shown, a silane precursor can be dispensed from a container (e.g., conduit, flexible tube, micropipette, or syringe) similar to how the precursor liquid can be dispensed, as described above. In even further aspects, the silane coupling agent can comprise one or more of the silane coupling agents discussed above (e.g., acrylate silane, epoxy silane).

In even further aspects, disposing the silane coupling agent can further comprise heating the foldable substrate 201 and the silane coupling agent at a second temperature for a second period of time. In even further aspects, the second temperature can be about 80° C. or more, about 100° C. or more, about 110° C. or more, about 120° C. or more, about 160° C. or less, about 140° C. or less, or about 130° C. In even further aspects, the second temperature can be in a range from about 80° C. to about 160° C., from about 100° C. to about 140° C., from about 110° C. to about 130° C., or any range or subrange therebetween. In even further aspects, the second period of time can be about 15 minutes or more, about 30 minutes or more, about 45 minutes or more, about 6 hours or less, about 2 hours or less, about 90 minutes or less, about 75 minutes or less, or about 60 minutes or less. In even further aspects, the second period of time can be in a range from about 15 minutes to about 6 hours, from about 30 minutes 2 hours, from about 45 minutes to about 2 hours, from about 45 minutes to about 75 minutes, from about 45 minutes to about 60 minutes. In even further aspects, the first central surface area 213 of the foldable substrate 201 can be treated with plasma and/or ozone before disposing the silane coupling agent and/or the precursor liquid 1305 on the first central surface area 213 of the foldable substrate 201. Alternatively, a separate layer of a silane coupling agent may not be used, for example, if the precursor liquid (e.g., composition) includes a silane coupling agent or the adhesion of the resulting polymer-based portion is sufficient without a silane coupling agent.

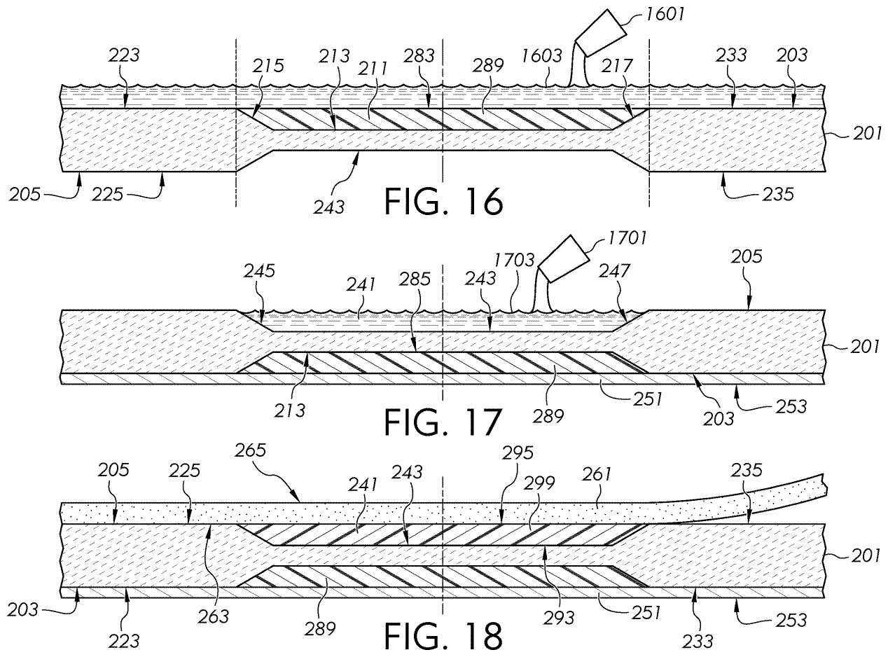

After step 1203, as shown in FIGS. 14-15, methods can proceed to step 1205 comprising curing the layer 1301 to form the first polymer-based portion 289 (see FIGS. 16-18). In further aspects, as shown in FIG. 14, curing the layer 1301 in step 1205 can comprise impinging the material with radiation 1405 from a radiation source 1403. In even further aspects, the radiation 1405 can comprise a wavelength that the photoinitiator is sensitive to. In even further aspects, the radiation can impinge substantially (e.g., the entire) layer 1301. In even further aspects, the radiation 1405 can comprise ultraviolet radiation and/or visible radiation. In even further aspects, the radiation 1405 can comprise an optical wavelength in a range from about 10 nm to about 400 nm, from about 100 nm to about 300 nm, from about 100 nm to about 200 nm, or any range or subrange therebetween. In even further aspects, the radiation can comprise an optical wavelength in a range from about 315 nm to about 400 nm, from about 280 nm to about 315 nm, from about 100 nm to about 280 nm, or from 122 nm to about 200 nm. In even further aspects, the wavelength of the radiation can be in a range from about 300 nm to about 1,000 nm, from about 350 nm to about 900 nm, from about 400 to about 800 nm, from about 500 nm to about 700 nm, or any range or subrange therebetween. In still further aspects, the optical wavelength of the radiation can be about 365 nm, about 415 nm, or about 590 nm. In even further aspects, the radiation source 1403 can comprise a light-emitting diode (LED), an organic light-emitting diode (OLED), a laser, an incandescent bulb, and/or a fluorescent bulb (e.g., a cold cathode fluorescent lamp (CCFL)). In further aspects, a fluence of the radiation (e.g., UV radiation) can be about 1 mJ/cm² or more, about 1.5 mJ/cm² or more, about 2 mJ/cm² or more, about 4 mJ/cm² or less, about 3 mJ/cm² or less, or about 2.5 mJ/cm² or less. In further aspects, the fluence can range from about 1 mJ/cm² to about 4 mJ/cm², from about 1.5 mJ/cm² to about 3 mJ/cm², from about 2 mJ/cm² to about 2.5 mJ/cm², or any range or subrange therebetween. In further aspects, a period of time for the curing by irradiating the layer can be about 30 seconds or more, about 1 minute or more, about 2 minutes or more, about 4 minutes or more, about 30 minutes or less, about 20 minutes or less, about 10 minutes or less, or about 8 minutes to less. In further aspects, a period of time for the curing by irradiating the layer can be in a range from about 30 seconds to about 30 minutes, from about 1 minute to about 20 minutes, from about 2 minutes to about 10 minutes, from about 4 minutes to about 8 minutes, or any range or subrange therebetween. Curing the composition comprising a photoinitiator and curing the composition using irradiation can reduce processing time, processing equipment, and the overall cost of production.

In further aspects, as shown in FIG. 15, curing the layer 1301 can comprise heating the layer 1301. In even further aspects, as shown, the layer 1301 disposed over the first central surface area 213 of the foldable substrate 201 can be heated by placing the layer 1301 and the foldable substrate 201 in an oven 1501 maintained a third temperature for a third period of time. In still further aspects, the third temperature can be about 60° C. or more, about 75° C. or more, about 100° C. or more, about 250° C. or less, about 200° C. or less, about 160° C. or less, or about 130° C. or less. In still further aspects, the third temperature can be in a range from about 60° C. to about 250° C., from about 75° C. to about 250° C., from about 100° C. to about 200° C., from about 100° C. to about 160° C., from about 100° C. to about 130° C., or any range or subrange therebetween. In still further aspects, the third period of time can be about 15 minutes or more, about 30 minutes or more, about 45 minutes or more, about 60 minutes or more, about 90 minutes or more, about 16 hours or less, about 4 hours or less, or about 2 hours or less. In still further aspects, the third period of time can be in a range from about 15 minutes to about 16 hours, from about 30 minutes to about 4 hours, from about 45 minutes to about 2 hours, from about 60 minutes to about 2 hours, or any range or subrange therebetween. In further aspects, step 1205 can comprise irradiating the layer 1301 followed by heating the layer 1301.

After step 1205, as shown in FIGS. 16-18, methods can proceed to step 1207 comprising assembling a foldable apparatus. In aspects, as shown in FIGS. 16-18, step 1207 can comprise assembling the foldable apparatus by disposing a coating 251, another polymer-based portion (e.g., second polymer-based portion 299), an adhesive layer 261, and/or a coating 251 over the foldable substrate 201. As discussed above with reference to FIG. 3, it is to be understood that step 1207 can further comprise disposing a second adhesive layer 361 and/or a cover substrate 371 over the foldable substrate and/or the first polymer-based portion 289. In further aspects, as shown in FIG. 16, a first polymer-based portion 289 can be disposed in the first recess 211 and/or over the first central surface area 213 before step 1207. In further aspects, as shown in FIGS. 16-17, a coating 251 can be disposed over the first major surface 203 (e.g., first surface area 223 and third surface area 233), for example, by dispensing a first liquid 1603 from a container 1601 (e.g., conduit, flexible tube, micropipette, or syringe) over the first major surface 203 that can be cured to form the coating 251. In even further aspects, the first liquid 1603 may comprise a coating precursor, a solvent, particles, nanoparticles, and/or fibers. In still further aspects, the coating precursor can comprise, without limitation, one or more of a monomer, an accelerator, a curing agent, an epoxy, and/or an acrylate. Curing the first liquid 1603 can comprise heating the first liquid 1603, irradiating the first liquid 1603 with ultraviolet (UV) radiation, and/or waiting a predetermined amount of time (e.g., from about 30 minutes to 24 hours, from about 1 hour to about 8 hours). Alternatively, the second adhesive layer 361 (see FIG. 3) can be disposed over the first major surface 203. In further aspects, as shown in FIGS. 17-18, a second polymer-based portion 299 can be disposed in the second recess 241, for example, by dispensing a second liquid 1703 from a container 1701 (e.g., conduit, flexible tube, micropipette, or syringe) over the second central surface area 243 that can be cured to form the second polymer-based portion 299. In even further aspects, the second liquid 1703 can comprise one or more of the compositions discussed above. Curing the second liquid 1703 can comprise heating the second liquid 1703, irradiating the second liquid 1703 with ultraviolet (UV) radiation, and/or waiting a predetermined amount of time (e.g., from about 30 minutes to 24 hours, from about 1 hour to about 8 hours). In further aspects, as shown in FIG. 18, an adhesive layer 261 can contact the second major surface 205 (e.g., the second surface area 225 and the fourth surface area 235). For example, the adhesive layer 261 can comprise one or more sheets of an adhesive material. In aspects, there can be an integral interface between the one or more sheets comprising the adhesive layer 261, which can reduce (e.g., avoid) optical diffraction and/or optical discontinuities as light travels between the sheets since the one or more sheets can include substantially the same refractive index. In aspects, although not shown, at least a portion of the adhesive layer can be disposed in the second recess. In aspects, a release liner (e.g., see release liner 271 in FIG. 2) or a display device may be disposed on the adhesive layer 261 (e.g., second contact surface 265).

After step 1205 or 1207, methods can proceed to step 1209, where methods of making the foldable substrate and/or the foldable apparatus can be complete. In aspects, methods of making a foldable substrate and/or a foldable apparatus in accordance with aspects of the disclosure can proceed along steps 1201, 1203, 1205, 1207, and 1209 of the flow chart in FIG. 12 sequentially, as discussed above. In aspects, methods can follow arrow 1202 from step 1205 to step 1209, for example, if methods are complete at the end of step 1205. Any of the above options may be combined to make a foldable apparatus in accordance with the embodiments of the disclosure.

### EXAMPLES

Various aspects will be further clarified by the following examples. Tables 3-9 present compositions of Comparative Examples AA-BB and Examples 1-56 and Tables 10-16 present properties of Comparative Examples AA-BB and Examples 1-56. In Tables 3-9, Ph6019 is Photomer 6019 (IGM Resins), which is a tri-functional urethane-acrylate oligomer. BR543 is Bomar 543 (Dymax). BR543 are difunctional urethane-acrylate oligomers. M320 is Miramer M320 (Miwon), M340 is Miramer M340 (Miwon), M360 is Miramer M360 (Miwon), M3130 is Miramer M3130 (Miwon), and M3190 is Miramer 3190 (Miwon). M320, M340, M360, M3130, and M3190 are trifunctional acrylate monomers. M200 is Miramer M200 (Miwon), M210 is Miramer M210 (Miwon), M240 is Miramer M240 (Miwon), and PE210 is Miramer PE210 (Miwon), and TPGDA is tripropylene glycol diacrylate. TPGDA, M200, M210, M240, and PE210 are difunctional acrylate monomers. M140 is Miramer M140 (Miwon), M150 is Miramer M150 (Miwon), M164 is Miramer M164 (Miwon), M1182 is Miramer M1182 (Miwon), M1192 is Miramer M1192 (Miwon), Ph4184 is Photomer 4184 (IGM Resins), IBA is isobornyl acrylate, and EHA is 2-ethylhexyl acrylate. M140, M150, M164, M1182, M1192, Ph4184, IBA, and EHA are reactive diluents, namely, monofunctional acrylates. HBA is 4-hyrdoxybutyl acrylate, and HPPA is 2-hydroxy-3-phenoxypropyl acrylate (e.g., Miramer PE110 (Miwon)). HBA and HPPA each have one acrylate functionality and one hydroxyl functionality. PE210 has two acrylate functionalities and two hydroxyl functionalities. S28 is Syna Epoxy 28 (Synasia), and S06E is Syna Epoxy 06E (Synasia). S28 and S06E are cycloaliphatic epoxide resins. CuraliteOX is CuraliteOX (Perstorp), which is an epoxy reactive diluent. GPOSS is EP0409 (Hybrid Plastics). A21-GPOSS is the product of reacting DMS-A21 (Gelest) with GPOSS to form POSS linked to another POSS by an amine functionalized poly(dimethyl siloxane) (PDMS). Silica NP refers to silica nanoparticles; specifically, Nanopox C620 (Evonik) comprising silica nanoparticles comprising a mean effective diameter of 20 nm in a 40 wt % solution in a cycloaliphatic epoxy resin was used for Silica NP, which means that the actual content of silica nanoparticles is 40% of the amount listed in Tables 3-9. GPOSS, A21-GPOSS, and Silica NP are inorganic fillers. TPO is 2,4,6-trimethylbenzoyldiphenyl phosphine oxide, and UVI is UVI 6976 (Dow). TPO and UVI are photoinitiators. Example 4 is a proprietary, cross-linked acrylate resin acquired from Momentive. Tables 3-9 present the compositions as wt % with all components adding up to 100%, but it is to be understood that the photoinitiator (and any silane coupling agent and/or antioxidant) can be represented as pph or ppm, as discussed above. Unless otherwise indicated, all Examples further comprised 0.5 pph of an antioxidant (i.e., Igranox 1035 (BASF)) added by superaddition.

As shown in Table 3, Comparative Examples AA-BB do not contain any multi-functional urethane-acrylate oligomers nor multi-functional acrylates with 3 or more functionalities. Instead, Comparative Example AA comprises a difunctional urethane-acrylate oligomer and acrylate reactive diluents. Comparative Example BB comprises an epoxy resin with an epoxy reactive diluent and an inorganic filler (A21-GPOSS). As shown in Table 10, neither Comparative Example AA nor Comparative Example BB had a well-defined yield. Comparative Example AA has an elastic modulus of 0.65 MPa, and a tensile strength of 0.55 MPa, which are both too low for the application described above for the polymer-based portion.

As shown in Table 3, Examples 1-2 and 5 have a tri-functional urethane-acrylate oligomer (Ph6019). Example 3 is an epoxy resin with silica nanoparticles (24 wt % nanoparticles). As mentioned above, Example 4 is a proprietary, cross-linked acrylate resin acquired from Momentive. As shown in Table 10, the elastic modulus for Examples 1-5 ranges from about 1,000 MPa to about 2,500 MPa, and the tensile strength for Examples 1-5 ranges from about 50 MPa to about 85 MPa. Examples 1-5 all have well-defined yields, with strain at yield ranging from about 5% to about 6%. For Examples 1-5, the ultimate elongation was greater than the strain at the well-defined yield by about 19% to about 70%. Examples 1-5 have a glass-transition temperature (Tg) from about 55° C. to about 130° C., a cured refractive index (RI) from about 1.498 to about 1.510, a yellowing index of less than 2 (e.g., about 1.5 or less), a minimum transmittance for optical wavelengths from 400 nm to 750 nm of 89% or more, and a haze of about 0.10% or less. Examples 1-2 and 4-5 have a yellowing index of less than 1 (e.g., less than 0.75). It is contemplated that incorporating functionalized POSS or silica nanoparticles (see example 3) could provide similar or even improved properties relative to the Example disclosed herein.

TABLE 3
Composition (wt %) of Examples AA-BB, 1-3, and 5

| Example | AA | BB | 1 | 2 | 3 | 5 |
|---|---|---|---|---|---|---|
| Ph6019 | — | — | 60 | 60 | — | 60 |
| BR543 | 40 | — | — | — | — | — |
| M240 | — | — | 8.5 | — | — | — |
| M164 | 40 | — | — | — | — | — |
| M1192 | 20 | — | — | — | — | — |
| Ph4184 | — | — | — | 38.5 | — | — |
| HBA | — | — | 30 | — | — | 38.5 |
| CuraliteOX | — | 20 | — | — | — | — |
| S28 | — | — | — | — | 38 | — |
| S06E | — | 20 | — | — | — | — |
| Silica NP | — | — | — | — | 60 | — |
| A21-GPOSS | — | 58 | — | — | — | — |
| TPO | — | — | 1.5 | 1.5 | — | 1.5 |
| UVI | — | 2 | — | — | 2 | — |

TABLE 4
Composition (wt %) of Examples 6-12

| Ex. | 6 | 7 | 8 | 9 | 10 | 11 | 12 |
|---|---|---|---|---|---|---|---|
| Ph6019 | 50 | 50 | 60 | 60 | 60 | 60 | 60 |
| M320 | — | — | — | — | — | 38.5 | — |
| M340 | 30 | 40 | — | — | — | — | 38.5 |
| M3130 | — | — | 38.5 | — | — | — | — |
| M3160 | — | — | — | 38.5 | — | — | — |
| M3190 | — | — | — | — | 38.5 | — | — |
| Ph4184 | 18.5 | 8.5 | 18.5 | 30 | — | — | — |
| TPO | 1.5 | 1.5 | 1.5 | 1.5 | 1.5 | 1.5 | 1.5 |

Table 4 presents the compositions for Examples 6-12. Examples 6-12 comprise multi-functional (e.g., trifunctional) urethane-acrylate oligomers (50 wt % to 60 wt % of Ph6019) in combination with multifunctional (e.g., trifunctional) acrylate monomers (M320, M340, M3130, M3160, M3190). Examples 6-9 further comprise a reactive diluent (Ph4184) while Examples 10-12 do not. As shown in Table 11, the elastic modulus of Examples 6-12 ranges from about 1,700 MPa to about 3,000 MPa, and the tensile strength for Examples 6-12 ranges from about 60 MPa to about 90 MPa. Examples 6-12 all have well-defined yields, with strain at yield ranging from about 4.8% to about 6%. For Examples 6-12, the ultimate elongation was greater than the strain at the well-defined yield by about 7% to about 75%. It is contemplated that trifunctional acrylate monomers can be used in conjunction with difunctional urethane-acrylate oligomers in addition to or instead of the trifunctional urethane-acrylate oligomers.

Table 5 presents the compositions for Examples 13-20. Examples 13-20 comprise 50 wt % of the multi-functional (e.g., trifunctional) urethane-acrylate oligomers (Ph6019) and reactive diluents (M150, Ph4184, IBA). Examples 13-16 and 18-20 further comprise a difunctional acrylate monomer. As shown in Table 12, the elastic modulus of Examples 13-20 ranges from about 1,050 MPa to about 2,700 MPa, and the tensile strength for Examples 13-20 ranges from about 50 MPa to about 70 MPa. Examples 13-20 all have well-defined yields, with strain at yield ranging from about 4.4% to about 6%. For Examples 13-20, the ultimate elongation was greater than the strain at the well-defined yield by about 20% to about 75%.

TABLE 5
Composition(wt %) of Examples 13-20

| Ex. | 13 | 14 | 15 | 16 | 17 | 18 | 19 | 20 |
|---|---|---|---|---|---|---|---|---|
| Ph6019 | 50 | 50 | 50 | 50 | 50 | 50 | 50 | 50 |
| PE210 | 30 | — | — | — | — | — | — | — |
| M240 | — | 18.5 | 18.5 | 18.5 | — | — | — | — |
| TPGDA | — | — | — | — | — | 10 | 15 | 20 |
| M150 | — | — | 30 | — | 48.5 | 38.5 | 33.5 | 28.5 |
| Ph4184 | 18.5 | 30 | — | — | — | — | — | — |
| IBA | — | — | — | 30 | — | — | — | — |
| TPO | 1.5 | 1.5 | 1.5 | 1.5 | 1.5 | 1.5 | 1.5 | 1.5 |

TABLE 6
Composition (wt %) of Examples 21-31

| Ex. | 21 | 22 | 23 | 24 | 25 | 26 | 27 | 28 | 29 | 30 | 31 |
|---|---|---|---|---|---|---|---|---|---|---|---|
| Ph6019 | 60 | 60 | 70 | 80 | 55 | 60 | 60 | 60 | 60 | 65 | 80 |
| M240 | — | 18.5 | — | — | — | — | — | — | — | — | — |
| TPGDA | — | — | — | — | 13.5 | 8.5 | 13.5 | 8.5 | 8.5 | 3.5 | — |
| M150 | — | — | — | — | — | — | — | 10 | 20 | — | — |
| HPPA | 38.5 | 20 | 28.5 | 18.5 | — | — | — | — | — | — | — |
| HBA | — | — | — | — | 30 | 30 | 25 | 20 | 10 | 30 | 18.5 |
| TPO | 1.5 | 1.5 | 1.5 | 1.5 | 1.5 | 1.5 | 1.5 | 1.5 | 1.5 | 1.5 | 1.5 |

Table 6 presents the compositions for Examples 21-31. Examples 21-31 comprise 55 wt % to 80 wt % of the multi-functional (e.g., trifunctional) urethane-acrylate oligomers (Ph6019). Examples 22 and 25-30 further comprise a difunctional acrylate monomer (M240, TPGDA). Examples 21-31 further comprise HBA or HPPA that each have both an acrylate and a hydroxyl functionality. As shown in Table 13, the elastic modulus of Examples 21-31 ranges from about 1,500 MPa to about 2,700 MPa, and the tensile strength for Examples 21-30 ranges from about 50 MPa to about 70 MPa. Examples 21-31 all have well-defined yields, with strain at yield ranging from about 4.4% to about 5%. For Examples 21-31, the ultimate elongation was greater than the strain at the well-defined yield by about 8% to about 70%.

Table 7 presents the compositions for Examples 32-40. Examples 32-40 comprise 55 wt % or 60 wt % of the multi-functional (e.g., trifunctional) urethane-acrylate oligomers (Ph6019). Examples 32-34 further comprise a difunctional acrylate monomer (TPGDA). Examples 35-38 further comprise one or more difunctional acrylate monomers (M210, M240). Examples 32-34 and 38-40 further comprise a reactive diluent. As shown in Table 14, the elastic modulus of Examples 32-40 ranges from about 2,000 MPa to about 2,600 MPa, and the tensile strength for Examples 32-40 ranges from about 60 MPa to 80 MPa. Examples 32-40 all have well-defined yields, with strain at yield ranging from about 4.4% to about 6%. For Examples 32-40, the ultimate elongation was greater than the strain at the well-defined yield by about 20% to about 60%.

TABLE 7
Composition (wt %) of Examples 32-40

| Ex. | 32 | 33 | 34 | 35 | 36 | 37 | 38 | 39 | 40 |
|---|---|---|---|---|---|---|---|---|---|
| Ph6019 | 55 | 55 | 55 | 60 | 60 | 60 | 60 | 60 | 60 |
| TPGDA | 5 | 10 | 15 | — | — | — | — | — | — |
| M200 | — | — | — | 38.5 | — | — | — | — | — |
| M210 | — | — | — | — | 38.5 | 20 | — | — | — |
| M240 | — | — | — | — | — | 18.5 | 18.5 | — | — |
| M150 | 38.5 | 33.5 | 28.5 | — | — | — | — | 38.5 | — |
| M1182 | — | — | — | — | — | — | 20 | — | — |
| Ph4184 | — | — | — | — | — | — | — | — | 38.5 |
| TPO | 1.5 | 1.5 | 1.5 | 1.5 | 1.5 | 1.5 | 1.5 | 1.5 | 1.5 |

TABLE 8
Composition (wt %) of Examples 41-48

| Ex. | 41 | 42 | 43 | 44 | 45 | 46 | 47 | 48 |
|---|---|---|---|---|---|---|---|---|
| Ph6019 | 60 | 60 | 60 | 60 | 70 | 70 | 70 | 70 |
| PE210 | — | — | — | 20 | 10 | — | — | — |
| M140 | 38.5 | — | — | — | — | — | — | — |
| M150 | — | — | — | — | — | 28.5 | — | — |
| M1182 | — | — | 38.5 | — | — | — | — | — |
| Ph4184 | — | — | — | 18.5 | 18.5 | — | 28.5 | — |
| EHA | — | — | — | — | — | — | — | 28.5 |
| IBA | — | 38.5 | — | — | — | — | — | — |
| TPO | 1.5 | 1.5 | 1.5 | 1.5 | 1.5 | 1.5 | 1.5 | 1.5 |

Table 8 presents the compositions for Examples 41-48. Examples 41-48 comprise 60 wt % to 70 wt % of the multi-functional (e.g., trifunctional) urethane-acrylate oligomers (Ph6019). Examples 44-45 further comprise difunctional acrylate monomers (PE210). Examples 41-48 further comprise a reactive diluent. As shown in Table 15, the elastic modulus of Examples 41-48 ranges from about 1,600 MPa to about 2,700 MPa, and the tensile strength for Examples 41-48 ranges from about 60 MPa to about 70 MPa. Examples 41-48, all have well-defined yields, with strain at yield ranging from about 4.4% to about 6%. For Examples 41-48, the ultimate elongation was greater than the strain at the well-defined yield by about 9% to about 55%.

Table 9 presents the compositions for Examples 49-56. Examples 49-56 comprise 80 wt % of the multi-functional (e.g., trifunctional) urethane-acrylate oligomers (Ph6019). Examples 49-50 further comprise one or more difunctional acrylate monomers (M200, M210). Examples 51-56 further comprise a reactive diluent. As shown in Table 16, the elastic modulus of Examples 49-56 ranges from about 2,000 MPa to about 2,700 MPa, and the tensile strength for Examples 49-56 ranges from about 60 MPa to 80 MPa. Examples 46-56 all have well-defined yields, with strain at yield ranging from about 4.5% to about 6%. For Examples 52-58, the ultimate elongation was greater than the strain at the well-defined yield by about 25% to about 40%.

TABLE 9
Composition (wt %) of Examples 49-56

| Ex. | 49 | 50 | 51 | 52 | 53 | 54 | 55 | 56 |
|---|---|---|---|---|---|---|---|---|
| Ph6019 | 80 | 80 | 80 | 80 | 80 | 80 | 80 | 80 |
| M200 | 18.5 | — | — | — | — | — | — | — |
| M210 | — | 18.5 | — | — | — | — | — | — |
| M140 | — | — | 18.5 | — | — | — | — | — |
| M150 | — | — | — | 18.5 | — | — | — | — |
| M1182 | — | — | — | — | 18.5 | — | — | — |
| Ph4184 | — | — | — | — | — | 18.5 | — | — |
| EHA | — | — | — | — | — | — | 18.5 | — |
| IBA | — | — | — | — | — | — | — | 18.5 |
| TPO | 1.5 | 1.5 | 1.5 | 1.5 | 1.5 | 1.5 | 1.5 | 1.5 |

TABLE 10
Properties of Examples AA-BB and 1-5

| Example | AA | BB | 1 | 2 | 3 | 4 | 5 |
|---|---|---|---|---|---|---|---|
| Elastic Modulus (MPa) | 0.65 | 1900 | 1700 | 1970 | 2500 | 1810 | 1040 |
| Tensile Strength (MPa) | 0.55 | 67 | 62 | 59 | 83 | 74 | 49 |
| Ultimate Elongation (%) | 245 | 8 | 66 | 59 | 25 | 35 | 77 |
| Yield Stress (MPa) | n/a | n/a | 45 | 54 | 74 | 51 | 22 |
| Yield Strain (%) | n/a | n/a | 4.9 | 5.4 | 5.3 | 5.2 | 6.1 |
| Tg (°C) | −14 | 74 | 55 | 58 | 128 | 80 | 56 |
| Cured RI | 1.512 | 1.507 | 1.509 | 1.498 | 1.510 | 1.506 | 1.053 |
| Min. Transmission (%) | 90.1 | 90.5 | 89.6 | 89.9 | 89.0 | 90.0 | 89.6 |
| CIE b* value (D65, 10°) | 0.36 | 0.40 | 0.24 | 0.29 | 0.75 | 0.39 | 0.24 |
| Yellowing Index | 0.62 | 0.71 | 0.39 | 0.50 | 1.33 | 0.64 | 0.39 |
| Haze (D65, 10°) | 0.01 | 0.05 | 0.02 | 0.04 | 0.10 | 0.02 | 0.02 |
| Pen Drop Height (cm) | — | 5 | 14.5 | 15 | 14 | 20 | — |
| Puncture Resistance (kgf) | 0.9 | 1.1 | 1.2 | — | — | — | — |
| (0.25 mm diameter) | | | | | | | |
| Puncture Resistance (kgf) | 1.6 | 1.9 | 2.7 | — | — | — | — |
| (0.5 mm diameter) | | | | | | | |

For the Pen Drop Test, a polymer-based portion comprising a thickness of 45 μm of Comparative Example BB or Examples 1~4 was placed in and filled a recess in a glass-based substrate (having Composition 1) with a central thickness of 30 μm and a substrate thickness of 100 μm. The glass-based substrate has two recesses of equal depth with the Example (or Comparative Example) material in the recess opposite the PET sheet and a polymer-based portion with an elastic modulus of 2.4 MPa filling the other recess. As discussed above, a 50 μm thick sheet of PET was placed over the polymer-based portion. The Pen Drop Test was conducted with the pen dropped over a portion of the samples including the polymer-based portion such that the pen contacts the outer surface of the PET sheet. The pen drop height values reported in Table 10 correspond to the median pen drop height of at least 5 samples. Comparative Example BB had a median pen drop height value of 5 cm. Examples 1-4 had median pen drop heights about 3 times more than that of Comparative Example BB. It is expected that Examples 5-59 to demonstrate pen drop values similar to those of Examples 1-4.

For the Quasi-Static Puncture Test, a polymer-based portion comprising a thickness of 45 μm of Comparative Examples AA-BB and Example 1 was placed in and filled a recess in a glass-based substrate (having a Composition 1) with a central thickness of 30 μm. The glass-based substrate has two recesses of equal depth with the Example (or Comparative Example) material in the recess opposite the PET sheet and a polymer-based portion with an elastic modulus of 2.4 MPa filling the other recess. As discussed above, a 50 μm thick sheet of PET was placed over the polymer-based portion. The Quasi-Static Puncture Test was conducted with the ball bearing pressed into the outer surface of the PET sheet in a portion of the samples including the polymer-based portion. The reported puncture resistance reported in Table 10 corresponds to the median load at failure for at least 5 samples. For the 0.25 mm diameter ball bearing, Comparative Example AA had a puncture resistance of 0.9 kgf, Comparative Example BB had a puncture resistance of 1.1 kgf, and Example 1 had a puncture resistance of 1.2 kgf. For the 0.5 mm diameter ball bearing, Comparative Example AA had a puncture resistance of 1.6 kgf, Comparative Example BB had a puncture resistance of 1.9 kgf, and Example 1 had a puncture resistance of 2.7 kgf. It is expected that Examples 2-59 would exhibit puncture resistance similar to the puncture resistance of Example 1. Consequently, for both the 0.25 mm and 0.5 mm diameter ball bearings, Example 1 had a greater puncture resistance than Comparative Examples AA-BB.

TABLE 11
Properties of Examples 6-12

| Example | 6 | 7 | 8 | 9 | 10 | 11 | 12 |
|---|---|---|---|---|---|---|---|
| Elastic Modulus (MPa) | 2750 | 2920 | 2365 | 2090 | 1740 | 2465 | 2440 |
| Tensile Strength (MPa) | 76 | 84 | 79 | 74 | 74 | 68 | 67 |
| Ultimate Elongation (%) | 15 | 13 | 30 | 36 | 47 | 26 | 21 |
| Yield Stress (MPa) | 81 | 85 | 68 | 58 | 47 | 68 | 69 |
| Yield Strain (%) | 5.3 | 5.5 | 5.4 | 4.9 | 4.8 | 4.9 | 5.1 |

TABLE 12
Properties of Examples 13-20

| Example | 13 | 14 | 15 | 16 | 17 | 18 | 19 | 20 |
|---|---|---|---|---|---|---|---|---|
| Elastic Modulus (MPa) | 2645 | 2075 | 2160 | 1325 | 1080 | 1700 | 1905 | 2115 |
| Tensile Strength (MPa) | 68 | 71 | 76 | 51 | 52 | 64 | 71 | 69 |
| Ultimate Elongation (%) | 28 | 58 | 63 | 54 | 80 | 68 | 65 | 55 |
| Yield Stress (MPa) | 79 | 58 | 59 | 35 | 21 | 38 | 46 | 53 |
| Yield Strain (%) | 5.3 | 5.1 | 4.5 | 5.2 | 5.6 | 4.6 | 4.4 | 4.4 |

TABLE 13
Properties of Examples 21-31

| Example | 21 | 22 | 23 | 24 | 25 | 26 | 27 | 28 | 29 | 30 | 31 |
|---|---|---|---|---|---|---|---|---|---|---|---|
| Elastic | 2600 | 2630 | 2670 | 2630 | 1510 | 1665 | 1880 | 1830 | 2015 | 1790 | 2205 |
| Modulus (MPa) | | | | | | | | | | | |
| Tensile | 61 | 67 | 58 | 61 | 54 | 59 | 58 | 49 | 63 | 49 | 59 |
| Strength (MPa) | | | | | | | | | | | |
| Ultimate | 31 | 74 | 24 | 14 | 57 | 62 | 52 | 51 | 60 | 52 | 40 |
| Elongation (%) | | | | | | | | | | | |
| Yield | 73 | 48 | 75 | 77 | 37 | 41 | 50 | 46 | 53 | 46 | 67 |
| Stress (MPa) | | | | | | | | | | | |
| Yield | 4.6 | 4.7 | 4.8 | 4.7 | 4.9 | 4.8 | 4.7 | 4.6 | 4.4 | 4.7 | 4.9 |
| Strain (%) | | | | | | | | | | | |

TABLE 14
Properties of Examples 32-40

| Example | 32 | 33 | 34 | 35 | 36 | 37 | 38 | 39 | 40 |
|---|---|---|---|---|---|---|---|---|---|
| Elastic | 1970 | 2080 | 2135 | 2180 | 2520 | 2540 | 2430 | 2030 | 2065 |
| Modulus (MPa) | | | | | | | | | |
| Tensile | 66 | 65 | 64 | 75 | 73 | 78 | 66 | 61 | 63 |
| Strength (MPa) | | | | | | | | | |
| Ultimate | 66 | 57 | 54 | 25 | 37 | 45 | 44 | 61 | 57 |
| Elongation (%) | | | | | | | | | |
| Yield | 48 | 54 | 55 | 69 | 71 | 73 | 72 | 52 | 57 |
| Stress (MPa) | | | | | | | | | |
| Yield | 4.5 | 4.5 | 4.4 | 5.8 | 4.8 | 4.8 | 4.6 | 4.5 | 5.1 |
| Strain (%) | | | | | | | | | |

TABLE 15
Properties of Examples 41-48

| Example | 41 | 42 | 43 | 44 | 45 | 46 | 47 | 48 |
|---|---|---|---|---|---|---|---|---|
| Elastic | 2460 | 2325 | 2500 | 2630 | 2460 | 2310 | 2310 | 1620 |
| Modulus (MPa) | | | | | | | | |
| Tensile | 63 | 60 | 64 | 62 | 69 | 61 | 62 | 61 |
| Strength (MPa) | | | | | | | | |
| Ultimate | 58 | 14 | 56 | 33 | 47 | 53 | 42 | 60 |
| Elongation (%) | | | | | | | | |
| Yield | 66 | 73 | 67 | 78 | 74 | 64 | 69 | 45 |
| Stress (MPa) | | | | | | | | |
| Yield | 4.4 | 4.9 | 4.3 | 5.4 | 5.3 | 4.6 | 5.2 | 5 |
| Strain (%) | | | | | | | | |

TABLE 16
Properties of Examples 49-56

| Example | 49 | 50 | 51 | 52 | 53 | 54 | 55 | 56 |
|---|---|---|---|---|---|---|---|---|
| Elastic | 2480 | 2565 | 2560 | 2480 | 2630 | 2510 | 2055 | 2470 |
| Modulus (MPa) | | | | | | | | |
| Tensile | 70 | 74 | 62 | 69 | 65 | 65 | 62 | 65 |
| Strength (MPa) | | | | | | | | |
| Ultimate | 30 | 42 | 25 | 42 | 42 | 43 | 46 | 31 |
| Elongation (%) | | | | | | | | |
| Yield | 73 | 75 | 73 | 72 | 75 | 74 | 59 | 76 |
| Stress (MPa) | | | | | | | | |
| Yield Strain (%) | 5.1 | 4.9 | 4.8 | 4.5 | 4.6 | 5.1 | 5 | 4.9 |

The above observations can be combined to provide polymer-based portions, foldable apparatus comprising the same, and methods of making polymer-based portions and foldable apparatus comprising the same. Polymer-based portions can comprise an epoxy with an organic filler, or an acrylate or urethane-acrylate with one or more branching points. Providing a polymer with one or more branching points can increase a stiffness of the polymer and/or an ability of the polymer to absorb impacts (e.g., impact resistance). The polymer-based portion can comprise a well-defined yield. Providing a polymer-based portion with a well-defined yield can enable the polymer-based portion and/or a foldable apparatus containing the polymer-based portion to withstand impacts without failure and/or puncture, for example, because the polymer-based portion can withstand greater impacts through plastic deformation instead of failing. As demonstrated in the Examples, the pen drop height and/or puncture resistance of portions of foldable apparatus including the polymer-based portion can be greater than the Comparative Examples, meaning that the impact resistance and/or puncture resistance in portions of the foldable apparatus including the polymer-based portion can be closer to the corresponding properties of other portions of the polymer-based portion than was previously attainable. Providing a polymer-based portion with a glass-transition temperature outside of an operating range (e.g., from about 0° C. to about 40° C., from about −10° C. to about 50° C.) can enable consistent properties across the operating range.

Providing an refractive index for the polymer-based portion from about 1.48 to about 1.55 or from about 1.49 to about 1.52 can reduce an absolute difference of refractive index (e.g., about 0.05 or less, about 0.01 or less) between the polymer-based portion and components (e.g., substrate, adhesive, hard-coating) that can be adjacent to the polymer-based portion in an application, which can reduce optical distortions. Providing a low absolute value of b* (e.g., from −1 to 1) can be substantially free of yellowing and/or other noticeable color. Providing a polymer-based portion with a low yellowing index (e.g., about 2 or less, about 1.4 or less) can be substantially free of yellowing and/or other noticeable color.

Providing an inorganic filler can increase an elastic modulus, impact resistance, and/or puncture resistance of the resulting polymer-based portion. Providing a composition free of functionalized oligomeric silsesquioxanes can decrease a cost to produce the composition and/or resulting polymer-based portion, increase a flexibility of the resulting polymer-based portion, and/or increase an adhesion of the resulting polymer-based portion. Alternatively, in aspects, the composition can comprise functionalized oligomeric silsesquioxanes that can be in combination with silica nanoparticles or not. Providing a composition comprising functionalized oligomeric silsesquioxanes can increase a hardness and/or impact resistance of the resulting polymer-based portion. In aspects, the composition can be substantially free (e.g., 1 wt % or less) and/or free of silica nanoparticles. Without wishing to be bound by theory, silica nanoparticles can aggregate, especially at elevated temperature, impairing mechanical and/or optical properties of the composition or resulting coating and/or coated article. Providing a composition substantially free and/or free of silica nanoparticles can reduce processing issues (e.g., agglomeration, aggregation, phase separation) with the composition, improve optical properties (e.g., maintain low haze and/or high transmittance even after aging at elevated temperature and/or humidity) of the coating and/or the resulting coating and/or coated article, and reduce mechanical properties (e.g., hardness, modulus, strain) of the resulting coating and/or coated article compared to a corresponding composition, coating, and/or coated article comprising a plurality of functionalized oligomeric silsesquioxanes without silica nanoparticles.

Providing a composition that is substantially solvent-free (e.g., entirely solvent-free) can increase the curing rate of the composition, which can decrease processing time. Providing a composition that is substantially solvent-free (e.g., entirely solvent-free) can reduce (e.g., decrease, eliminate) the use of additives, for example, rheology modifiers, and increase composition homogeneity, which can improve the quality of the resulting polymer-based portion (e.g., increased transmittance, decreased haze, increased mechanical properties). Providing a composition that is substantially solvent-free (e.g., entirely solvent-free) can reduce a volume change as a result of curing (e.g., shrinkage). In aspects, the composition and/or the polymer-based portion can be substantially free of fluorine-based compounds and/or free of fluorine-based compounds, which can reduce an environmental impact of the polymer-based portion and/or reduce a cost to produce the polymer-based portion.

The foldable substrate can comprise glass-based and/or ceramic-based portions, which can provide good dimensional stability, reduced incidence of mechanical instabilities, good impact resistance, and/or good puncture resistance. The foldable substrate can comprise glass-based and/or ceramic-based portions comprising one or more compressive stress regions, which can further provide increased impact resistance and/or increased puncture resistance. By providing a foldable substrate comprising a glass-based and/or ceramic-based substrate, the substrate can also provide increased impact resistance and/or puncture resistance while simultaneously facilitating good folding performance. In aspects, the substrate thickness can be sufficiently large (e.g., from about 70 micrometers (microns or μm) to about 2 millimeters) to further enhance impact resistance and puncture resistance. Providing foldable substrates comprising a central portion comprising a central thickness that is less than a substrate thickness (e.g., first thickness of the first portion and/or second thickness of the second portion) (e.g., by about 10 μm or more) can enable a small parallel plate distance (e.g., about 10 millimeters or less) based on the reduced thickness in the central portion, which can enable the foldability and/or rollability of the foldable substrate and/or foldable apparatus.

In aspects, the foldable apparatus and/or foldable substrates can comprise one or more recesses, for example, a first central surface area recessed from a first major surface by a first distance and/or a second central surface area recessed from a second major surface by a second distance. Providing a first recess opposite a second recess can provide the central thickness that is less than a substrate thickness. Further, providing a first recess opposite a second recess can reduce a maximum bend-induced strain of the foldable apparatus, for example, between a central portion and a first portion and/or second portion since the central portion comprising the central thickness can be closer to a neutral axis of the foldable apparatus and/or foldable substrates than if only a single recess was provided. Additionally, providing the first distance substantially equal to the second distance can reduce the incidence of mechanical instabilities in the central portion, for example, because the foldable substrate is symmetric about a plane comprising a midpoint in the substrate thickness and the central thickness. Moreover, providing a first recess opposite a second recess can reduce a bend-induced strain of a material positioned in the first recess and/or second recess compared to a single recess with a surface recessed by the sum of the first distance and the second distance. Providing a reduced bend-induced strain of a material positioned in the first recess and/or the second recess can enable the use of a wider range of materials because of the reduced strain requirements for the material. For example, stiffer and/or more rigid materials can be positioned in the first recess, which can improve impact resistance, puncture resistance, abrasion resistance, and/or scratch resistance of the foldable apparatus. Additionally, controlling properties of a first material positioned in a first recess and a second material positioned in a second recess can control the position of a neutral axis of the foldable apparatus and/or foldable substrates, which can reduce (e.g., mitigate, eliminate) the incidence of mechanical instabilities, apparatus fatigue, and/or apparatus failure.

In aspects, the foldable apparatus and/or foldable substrates can comprise a first transition region attaching the central portion to the first portion and/or a second transition region attaching the central portion to the second portion. Providing transition regions with smoothly and/or monotonically decreasing (e.g., continuously decreasing) thicknesses can reduce stress concentration in the transition regions and/or avoid optical distortions. Providing a sufficient length of the transition region(s) (e.g., about 0.15 mm or more or about 0.3 mm or more) can avoid optical distortions that may otherwise exist from a sharp change in thickness of the foldable substrate. Providing an average transition angle of a first transition surface area of the first transition region relative to the first central surface area that is sufficiently large (e.g., about 167° or more or about 170° or more) can avoid optical distortions and/or reduce visibility of the transition region. Providing a sufficiently small average transition angle (e.g., about 179° or less or about 176° or less) can reduce the amount of the foldable apparatus and/or the foldable substrates having an intermediate thickness that may have reduced impact resistance and/or reduced puncture resistance.

Directional terms as used herein—for example, up, down, right, left, front, back, top, bottom—are made only with reference to the figures as drawn and are not intended to imply absolute orientation.

It will be appreciated that the various disclosed aspects may involve features, elements, or steps that are described in connection with that aspect. It will also be appreciated that a feature, element, or step, although described in relation to one aspect, may be interchanged or combined with alternate aspects in various non-illustrated combinations or permutations.

It is also to be understood that, as used herein the terms “the,” “a,” or “an,” mean “at least one,” and should not be limited to “only one” unless explicitly indicated to the contrary. For example, reference to “a component” comprises aspects having two or more such components unless the context clearly indicates otherwise. Likewise, a “plurality” is intended to denote “more than one.”

As used herein, the term “about” means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art. Ranges can be expressed herein as from “about” one particular value, and/or to “about” another particular value. When such a range is expressed, aspects include from the one particular value and/or to the other particular value. Similarly, when values are expressed as approximations, by use of the antecedent “about,” it will be understood that the particular value forms another aspect. Whether or not a numerical value or endpoint of a range in the specification recites “about,” the numerical value or endpoint of a range is intended to include two aspects: one modified by “about,” and one not modified by “about.” It will be further understood that the endpoints of each of the ranges are significant both in relation to the other endpoint and independently of the other endpoint.

The terms “substantial,” “substantially,” and variations thereof as used herein are intended to note that a described feature is equal or approximately equal to a value or description. For example, a “substantially planar” surface is intended to denote a surface that is planar or approximately planar. Moreover, as defined above, “substantially similar” is intended to denote that two values are equal or approximately equal. In aspects, “substantially similar” may denote values within about 10% of each other, for example, within about 5% of each other, or within about 2% of each other.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is in no way intended that any particular order be inferred.

While various features, elements, or steps of particular aspects may be disclosed using the transitional phrase “comprising,” it is to be understood that alternative aspects, including those that may be described using the transitional phrases “consisting of” or “consisting essentially of,” are implied. Thus, for example, implied alternative aspects to an apparatus that comprises A+B+C include aspects where an apparatus consists of A+B+C and aspects where an apparatus consists essentially of A+B+C. As used herein, the terms “comprising” and “including”, and variations thereof shall be construed as synonymous and open-ended unless otherwise indicated.

The above aspects, and the features of those aspects, are exemplary and can be provided alone or in any combination with any one or more features of other aspects provided herein without departing from the scope of the disclosure.

It will be apparent to those skilled in the art that various modifications and variations can be made to the present disclosure without departing from the spirit and scope of the disclosure. Thus, it is intended that the present disclosure cover the modifications and variations of the aspects herein provided they come within the scope of the appended claims and their equivalents.

1. A polymer-based portion comprising:
an elastic modulus from about 500 MegaPascals to about 3 GigaPascals;
an ultimate elongation of about 12% or more;
a glass-transition temperature from about 45° C. to about 150° C.; and
a refractive index from about 1.48 to about 1.55,
wherein the polymer-based portion exhibits a well-defined yield, and a difference between the ultimate elongation and a strain at the well-defined yield is about 3% or more.

2. The polymer-based portion of claim 1, wherein the polymer-based portion comprises urethane-acrylate branching points or acrylate branching points.

3. The polymer-based portion of claim 1, wherein the polymer-based portion is an epoxy with from about 5 weight % to about 20 weight % of an inorganic filler.

4. The polymer-based portion of claim 1, wherein the polymer-based portion comprises from about 0.5 parts-per-hundred to about 3 parts-per-hundred of a photoinitiator.

5. The polymer-based portion of claim 1, wherein the polymer-based portion comprises from about 0.1 parts-per-hundred to about 10 parts-per-hundred of an acrylate silane.

6. The polymer-based portion of claim 1, wherein the polymer-based portion comprises from about 0.1 parts-per-hundred to about 1 parts-per-hundred of an antioxidant.

7. The polymer-based portion of claim 1, wherein a minimum transmittance of the polymer-based portion for optical wavelengths from 400 nanometers to 750 nanometers is 89% or more.

8. The polymer-based portion of claim 1, wherein a haze of the polymer-based portion is about 1% or less.

9. The polymer-based portion of claim 1, wherein the polymer-based portion has a CIE b* value from about −1 to about 1.

10. The polymer-based portion of claim 1, wherein the polymer-based portion has a yellowing index of about 2 or less.

11. The polymer-based portion of claim 1, wherein the polymer-based portion can withstand 200,000 cycles of bending to a parallel plate distance of 3 millimeters at 25° C. and 40% relative humidity.

12. The polymer-based portion of claim 1, wherein the polymer-based portion can withstand a pen drop height of 10 centimeters or more when a pen is incident on a 50 micrometer thick sheet of poly(ethylene terephthalate) that is disposed on a 25 micrometer thick adhesive having an elastic modulus of 10 MegaPascals that is in turn disposed on the polymer-based portion that is in turn disposed on a glass-based substrate comprising a thickness of 30 micrometers.

13. The polymer-based portion of claim 1, wherein the polymer-based portion can withstand a load of 1 kgf from a 0.25 millimeter diameter tungsten carbide ball incident on a 50 micrometer thick sheet of poly(ethylene terephthalate) that is disposed on a 25 micrometer thick adhesive having an elastic modulus of 10 MegaPascals that is in turn disposed on the polymer-based portion that is in turn disposed on a glass-based substrate comprising a thickness of 30 micrometers without puncturing the 50 micrometer thick sheet of poly(ethylene terephthalate).

14. A foldable apparatus comprising:
a substrate comprising:
a substrate thickness defined between a first major surface and a second major surface opposite the first major surface;
a first portion comprising the substrate thickness, a first compressive stress region extending to a first depth of compression from the first major surface, a second compressive stress region extending to a second depth of compression from the second major surface;
a second portion comprising the substrate thickness, a third compressive stress region extending to a third depth of compression from the first major surface, a fourth compressive stress region extending to a fourth depth of compression from the second major surface; and
a central portion positioned between the first portion and the second portion, the central portion comprising a central thickness defined between a first central surface area and a second central surface area opposite the first central surface area, a first central compressive stress region extending to a first central depth of compression from the first central surface area, a second central compressive stress region extending to a second central depth of compression from the second central surface area, and the central thickness is less than the substrate thickness; and
the polymer-based portion claim 1, the polymer-based portion positioned in a recess defined between the first central surface area and a first plane that the first major surface extends along.

15. A method of making a polymer-based portion comprising:
curing a precursor solution to form the polymer-based portion, the precursor solution comprising:
from about 30 wt % to about 80 wt % of a multi-functional urethane-acrylate oligomer, a multi-functional acrylate monomer, or combinations thereof, and at least one of the multi-functional urethane-acrylate oligomer or the multi-functional acrylate monomer has a functionality of 3 or more;
from 0 wt % to about 60 wt % of a reactive diluent;
from 0 wt % to about 40 wt % of a difunctional acrylate monomer;
from 0 wt % to about 40 wt % of a difunctional urethane-acrylate oligomer; and
from 0 wt % to about 70 wt % of an inorganic filler,
wherein the polymer-based portion comprises:
one or more branching points at the multi-functional urethane-acrylate oligomer or multi-functional acrylate monomer;
a refractive index from about 1.48 to about 1.55;
an elastic modulus from about 500 MegaPascals to about 3 GigaPascals; and
a glass-transition temperature from about 45° C. to about 150° C.

16. The method of claim 15, wherein the inorganic filler comprises from about 20 wt % to about 60 wt % of an acrylate-functionalized polyhedral oligomeric silsesquioxane.

17. The method of claim 15, wherein the inorganic filler comprises from about 10 wt % to about 30 wt % of silica nanoparticles dispersed in at least a portion of the reactive diluent, the difunctional acrylate monomer, or combinations thereof.

18. The method of claim 15, wherein the curing comprises irradiating the precursor solution with one or more wavelengths that the photoinitiator is sensitive to with a predetermined fluence.

19. The method of claim 15, wherein the precursor solution is solvent-free.

20. The method of claim 15, wherein the precursor solution is disposed in a recess of a substrate prior to the curing, the substrate comprising:
a substrate thickness defined between a first major surface and a second major surface opposite the first major surface;
a first portion comprising the substrate thickness, a first compressive stress region extending to a first depth of compression from the first major surface, a second compressive stress region extending to a second depth of compression from the second major surface;
a second portion comprising the substrate thickness, a third compressive stress region extending to a third depth of compression from the first major surface, a fourth compressive stress region extending to a fourth depth of compression from the second major surface; and
a central portion positioned between the first portion and the second portion, the central portion comprising a central thickness defined between a first central surface area and a second central surface area opposite the first central surface area, a first central compressive stress region extending to a first central depth of compression from the first central surface area, a second central compressive stress region extending to a second central depth of compression from the second central surface area, and the central thickness is less than the substrate thickness,
wherein the recess is defined between the first central surface area and a first plane that the first major surface extends along.
